(19) United States
(12) Patent Application Publication
(10) Pub. No.: US 2018/0066000 A1
(43) Pub. Date: Mar. 8, 2018

(54) Metal Complexes and Electroluminescent Devices Comprising These Metal Complexes

(71) Applicant: MERCK PATENT GMBH, Darmstadt (DE)

(72) Inventors: Philipp Stoessel, Frankfurt am Main (DE); Dominik Joosten, Frankfurt am Main (DE); Beate Burkhart, Darmstadt (DE); Katja Stegmaier, Darmstadt (DE)

(73) Assignee: MERCK PATENT GMBH, Darmstadt (DE)

(21) Appl. No.: 15/573,259

(22) PCT Filed: Apr. 19, 2016
(86) PCT No.: PCT/EP2016/000633

§ 371 Date: Nov. 10, 2017

(30) Foreign Application Priority Data
May 13, 2015 (EP) 15001434.8

(51) Int. Cl. C07F 9/94; C09K 11/06; H01L 51/00

(52) U.S. Cl. CPC C07F 9/94; C09K 11/06; H01L 51/0077; H01L 51/0058; H01L 51/0043; C09K 2211/188; H01L 51/006; H01L 51/0039

(57) ABSTRACT

The present invention relates to metal complexes having a metal atom of groups 13 to 15 and at least one ligand, where the ligand comprises at least one anionic coordination group having at least one oxygen and/or nitrogen atom via which the metal atom is coordinated, and the ligand comprises at least one triarylamine group, to processes for preparation thereof and to the use thereof in electronic devices, especially in organic electroluminescent devices, called OLEDs (OLED=organic light emitting diode). The present invention also further relates to organic electroluminescent devices comprising these metal complexes.

The present invention relates to metal complexes, to processes for preparation thereof and to the use thereof in electronic or optoelectronic devices, especially in organic electroluminescent devices, called OLEDs (OLED=organic light-emitting diodes). The present invention also further relates to organic electroluminescent devices comprising these compositions.

In electronic or optoelectronic devices, especially in organic electroluminescent devices (OLEDs), components of various functionality are required. In OLEDs, the different functionalities are normally present in different layers. Reference is made in this case to multilayer OLED systems. The layers in these multilayer OLED systems include charge-injecting layers, for example electron- and hole-injecting layers, charge-transporting layers, for example electron- and hole-conducting layers, and layers containing light-emitting components. These multilayer OLED systems are generally produced by successive layer by layer application.

If two or more layers are applied from solution, it has to be ensured that any layer already applied, after drying, is not destroyed by the subsequent application of the solution for production of the next layer. This can be achieved, for example, by rendering a layer insoluble, for example by crosslinking. Methods of this kind are disclosed, for example, in EP 0 637 899 and WO 96/20253.

Furthermore, it is also necessary to match the functionalities of the individual layers in terms of the material such that very good results, for example in terms of lifetime, efficiency, etc., are achieved. For instance, particularly the layers that directly adjoin an emitting layer, especially the hole-transporting layer (HTL=hole transport layer) have a significant influence on the properties of the adjoining emitting layer.

Known electronic devices and the methods for production thereof have a usable profile of properties. However, there is a constant need to improve the properties of these devices and the methods for production of these devices.

These properties of the devices especially include the energy efficiency with which an electronic device solves the problem defined. In the case of organic light-emitting diodes, the light yield in particular should be sufficiently high that a minimum amount of electrical power has to be applied to achieve a particular luminous flux. In addition, a minimum voltage should also be necessary to achieve a defined luminance. A further particular problem is the lifetime of the electronic devices.

One of the problems addressed by the present invention was therefore that of providing compositions which can firstly be processed as a solution and which secondly lead to an improvement in the properties of the device, especially of the OLED, when used in electronic or optoelectronic devices, preferably in OLEDs, and here especially in the hole injection and/or hole transport layer thereof. Moreover, the composition should be processible in a very simple and inexpensive manner.

It has been found that, surprisingly, metal complexes having a metal atom of groups 13 to 15 and at least one ligand, where the ligand comprises at least one anionic coordination group having at least one oxygen and/or nitrogen atom via which the metal atom is coordinated, and the ligand comprises at least one triarylamine group, especially in the case of use for production of the hole-injecting and/or hole-transporting layer of OLEDs, lead to a distinct lowering of the voltage to achieve a given luminance, a reduction in the electrical power needed to attain a particular luminous flux, and an increase in the lifetime of these OLEDs. It has been found here that, surprisingly, the components of the metal complexes, i.e. the ligands and the metal atoms, interact in a synergistic manner without having any adverse effect on other properties. Particular advantages can especially be achieved by using a metal complex of the invention in a hole injection layer. Preferably, the metal complexes of the invention can be converted in a particularly simple and inexpensive manner to layers which can subsequently be provided with further layers without having to take particular measures that would prevent alteration of the metal complex-containing layer.

The present application thus provides a metal complex having a metal atom of groups 13 to 15 and at least one ligand, where the ligand comprises at least one anionic coordination group having at least one oxygen and/or nitrogen atom through which the metal atom is coordinated, and the ligand comprises at least one triarylamine group.

The term “ligand” herein refers to a low molecular weight, oligomeric or polymeric compound through which one or more metal atoms are coordinated. Ligands usable in accordance with the invention comprise at least one triarylamine group. Triarylamine groups are groups which have at least one nitrogen atom bonded to at least three aromatic and/or heteroaromatic ring systems, where the nitrogen atom is bonded directly to each aromatic and/or heteroaromatic group.

Preferred triarylamine groups comprise at least one structural element of the following formula (I):

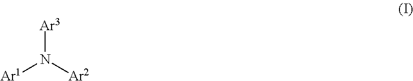

where
Ar¹, Ar² and Ar³ are the same or different at each instance and are a mono- or polycyclic, aromatic or heteroaromatic ring system which may be substituted by one or more R radicals;
R is the same or different at each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 40 carbon atoms, each of which may be substituted by one or more R¹ radicals, where one or more nonadjacent CH₂ groups may be replaced by R¹C═CR¹, C≡C, Si(R¹)₂, C═O, C═S, C═NR¹, P(═O)R¹, SO, SO₂, NR¹, O, S or CONR¹ and where one or more hydrogen atoms may be replaced by D, F, Cl, Br, I or CN, or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals; where two or more R radicals together may also form a mono- or polycyclic, aliphatic, aromatic and/or benzofused ring system;
R¹ is the same or different at each instance and is H, D, F or an aliphatic, aromatic and/or heteroaromatic hydrocarbyl radical having 1 to 20 carbon atoms, in which one or more hydrogen atoms may also be replaced by F; where two or more R¹ substituents together may also form a mono- or polycyclic, aliphatic or aromatic ring system.

It is possible here for the structural element of formula (I) to be bonded to one or more anionic coordination groups via the Ar¹, Ar², Ar³ radicals and/or a substituent of these radicals, for example the R radical.

The term “mono- or polycyclic aromatic ring system” is understood in the present application to mean an aromatic ring system which has 6 to 60, preferably 6 to 30 and more preferably 6 to 24 aromatic ring atoms and does not necessarily contain only aromatic groups, but in which it is also possible for two or more aromatic units to be interrupted by a short nonaromatic unit (<10% of the atoms other than H, preferably <5% of the atoms other than H), for example an sp³-hybridized carbon atom or oxygen or nitrogen atom, a CO group, etc. For example, systems such as 9,9′-spirobifluorene, 9,9-diarylfluorene and 9,9-dialkylfluorene, for example, shall also be regarded as aromatic ring systems.

The aromatic ring systems may be mono- or polycyclic, meaning that they may have one ring (e.g. phenyl) or two or more rings which may also be fused (e.g. naphthyl) or covalently bonded (e.g. biphenyl), or contain a combination of fused and bonded rings.

Preferred aromatic ring systems are, for example, phenyl, biphenyl, terphenyl, [1,1′:3′,1″]terphenyl-2′-yl, quarterphenyl, naphthyl, anthracene, binaphthyl, phenanthrene, dihydrophenanthrene, pyrene, dihydropyrene, chrysene, perylene, tetracene, pentacene, benzopyrene, fluorene, indene, indenofluorene and spirobifluorene.

The term “mono- or polycyclic heteroaromatic ring system” is understood in the present application to mean an aromatic ring system having 5 to 60, preferably 5 to 30 and more preferably 5 to 24 aromatic ring atoms, where one or more of these atoms is/are a heteroatom. The “mono- or polycyclic heteroaromatic ring system” does not necessarily contain only aromatic groups, but may also be interrupted by a short nonaromatic unit (<10% of the atoms other than H, preferably <5% of the atoms other than H), for example an sp³-hybridized carbon atom or oxygen or nitrogen atom, a CO group, etc.

The heteroaromatic ring systems may be mono- or polycyclic, meaning that they may have one ring or two or more rings which may also be fused or covalently bonded (e.g. pyridylphenyl), or contain a combination of fused and bonded rings. Preference is given to fully conjugated heteroaryl groups.

Preferred heteroaromatic ring systems are, for example, 5-membered rings such as pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings such as pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, or groups having several rings, such as carbazole, indenocarbazole, indole, isoindole, indolizine, indazole, benzimidazole, benzotriazole, purine, naphthimidazole, phenanthrimidazole, pyridimidazole, pyrazinimidazole, quinoxalinimidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzoisoquinoline, acridine, phenothiazine, phenoxazine, benzopyridazine, benzopyrimidine, quinoxaline, phenazine, naphthyridine, azacarbazole, benzocarboline, phenanthridine, phenanthroline, thieno[2,3-b]thiophene, thieno[3,2-b]thiophene, dithienothiophene, isobenzothiophene, dibenzothiophene, benzothiadiazothiophene or combinations of these groups.

The mono- or polycyclic, aromatic or heteroaromatic ring system may be unsubstituted or substituted. “Substituted” in the present application means that the mono- or polycyclic, aromatic or heteroaromatic ring system has one or more R substituents.

R is preferably the same or different at each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 40 carbon atoms, each of which may be substituted by one or more R¹ radicals, where one or more nonadjacent CH₂ groups may be replaced by R¹C═CR¹, C≡C, Si(R¹)₂, C═O, C═S, C═NR¹, P(═O)R¹, SO, SO₂, NR¹, O, S or CONR¹ and where one or more hydrogen atoms may be replaced by D, F, Cl, Br, I or CN, or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals; at the same time, two or more R radicals together may also form a mono- or polycyclic, aliphatic, aromatic and/or benzofused ring system.

R is more preferably the same or different at each instance and is H, D, F, Cl, Br, I, N(R¹)₂, Si(R¹)₃, B(OR¹)₂, C(═O)R¹, P(═O)(R¹)₂, a straight-chain alkyl or alkoxy group having 1 to 20 carbon atoms or an alkenyl or alkynyl group having 2 to 20 carbon atoms or a branched or cyclic alkyl or alkoxy group having 3 to 20 carbon atoms, each of which may be substituted by one or more R¹ radicals, where one or more nonadjacent CH₂ groups may be replaced by R¹C═CR¹, C≡C, Si(R¹)₂, C═O, C═NR¹, P(═O)R¹, NR¹, O or CONR¹ and where one or more hydrogen atoms may be replaced by F, Cl, Br or I, or an aromatic or heteroaromatic ring system which has 5 to 30 aromatic ring atoms and may be substituted in each case by one or more R¹ radicals, or an aryloxy or heteroaryloxy group which has 5 to 30 aromatic ring atoms and may be substituted by one or more R¹ radicals, or an aralkyl or heteroaralkyl group which has 5 to 30 aromatic ring atoms and may be substituted by one or more R¹ radicals, or a diarylamino group, diheteroarylamino group or arylheteroarylamino group which has 10 to 20 aromatic ring atoms and may be substituted by one or more R¹ radicals; at the same time, two or more R radicals together may also form a mono- or polycyclic, aliphatic, aromatic and/or benzofused ring system.

R is even more preferably the same or different at each instance and is H, a straight-chain alkyl or alkoxy group having 1 to 10 carbon atoms or an alkenyl or alkynyl group having 2 to 10 carbon atoms or a branched or cyclic alkyl or alkoxy group having 3 to 10 carbon atoms, each of which may be substituted by one or more R¹ radicals, where one or more nonadjacent CH₂ groups may be replaced by R¹C═CR¹, C≡C, C═O, C═NR¹, NR¹, O or CONR¹, or an aromatic or heteroaromatic ring system which has 5 to 20 aromatic ring atoms and may be substituted in each case by one or more R¹ radicals, or an aryloxy or heteroaryloxy group which has 5 to 20 aromatic ring atoms and may be substituted by one or more R¹ radicals, or an aralkyl or heteroaralkyl group which has 5 to 20 aromatic ring atoms and may be substituted by one or more R¹ radicals, or a diarylamino group, diheteroarylamino group or arylheteroarylamino group which has 10 to 20 aromatic ring atoms and may be substituted by one or more R¹ radicals; at the same time, two or more R radicals together may also form a mono- or polycyclic, aliphatic, aromatic and/or benzofused ring system.

Preferred alkyl groups having 1 to 10 carbon atoms are depicted in the following table:

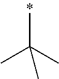

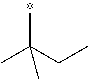

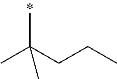

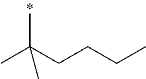

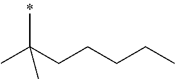

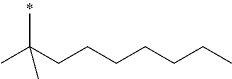

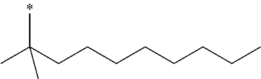

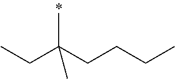

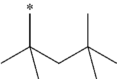

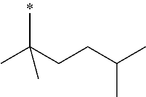

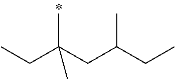

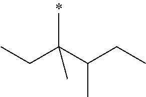

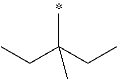

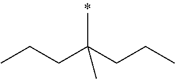

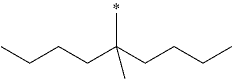

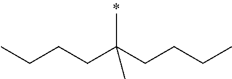

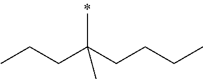

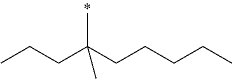

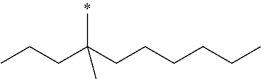

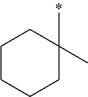

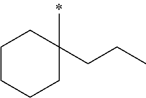

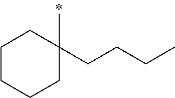

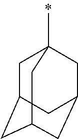

R¹ is preferably the same or different at each instance and is H, D, F or an aliphatic hydrocarbyl radical having 1 to 20 carbon atoms, an aromatic and/or a heteroaromatic hydrocarbyl radical having 5 to 20 carbon atoms, in which one or more hydrogen atoms may also be replaced by F; at the same time, two or more R¹ substituents together may also form a mono- or polycyclic, aliphatic or aromatic ring system.

R¹ is more preferably the same or different at each instance and is H, D or an aliphatic hydrocarbyl radical having 1 to 20 carbon atoms, an aromatic and/or a heteroaromatic hydrocarbyl radical having 5 to 20 carbon atoms; at the same time, two or more R¹ substituents together may also form a mono- or polycyclic, aliphatic or aromatic ring system.

R¹ is even more preferably the same or different at each instance and is H or an aliphatic hydrocarbyl radical having 1 to 10 carbon atoms, an aromatic and/or a heteroaromatic hydrocarbyl radical having 5 to 10 carbon atoms.

The ligand comprises at least one anionic coordination group having at least one oxygen and/or nitrogen atom via which at least one metal atom is coordinated, such that at least one of the Ar¹, Ar² and Ar³ radicals is bonded covalently to at least one anionic coordination group.

The term “coordination group” refers to the atoms involved in the coordination of the metal atom. These atoms therefore interact with the metal atom or are involved in this interaction via delocalization of the anionic charge which can be assigned at least in a formal sense to the coordination group. In this context, the anionic coordination group preferably has exactly one charge which can be delocalized over the coordination group, and so the coordination group is preferably monoanionic.

It may preferably be the case that the ligand comprises at least two spatially far-removed anionic coordination groups via which two metal atoms can be complexed. “Spatially far-removed” preferably means that the anionic coordination groups are separated by at least 4, preferably at least 6 and more preferably at least 10 bonds. This configuration can achieve crosslinking of the ligands via coordination of metal atoms. The effect of this crosslinking is that devices comprising these metal complexes can be produced in a particularly simple and inexpensive manner. By sufficient crosslinking, it is possible to obtain an insoluble metal complex. “Insoluble” in the context of the present invention preferably means that the metal complex of the invention, after the crosslinking reaction, i.e. after the reaction of the ligand with the metal atom, has a lower solubility at room temperature in an organic solvent by at least a factor of 3, preferably at least a factor of 10, than that of the corresponding non-crosslinked ligand of the invention in the same organic solvent.

In addition, it may be the case that the ligand comprises at least one anionic coordination group via which at least bidentate coordination of the metal atom is possible, in which case coordination can be effected via at least one oxygen and/or nitrogen atom.

Preferably, at least one anionic coordination group in the ligand may comprise a structure of formula (K-I):

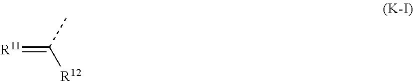

in which R¹¹ and R¹² may each independently be oxygen, sulphur, selenium, NH or NR¹³ where R¹³ is selected from the group comprising alkyl and aryl and may be bonded to other groups in the ligand, and the dotted line represents the bond of the coordination group to the ligand. The anionic charge is not shown in the formula (I) since it can be partly delocalized. Preferred anionic coordination groups are carboxylate groups (—CO₂⁻), thiocarboxylate groups (—CSO⁻), amidate groups (—CNR¹³O⁻), (—CNHO⁻), and thioamidate groups (—CNR¹³S⁻), (—CNHS⁻). Among these, preference is given to carboxylate groups (—CO₂-) and thiocarboxylate groups (—CSO⁻), and particular preference to carboxylate groups (—CO₂⁻) Preferably, at least one anionic coordination group is bonded by a bonding group to the triarylamine group of the ligand, such that the anionic coordination group provided with a bonding group can be represented by a structure of formula (K-II):

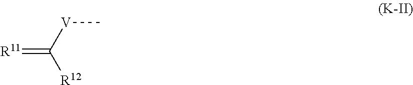

in which R¹¹ and R¹² may each independently be oxygen, sulphur, selenium, NH or NR¹³ where R¹³ is selected from the group comprising alkyl and aryl and may be bonded to other groups in the ligand, V is a bond or a bonding group selected from an aromatic or heteroaromatic ring system which has 5 to 40 aromatic ring atoms and may be substituted in each case by one or more R radicals, an alkylene group which has 1 to 40 carbon atoms and may be substituted in each case by one or more R radicals, where one or more nonadjacent CH₂ groups may be replaced by RC═CR, C≡C, Si(R)₂, C═O, C═S, C═NR, P(═O)R, SO, SO₂, NR, O, S or CONR and where one or more hydrogen atoms may be replaced by D, F, Cl, Br, I or CN, where the R radical is as defined above for formula (I), and the dotted line represents the bond of the coordination group to the triarylamine group.

The V radical in formula (K-II) may preferably represent a straight-chain alkylene, alkoxy or thioalkoxy group having 1 to 40 carbon atoms or an alkenyl or alkynyl group having 2 to 40 carbon atoms or a branched or cyclic alkyl, alkoxy or thioalkoxy group having 3 to 40 carbon atoms, each of which may be substituted by one or more R¹ radicals, where one or more nonadjacent CH₂ groups may be replaced by R¹C═CR¹, C≡C, Si(R¹)₂, C═O, C═S, C═NR¹, P(═O)R¹, SO, SO₂, NR¹, O, S or CONR¹ and where one or more hydrogen atoms may be replaced by D, F, Cl, Br, I or CN, or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals; where the V radical may also form a ring system together with one or both of the R¹¹ and R¹² radicals, where R¹ may assume the definition given above.

It may preferably be the case that the V radical in formula (K-II) is selected from the group comprising alkylene, long-chain alkylene, alkoxy, long-chain alkoxy, cycloalkylene, haloalkylene, aryl, arylenes, haloaryl, heteroaryl, heteroarylenes, heterocycloalkylenes, heterocycloalkyl, haloheteroaryl, alkenyl, haloalkenyl, alkynyl, haloalkynyl, ketoaryl, haloketoaryl, ketoheteroaryl, ketoalkyl, haloketoalkyl, ketoalkenyl, haloketoalkenyl, preferably having 1 to 40 and more preferably 1 to 20 carbon atoms, where, in the case of suitable radicals, one or more nonadjacent CH₂ groups may independently be replaced by —O—, —S—, —NH—, —NR—, —SiR₂—, —CO—, —COO—, —OCO—, —OCO—O—, —SO₂—, —S—CO—, —CO—S—, —CR═CR— or —C═C—, in such a way that no oxygen and/or sulphur atoms are bonded directly to one another, and likewise optionally by aryl or heteroaryl preferably containing 1 to 30 carbon atoms (terminal CH₃ groups are regarded as CH₂ groups in the sense of CH₂—H), where R may assume the definition given above, especially for formula (I).

Long-chain alkyl groups especially have, with regard to the description of the R¹¹, R¹², R¹³ and V radicals in formula (K-I) and (K-III), preferably 5 to 20 carbon atoms. Alkyl groups not given the “long-chain” attribute may especially have, with regard to the description of the R¹¹, R¹², R¹³ and V radicals in formula (K-I) and (K-III), preferably 1 to 10 and more preferably 1 to 4 carbon atoms. The description and definition especially of the preferred groups detailed in the context of the formula (K-I) and (K-II) can be found, inter alia, in WO 2013/182389 A2 filed on 14 May 2013 at the European Patent Office with application number PCT/EP2013/059911, the disclosure of this document being incorporated into the description of the present application by reference.

Preferably, the V radical in formula (K-II) may represent a bond or a bonding group selected from an arylene group having 6 to 24 carbon atoms and a heteroarylene group having 3 to 24 carbon atoms, each of which may be substituted by one or more R¹ radicals, an alkylene group which has 1, 2, 3, 4, 5, 6, 7, 8, 9, 10, 11 or 12 carbon atoms and may be substituted by one or more R¹ radicals, where the R¹ radical may be as defined for formula (I).

In a further configuration of the present invention, it is possible to use a metal complex in which the V radical shown in formula (K-III) has at least one substituent selected from halogen, pseudohalogen, —CN, —NO₂.

It is possible to use a metal complex in which the V radical shown in formula (K-II) corresponds to one of the formulae (V-I), (V-II) and (V-III):

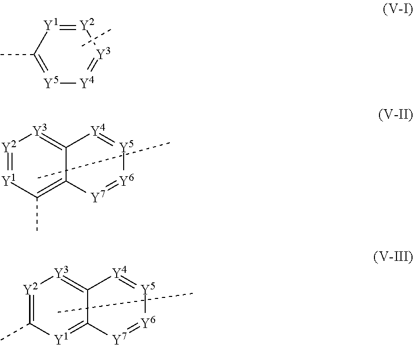

in which the Y¹ to Y⁷ groups are each independently selected from the group comprising C—H, C—R², C—F, C—CF₃, C—NO₂, C—CN, C-halogen, C-pseudohalogen and N, where the group selected from Y¹ to Y⁷ which binds to the triarylamine group is C, and a dotted line represents the bond to the carbon atom to which the R¹¹ and/or R¹² radicals bind, the R² radical is an alkyl group having 1 to 20 and preferably 1 to 10 carbon atoms, in which it is also possible for one or more hydrogen atoms to be replaced by F, or an aromatic or heteroaromatic ring system having 5 to 40 carbon atoms, preferably 5 to 30 and more preferably 5 to 24, which may be substituted by the R radicals detailed above, and a dotted line represents the bond to the triarylamine group. It may preferably be the case that at least one and more preferably at least two of the Y¹ to Y⁷ groups is/are independently selected from the group comprising C—F, C—CF₃, C—NO₂, C—CN, C-halogen, C-pseudohalogen and N. Preferably, the symbol R² is an aryl radical, and so an aromatic group of an aromatic ring system is bonded to the carbon atom of the C—R² group.

In a preferred embodiment, the V radical shown in formula (K-II) is selected from the group comprising halogenated, preferably perhalogenated and/or pseudohalogenated, pteridines, isopteridines, naphthyridines, quinoxalines, azaquinoxalines.

In addition, it may be the case that the V radical shown in formula (K-II) has or consists of one or more of the following structures:

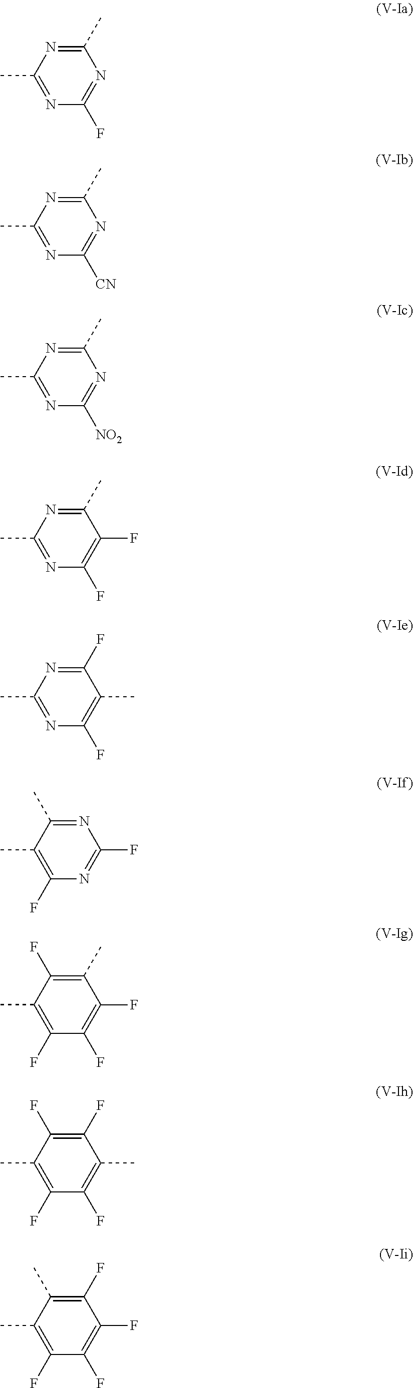

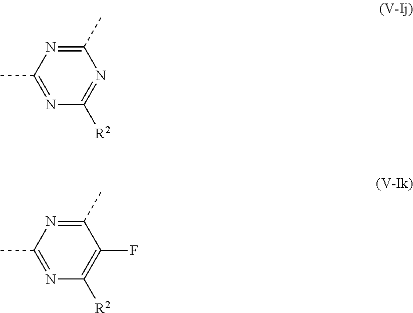

where the dotted line represents the attachment site and R² is as defined above.

It may preferably be the case that the V radical in formula (K-II) is substituted by fluorine, in which case preferably at least 10% of the hydrogen atoms and more preferably at least 50% of the hydrogen atoms are replaced by fluorine and, more preferably, V represents a perfluorinated group.

In a preferred embodiment, the V radical in formula (K-II) is haloalkenyl, more preferably perfluoroalkenyl having 1 to 8 carbons, more preferably 1 to 4, haloaryl, more preferably perfluoroaryl, haloalkylaryl, more preferably (per)fluoroalkylaryl and haloheteroaryl, more preferably perfluoroheteroaryl, where these groups may preferably have 6 to 20 carbon atoms.

In one embodiment, the ligand in the metal complex may be a low molecular weight compound, in which case the ligand preferably has a molecular weight of not more than 10 000 g/mol, more preferably not more than 5000 g/mol, particularly preferably not more than 4000 g/mol, especially preferably not more than 3000 g/mol, specifically preferably not more than 2000 g/mol and most preferably not more than 1000 g/mol.

The ligand may be a compound comprising structures of the following formula (L-I):

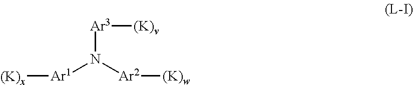

where
Ar¹, Ar² and Ar³ are each the same or different at each instance and are as defined above, especially for formula (I), K represents an anionic coordination group, preferably a group of formula (K-I) and/or (K-III),
v=0, 1, 2, 3, 4, 5, 6 or 7, preferably 0, 1, 2, 3 or 4, more preferably 0, 1 or 2;
w=0, 1, 2, 3, 4, 5, 6 or 7, preferably 0, 1, 2, 3 or 4, more preferably 0, 1 or 2; and
x=0, 1, 2, 3, 4, 5, 6 or 7, preferably 0, 1, 2, 3 or 4, more preferably 0, 1 or 2,
   where the sum of v, w and x is not less than 1, preferably not less than 2.

The sum of v, w and x may preferably be in the range from 1 to 10, more preferably 2 to 7 and especially preferably 3 to 5.

Preferably, the ligand may be represented by a structure of the formula (I) and/or (L-I).

It may additionally be the case that the ligand is a polymer. The ligand may preferably be a polymer comprising at least one structural unit of the following formula (P-I):

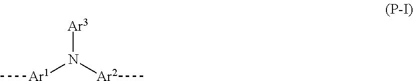

where
Ar¹, Ar² and Ar³ are each the same or different at each instance and are as defined above, especially for formula (I), and
the dotted lines represent bonds to adjacent structural units in the polymer,
where the Ar¹, Ar² and Ar³ groups in the structural unit (P-I) may be substituted by at least one anionic coordination group, preferably a group of formula (K-I) and/or (K-II).

In this case, all the structural units of formula (P-I) or only a portion of the structural units of formula (P-I) may be substituted by at least one anionic coordination group, preferably a group of formula (K-I) and/or (K-II).

Preferably, a polymeric ligand of formula (P-I) comprises structural units in which the Ar¹, Ar² and Ar³ groups are not substituted by an anionic coordination group, and so the structural units do not comprise any anionic coordination group.

Preferably, a polymeric ligand may comprise at least one structural unit of the following formula (L-P-I):

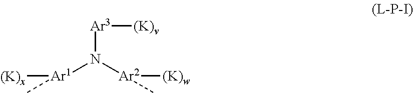

where
Ar¹, Ar² and Ar³ are each the same or different at each instance and are as defined above, especially for formula (I), K represents an anionic coordination group, preferably a group of formula (K-I) and/or (K-II),
v=0, 1, 2, 3, 4, 5, 6 or 7,
w=0, 1, 2, 3, 4, 5, 6 or 7, and
x=0, 1, 2, 3, 4, 5, 6 or 7,
   where the sum of v, w and x is not less than 1, preferably not less than 2, and
   the dotted lines represent bonds to adjacent structural units in the polymer.

In the present application, the term “polymer” is understood to mean polymeric compounds, oligomeric compounds and dendrimers. The polymeric compounds of the invention have preferably 10 to 10 000, more preferably 10 to 5000 and most preferably 10 to 2000 structural units (i.e. repeat units). The inventive oligomeric compounds preferably have 3 to 9 structural units. The branching factor of the polymers is between 0 (linear polymer, no branching sites) and 1 (fully branched dendrimer).

The polymers usable in accordance with the invention preferably have a molecular weight M_{w} in the range from 1000 to 2 000 000 g/mol, more preferably a molecular weight M_{w} in the range from 10 000 to 1 500 000 g/mol and most preferably a molecular weight M_{w} in the range from 50 000 to 1 000 000 g/mol. The molecular weight M_{w} is determined by means of GPC (=gel permeation chromatography) against an internal polystyrene standard. M_{w} is the weight-average molecular weight.

The polymers of the invention are conjugated, semi-conjugated or non-conjugated polymers. Preference is given to conjugated or semi-conjugated polymers.

According to the invention, the structural units of the formula (P-I) may be incorporated into the main chain or side chain of the polymer. Preferably, however, the structural units of the formula (P-I) are incorporated into the main chain of the polymer. In the case of incorporation into the side chain of the polymer, the structural units of the formula (P-I) may either be mono- or bivalent, meaning that they have either one or two bonds to adjacent structural units in the polymer.

“Conjugated polymers” in the context of the present application are polymers containing mainly sp²-hybridized (or else optionally sp-hybridized) carbon atoms in the main chain, which may also be replaced by correspondingly hybridized heteroatoms. In the simplest case, this means the alternating presence of double and single bonds in the main chain, but also polymers having units such as a meta-bonded phenylene, for example, should also be regarded as conjugated polymers in the context of this application. “Mainly” means that defects that occur naturally (involuntarily) and lead to interrupted conjugation do not make the term “conjugated polymer” inapplicable. Conjugated polymers are likewise considered to be polymers having a conjugated main chain and non-conjugated side chains.

In addition, the present application likewise refers to conjugation when, for example, arylamine units, arylphosphine units, particular heterocycles (i.e. conjugation via nitrogen, oxygen or sulphur atoms) and/or organometallic complexes (i.e. conjugation by the metal atom) are present in the main chain. The same applies to conjugated dendrimers. In contrast, units such as simple alkyl bridges, (thio)ether, ester, amide or imide linkages, for example, are unambiguously defined as non-conjugated segments.

A semi-conjugated polymer shall be understood in the present application to mean a polymer containing conjugated regions separated from one another by non-conjugated sections, deliberate conjugation breakers (for example spacer groups) or branches, for example in which comparatively long conjugated sections in the main chain are interrupted by non-conjugated sections, or containing comparatively long conjugated sections in the side chains of a polymer non-conjugated in the main chain. Conjugated and semiconjugated polymers may also contain conjugated, semi-conjugated or non-conjugated dendrimers.

The term “dendrimer” in the present application shall be understood to mean a highly branched compound formed from a multifunctional core to which monomers branched in a regular structure are bonded, such that a tree-like structure is obtained. In this case, both the core and the monomers may assume any desired branched structures consisting both of purely organic units and organometallic compounds or coordination compounds. “Dendrimeric” shall generally be understood here as described, for example, by M. Fischer and F. Vögtle (Angew. Chem., Int. Ed. 1999, 38, 885).

The term “structural unit” in the present application is understood to mean a unit which, proceeding from a monomer unit having at least two, preferably two, reactive groups, by a bond-forming reaction, is incorporated into the polymer base skeleton as a portion thereof and is present thus bonded as a repeat unit within the polymer prepared.

Preferably, at least one of the Ar¹, Ar² and Ar³ radicals in formula (I), formula (L-I), formula (P-I) and/or formula (L-P-I) may comprise at least one R substituent having at least 2 carbon atoms, preferably at least 4 and most preferably at least 6 carbon atoms. Particularly advantageously, this substituent having 2 carbon atoms displays a C═C double bond between these 2 carbon atoms or this substituent having 2 carbon atoms is part of a mono- or polycyclic, aromatic or heteroaromatic ring system having 5 to 60 aromatic ring atoms.

In a first preferred configuration, it may be the case that the Ar³ radical in formula (I), (L-I), (P-I) and/or (L-P-I) is substituted by Ar⁴ in at least one ortho position, preferably in exactly one of the two ortho positions, based on the position of the nitrogen atom shown in formula (I), (L-I), (P-I) and/or (L-P-I), where Ar⁴ is a mono- or polycyclic, aromatic or heteroaromatic ring system which has 5 to 60 aromatic ring atoms and may be substituted by one or more R radicals, where R may assume the definition given above, especially for formula (I), where the Ar⁴ radical may be substituted by one or more anionic coordination groups, preferably a group of formula (K-I) and/or (K-II).

Ar⁴ may be joined to Ar³ either directly, i.e. by a single bond, or else via a linking group X. Preferably, an aromatic group in the Ar⁴ radical may be bonded directly to an aromatic group in the Ar³ radical.

The triarylamine group of the formula (I) may comprise at least one structural element selected from a structural element of the following formula (Ia) or the polymer may comprise at least one structural unit of the formula (P-I) selected from a structural unit of the following formula (P-Ia), preferably selected from a structural unit of the following formula (L-P-Ia):

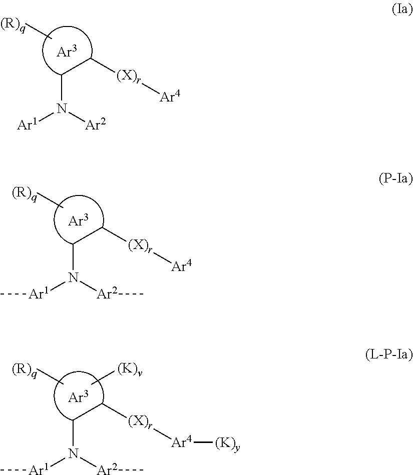

where Ar¹, Ar², Ar³ and R may assume the definitions given above, especially for formula (I), Ar⁴ is a mono- or polycyclic, aromatic or heteroaromatic ring system which has 5 to 60 aromatic ring atoms and may be substituted by one or more R radicals, where R may assume the definition given above, especially for formula (I), K is an anionic coordination group, preferably a group of formula (K-I) and/or (K-II), the dotted lines represent bonds to adjacent structural units in the polymer,
q=0, 1, 2, 3, 4, 5 or 6, preferably 0, 1, 2, 3 or 4,
X=CR₂, NR, SiR₂, NR, CK₂, NK, SiK₂, CRK, SiRK, O, S, C═O or (P═O)R, preferably CR₂, SiR₂, NR, CK₂, NK, SiK₂, CRK, SiRK, O or S, where R may assume the definition given above, especially for formula (I), and K represents an anionic coordination group, preferably a group of formula (K-I) and/or (K-II), and
r=0 or 1, preferably 0,
v=0, 1, 2 or 3, preferably 0, 1 or 2, more preferably 0 or 1,
y=0, 1, 2 or 3, preferably 0, 1 or 2, more preferably 0 or 1,
   where the sum of v and y is not less than 1.

It may preferably be the case that Ar³ in formula (I), (L-I), (P-I) and/or (L-P-I) is substituted by Ar⁴ in one of the two ortho positions, and Ar³ is additionally joined to Ar⁴ in the meta position adjacent to the substituted ortho position.

The triarylamine group of the formula (I) may comprise at least one structural element selected from a structural element of the following formula (Ib) or the polymer may comprise at least one structural unit of the formula (P-I) selected from a structural unit of the following formula (P-Ib), preferably selected from a structural unit of the following formula (L-P-Ib):

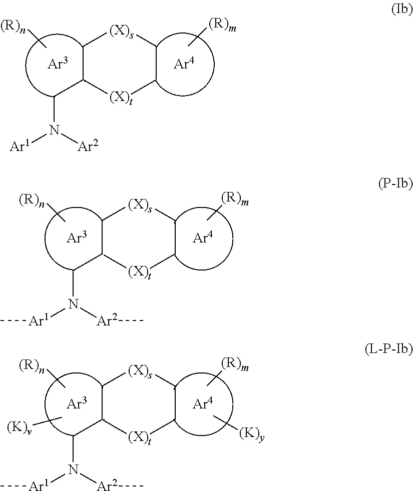

where Ar¹, Ar², Ar³, Ar⁴, R and X may assume the definitions given above, especially for the formulae (I) and (Ia), K represents an anionic coordination group, preferably a group of formula (K-I) and/or (K-II), the dotted lines represent bonds to adjacent structural units in the polymer;
m=0, 1, 2, 3 or 4, preferably 0, 1 or 2, more preferably 0 or 1;
n=0, 1, 2 or 3, preferably 0, 1 or 2, more preferably 0 or 1;
s and t are each 0 or 1, where the sum of (s+t)=1 or 2;
v=0, 1, 2 or 3, preferably 0, 1 or 2, more preferably 0,
y=0, 1, 2 or 3, preferably 0, 1 or 2, more preferably 1,
   where the sum of v and y is not less than 1.

It may additionally be the case that the sum total of the ring atoms of the Ar⁴ radical together with the ring atoms of the Ar³ group bonded to said radical of formulae (Ia), (P-Ia), (Ib) and/or (P-Ib) is at least 12. Preferably, the Ar⁴ radical does not form a fused ring system with the ring atoms of the Ar³ group bonded to said radical of formulae (Ia), (P-Ia), (Ib) and/or (P-Ib).

In addition, preferred radicals are Ar⁴ groups having a low condensation level, and so preference is given to monocyclic, aromatic or heteroaromatic ring systems or to polycyclic, aromatic or heteroaromatic ring systems wherein the aromatic or heteroaromatic rings are bonded via groups which minimize or eliminate conjugation of the rings.

In a preferred embodiment, the at least one structural element of the formula (I) is selected from the structural elements of the following formulae (II), (III) and (IV) or the at least one structural unit of the formula (P-I) is selected from the structural units of the following formulae (P-II), (P-III) and (P-IV):

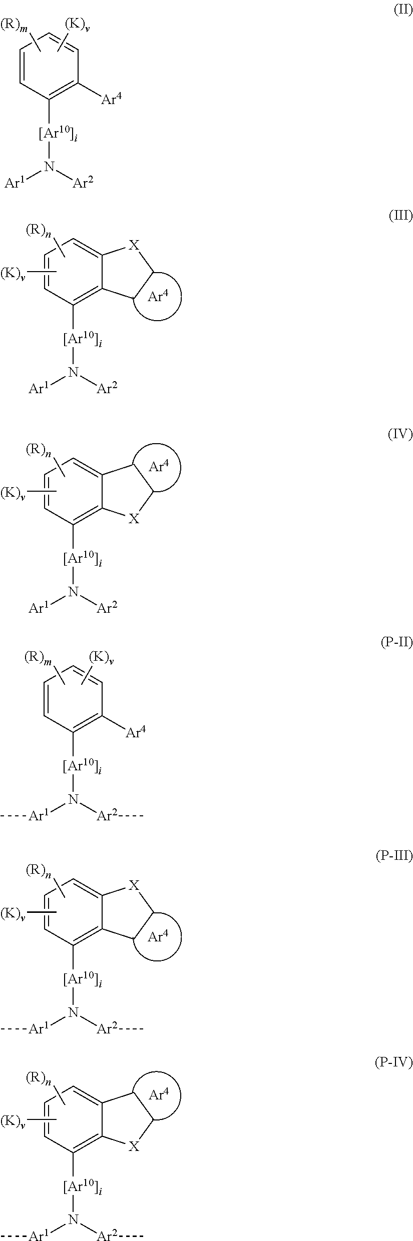

where Ar¹, Ar², Ar⁴, R, K, v, m, n and X may assume the definitions given above, especially for the formulae (I), (Ia) and (Ib), Ar¹⁰ is a mono- or polycyclic, aromatic or heteroaromatic ring system which has 5 to 60, preferably 5 to 30 and more preferably 5 to 24 aromatic ring atoms and may be substituted by one or more R radicals, where R may assume the definition given above, especially for formula (I), the index i is 0, 1 or 2, preferably 0 or 1 and especially preferably 0, and the dotted lines represent bonds to adjacent structural units in the polymer, where the Ar¹, Ar², Ar⁴ and R groups may be substituted by at least one anionic coordination group, preferably a group of formula (K-I) and/or (K-II). Preferably, the symbol Ar¹⁰ represents an aryl radical, and so an aromatic group in the Ar¹⁰ radical is bonded to the phenyl radical which is bonded to the Ar⁴ radical, and/or to the nitrogen atom.

In a particularly preferred embodiment, it may be the case that at least one structural element of the formula (II) is selected from the structural unit of the following formula (V) or a structural unit of the formula (P-III) is selected from a structural unit of the following formula (P-V):

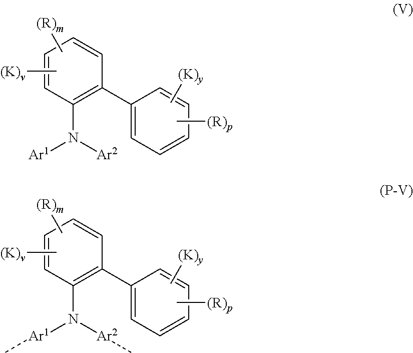

where Ar¹, Ar², K, R, m, v and y may assume the definitions given above, especially for the formulae (I), (la) and (lb), the dotted lines represent bonds to adjacent structural units in the polymer, and

p=0,1, 2, 3,4 or 5.

Examples of preferred structural elements of the formula (V) are depicted in the following table:

| | |
|---|---|
| 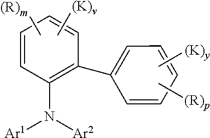 | (Va) |
| 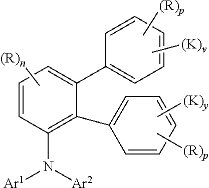 | (Vb) |
| 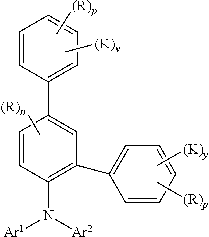 | (Vc) |
| 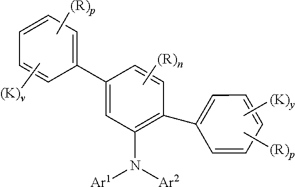 | (Vd) |
| 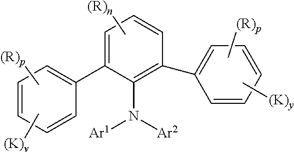 | (Ve) |
| 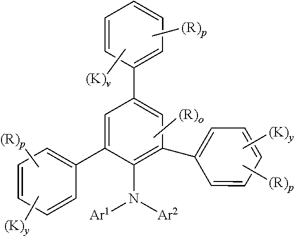 | (Vf) |
| 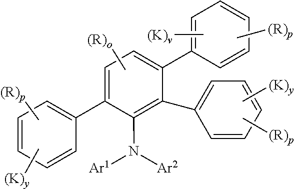 | (Vg) |
| 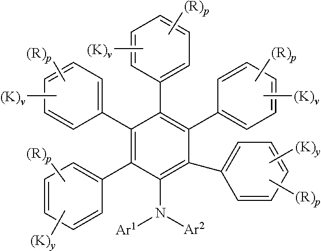 | (Vh) |

where Ar¹, Ar², R, m, n, p, v and y may assume the definitions given above, especially for formulae (I), (Ib) and/or (V), and
o=0, 1 or 2.

Examples of preferred structural units of the formula (P-V) are depicted in the following table:

| | |
|---|---|
| 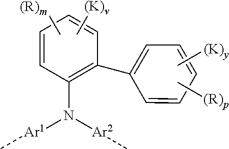 | (P-Va) |
| 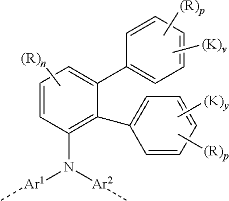 | (P-Vb) |
| 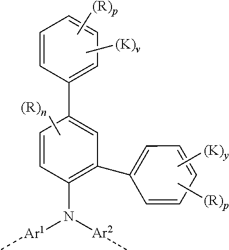 | (P-Vc) |
| 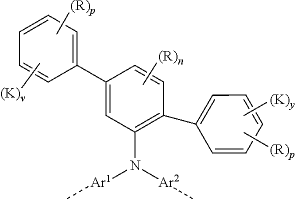 | (P-Vd) |
| 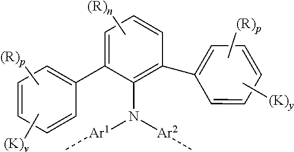 | (P-Ve) |
| 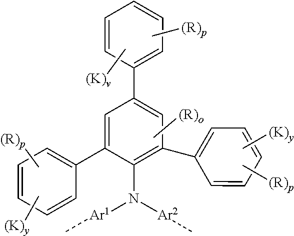 | (P-Vf) |
| 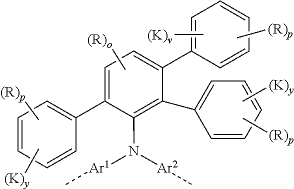 | (P-Vg) |
| 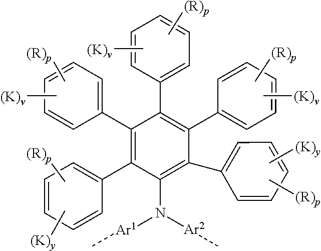 | (P-Vh) |

where Ar¹, Ar², R, m, n, p, v, y and the dotted lines may each be as defined above for formulae (P-I), (P-Ib) and/or (P-V), and
o=0, 1 or 2.

In a further particularly preferred embodiment, it may be the case that at least one structural element of the formula (III) is selected from the structural unit of the following formula (VI) or a structural unit of the formula (P-III) is selected from a structural unit of the following formula (P-VI):

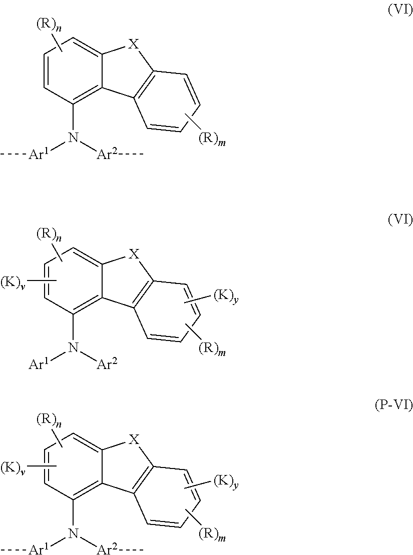

where Ar¹, Ar², R, K, v, y, m, n and X may assume the definitions given above, especially for formulae (I), (Ib) and/or (V), and the dotted lines represent bonds to adjacent structural units in the polymer.

Examples of preferred structural elements of the formula (VI) are depicted in the following table:

| | |
|---|---|
| 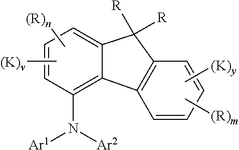 | (VIa) |
| 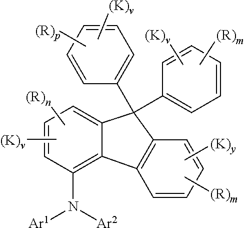 | (VIb) |
| 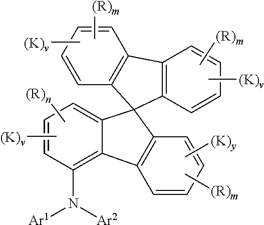 | (VIc) |
| 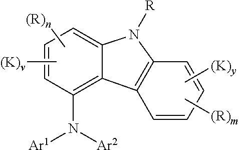 | (VId) |
| 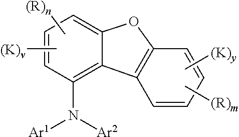 | (VIe) |
| 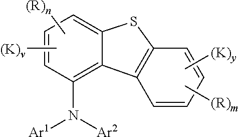 | (VIf) |

where Ar¹, Ar², R, K, v, y, m, n and X may assume the definitions given above, especially for formulae (I), (Ib) and/or (V).

Examples of preferred structural units of the formula (P-VI) are depicted in the following table:

| | |
|---|---|
| 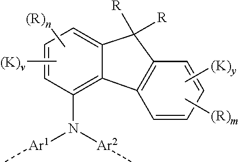 | (P-VIa) |
| 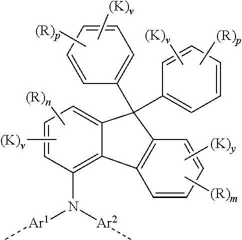 | (P-VIb) |
| 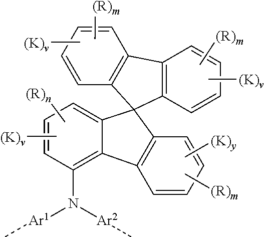 | (P-VIc) |
| 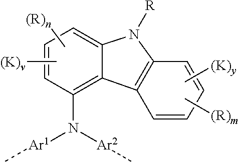 | (P-VId) |
| 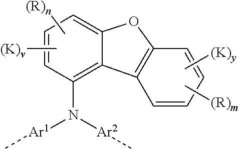 | (P-VIe) |
| 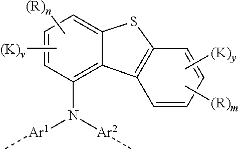 | (P-VIf) |

where Ar¹, Ar², R, K, v, y, m, n and X may assume the definitions given above, especially for formulae (I), (Ib) and/or (V), and the dotted lines represent bonds to adjacent structural units in the polymer.

In yet a further particularly preferred embodiment, it may be the case that at least one structural element of the formula (IV) is selected from the structural unit of the following formula (VII) or a structural unit of the formula (P-IV) is selected from a structural unit of the following formula (P-VII):

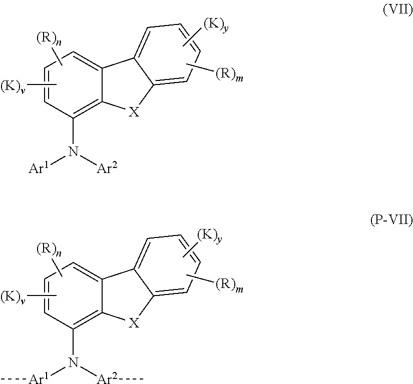

where Ar¹, Ar², R, K, v, y, m, n and X may assume the definitions given above, especially for formulae (I), (Ib) and/or (V), and the dotted lines represent bonds to adjacent structural units in the polymer.

Examples of preferred structural elements of the formula (VII) are depicted in the following table:

| | |
|---|---|
| 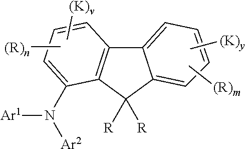 | (VIIa) |
| 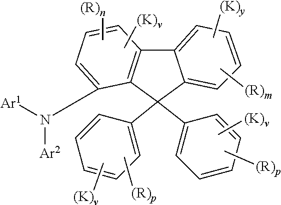 | (VIIb) |
| 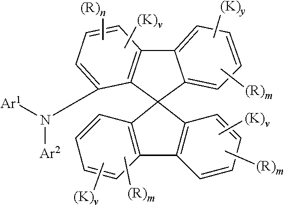 | (VIIc) |
| 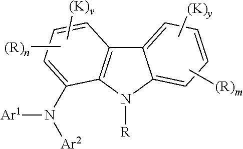 | (VIId) |
| 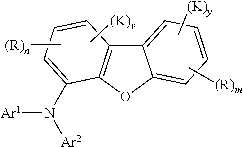 | (VIle) |
| 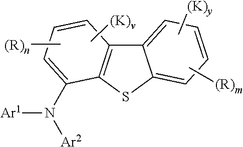 | (VIIf) |

where Ar¹, Ar², R, K, v, y, m and n may assume the definitions given above, especially for formulae (I), (Ib) and/or (V).

Examples of preferred structural units of the formula (P-VII) are depicted in the following table:

(P-VIIa)

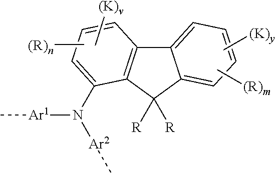

(P-VIIb)

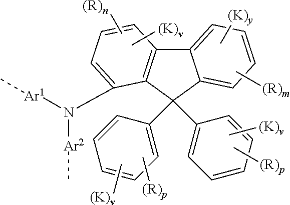

(P-VIIc)

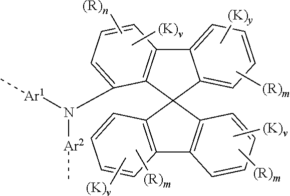

(P-VIId)

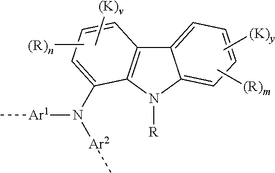

(P-VIIe)

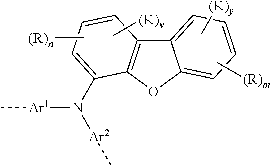

(P-VIIf)

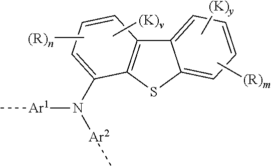

where Ar¹, Ar², R, K, v, y, m and n may assume the definitions given above, especially for formulae (I), (Ib) and/or (V), and the dotted lines represent bonds to adjacent structural units in the polymer.

In a very particularly preferred embodiment, it may be the case that at least one structural element of the formula (V) is selected from the structural element of the following formula (Vi) or a structural unit of the formula (P-V) is selected from a structural unit of the following formula (P-Vi):

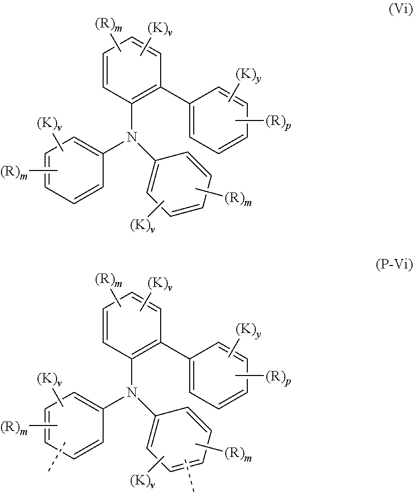

where R, m, p, v, y and the dotted lines may assume the definitions given above, especially for formulae (I), (Ib) and/or (V).

Examples of preferred structural elements of the formula (Vi) are depicted in the following table:

(Vi-1)

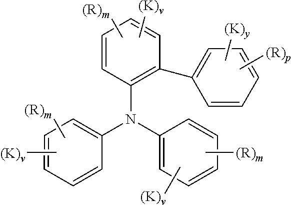

(Vi-2)

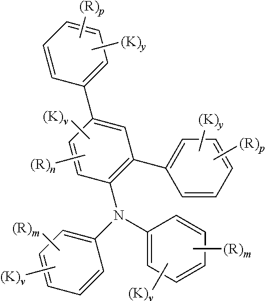

(Vi-3)

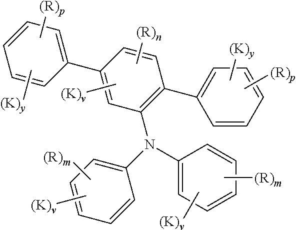

(Vi-4)

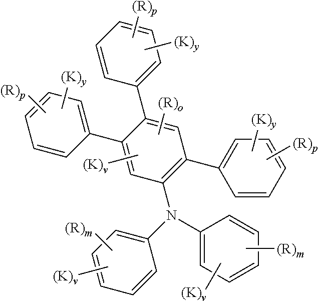

(Vi-5)

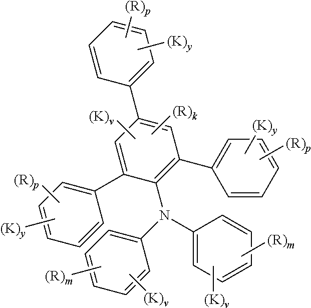

(Vi-6)

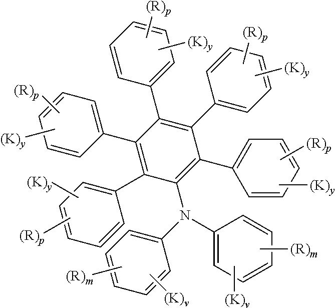

(Vi-7)

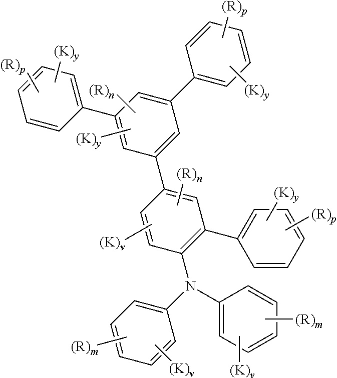

(Vi-8)

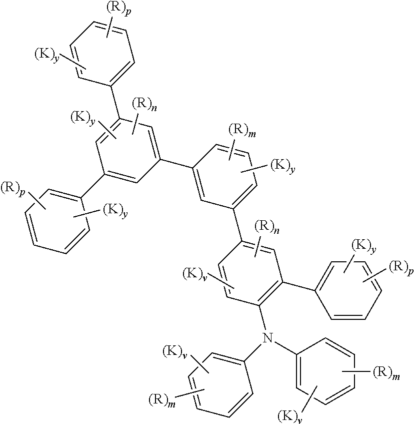

where R, m, n, p, v and y may assume the definitions given above, especially for formulae (I), (Ib) and/or (V), and o is 0, 1 or 2.

Examples of preferred structural units of the formula (P-Vi) are depicted in the following table:

(P-Vi-1)

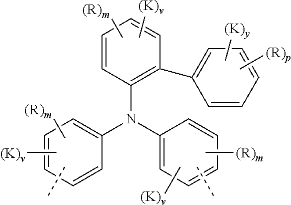

(P-Vi-2)

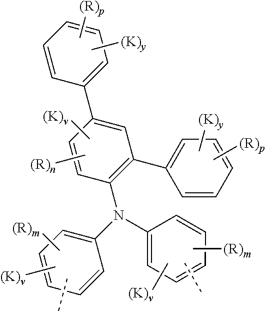

(P-Vi-3)

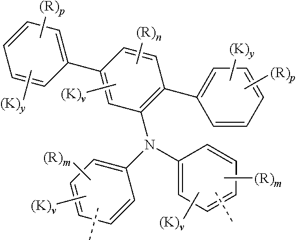

(P-Vi-4)

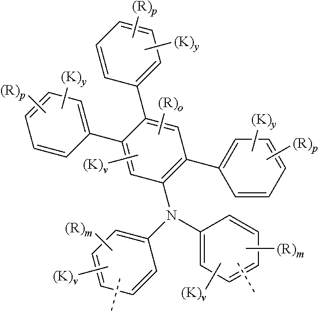

(P-Vi-5)

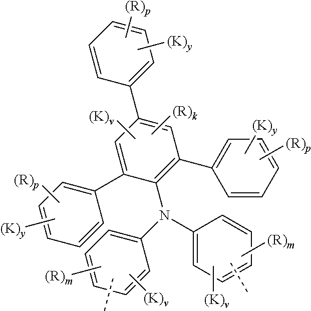

(P-Vi-6)

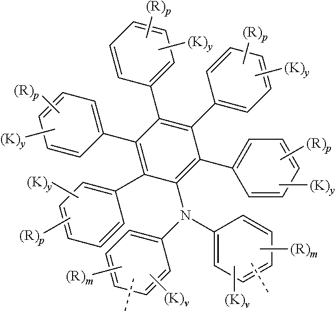

(P-Vi-7)

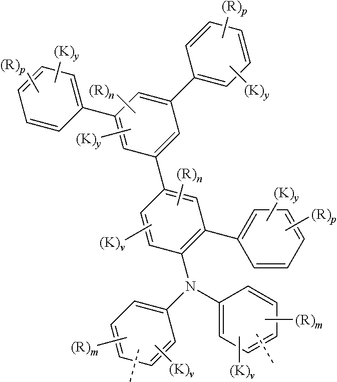

(P-Vi-8)

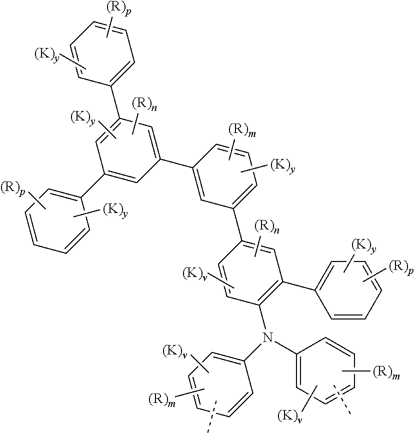

where R, m, n, p, v, y and the dotted lines may assume the definitions given above, especially for formulae (I), (Ib) and/or (V), and o is 0, 1 or 2.

In a further very particularly preferred embodiment, it may be the case that at least one structural element of the formula (VI) is selected from the structural element of the following formula (VIg) or a structural unit of the formula (P-VI) is selected from a structural unit of the following formula (P-VIg):

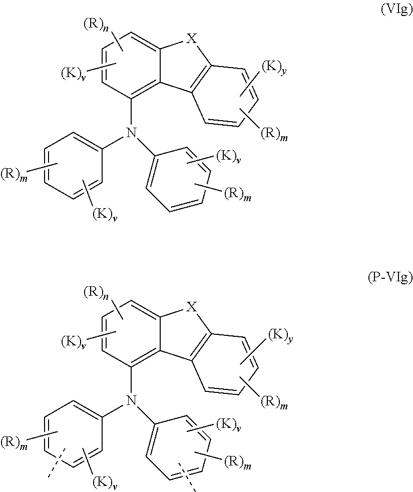

where R, m, n, v, y and the dotted lines may assume the definitions given above, especially for formulae (I), (Ib) and/or (VI).

Examples of preferred structural elements of the formula (VIg) are depicted in the following table:

(VIg-1)

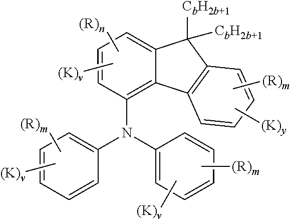

(VIg-2)

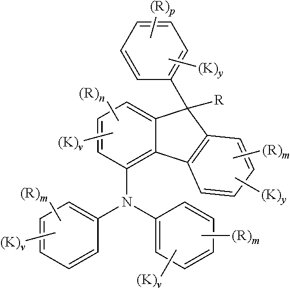

(VIg-3)

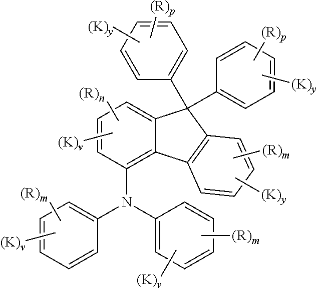

(VIg-4)

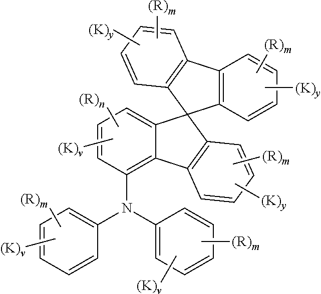

(VIg-5)

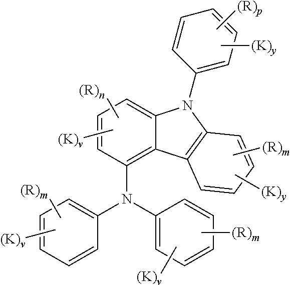

(VIg-6)

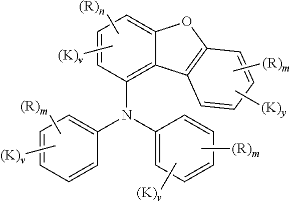

(VIg-7)

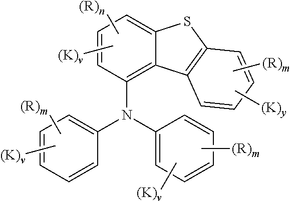

where R, m, n, p, v and y may assume the definitions given above, especially for formulae (I), (Ib) and/or (VI), and
b=1 to 20, preferably 1 to 10.

Examples of preferred structural units of the formula (P-VIg) are depicted in the following table:

(P-VIg-1)

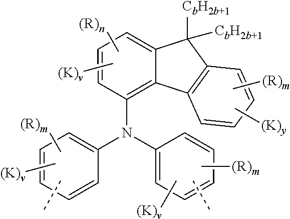

(P-VIg-2)

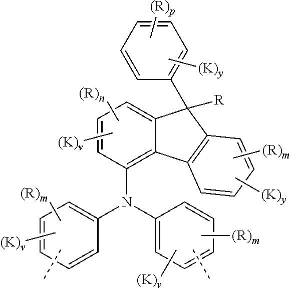

(P-VIg-3)

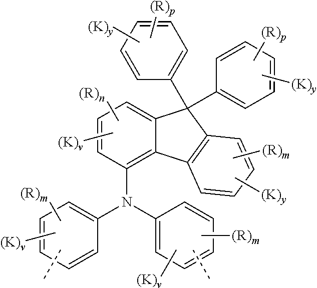

(P-VIg-4)

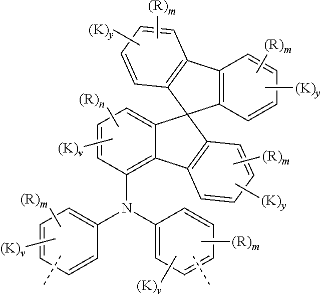

(P-VIg-5)

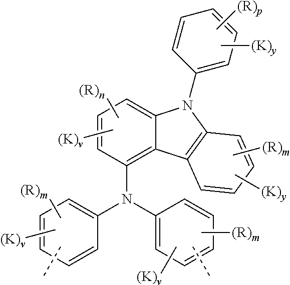

(P-VIg-6)

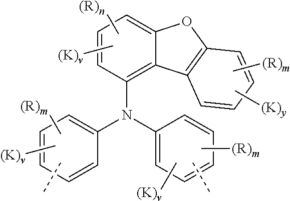

(P-VIg-7)

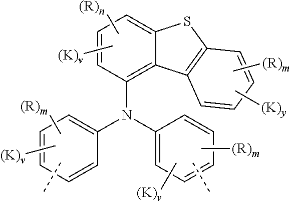

where R, m, n, p, v, y and the dotted lines may assume the definitions given above, especially for formulae (I), (Ib) and/or (VI), and
b=1 to 20, preferably 1 to 10.

In yet a further very particularly preferred embodiment, it may be the case that at least one structural element of the formula (VII) is selected from the structural element of the following formula (VIIg) or a structural unit of the formula (P-VII) is selected from a structural unit of the following formula (P-VIIg):

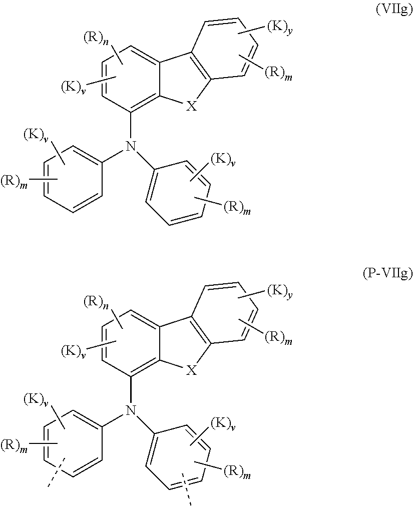

where R, m, n, v, y, X and the dotted lines may assume the definitions given above, especially for formulae (I), (Ib) and/or (VII).

Examples of preferred structural elements of the formula (VIIg) are depicted in the following table:

(VIIg-1)

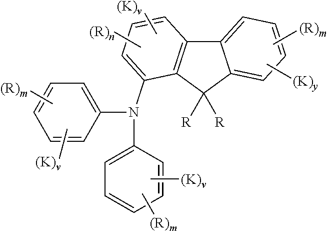

(VIIg-2)

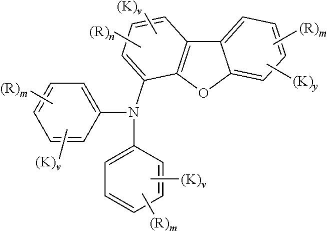

(VIIg-3)

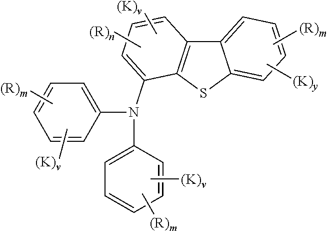

where R, m, n, v and y may assume the definitions given above, especially for formulae (I), (Ib) and/or (VII).

Examples of preferred structural units of the formula (P-VIIg) are depicted in the following table:

(P-VIIg-1)

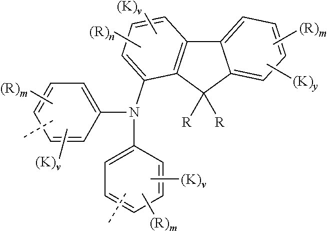

(P-VIIg-2)

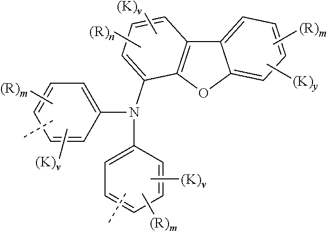

(P-VIIg-3)

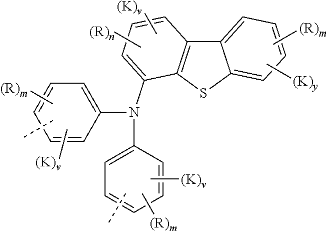

where R, m, n, v, y and the dotted lines may assume the definitions given above, especially for formulae (I), (Ib) and/or (VII).

In the formulae (P-Vi), (P-VIg) and (P-VIIg) and their preferred embodiments of the formulae (P-Vi-1) to (P-Vi-7), (P-VIg-1) to (P-VIg-7) and (P-VIIg-1) to (P-VIIg-3), the dotted lines represent the bonds to the adjacent structural units in the polymer. They may independently be arranged identically or differently in the ortho, meta or para position, preferably identically in the ortho, meta or para position, more preferably in the meta or para position and most preferably in the para position.

Preferably, the ligand may be represented by a structure of the formula (II) to (VII) or preferred embodiments of these structures.

In a further preferred configuration of the present invention, it may be the case that the ligand is a polymer comprising at least one structural unit of the formula (P-I) selected from a structural unit of the following formula (P-VIIIa):

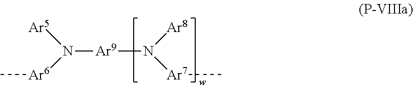

and/or a structural unit of the following formula (P-VIIIb):

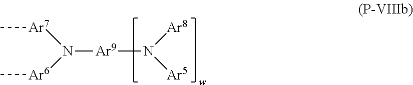

where z is 1, 2 or 3, Ar⁵ to Ar⁹ are each the same or different at each instance and are a mono- or polycyclic, aromatic or heteroaromatic ring system which may be substituted by one or more R radicals, where R may assume the definition given above, especially for formula (I); the dotted lines represent bonds to adjacent structural units in the polymer; where the Ar¹, Ar², Ar³, Ar⁴, Ar⁵, Ar⁶, Ar⁷, Ar⁸ and Ar⁹ groups in the structural units (P-VIIIa) and/or (P-VIIIb) may be substituted by one or more anionic coordination groups, preferably at least one group of formula (K-I) and/or (K-III).

It may preferably be the case that the Ar¹, Ar², Ar³, Ar⁴, Ar⁵, Ar⁶, Ar⁶, Ar⁷, Ar⁸ and Ar⁹ groups in the structural units (P-VIIIa) and (P-VIIIb) are not substituted by an anionic coordination group, such that these structural units do not comprise any anionic coordination groups.

Preferably, a polymeric ligand may comprise at least one structural unit of the following formula (L-P-I) selected from a structural unit of the following formula (L-P-VIIIa):

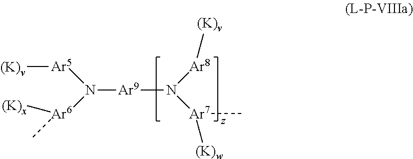

and/or a structural unit of the following formula (L-P-VIIIb):

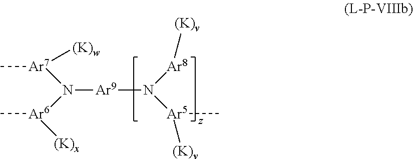

where z=1, 2 or 3, Ar⁵ to Ar⁹ are each the same or different at each instance and are a mono- or polycyclic, aromatic or heteroaromatic ring system which may be substituted by one or more R radicals, where R may be as defined in Claim 2; K represents an anionic coordination group, preferably a group of formula (K-I) and/or (K-II);
v=0, 1, 2, 3, 4, 5, 6 or 7, preferably 0, 1, 2, 3 or 4, more preferably 0, 1 or 2;
w=0, 1, 2, 3, 4, 5, 6 or 7, preferably 0, 1, 2, 3 or 4, more preferably 0, 1 or 2; and
x=0, 1, 2, 3, 4, 5, 6 or 7, preferably 0, 1, 2, 3 or 4, more preferably 0, 1 or 2,
   where the sum of v, w and x is not less than 1 and
   the dotted lines represent bonds to adjacent structural units in the polymer.

The sum of v, w and x in formulae (L-P-VIIa) and/or (L-P-VIIIb) may preferably be in the range from 1 to 10, more preferably 1 to 5 and especially preferably 1 to 3.

Preferably, at least one of the Ar⁵ to Ar⁹ radicals in formulae (P-VIIIa), (P-VIIIb), (L-P-VIIIa) and/or (L-P-VIIIb) may comprise at least one R substituent having at least 2 carbon atoms, preferably at least 4 and more preferably at least 6 carbon atoms, where R may assume the definition given above, especially for formula (I). Particularly advantageously, this substituent having 2 carbon atoms displays a C—C double bond between these 2 carbon atoms or this substituent having 2 carbon atoms is part of a mono- or polycyclic, aromatic or heteroaromatic ring system having 5 to 60 aromatic ring atoms.

It may preferably be the case that at least one of the Ar⁵ and/or Ar⁸ radicals in formulae (P-VIIIa), (P-VIIIb), (L-P-VIIIa) and/or (L-P-VIIIb) is substituted by Ar⁴ in at least one ortho position, preferably in exactly one of the two ortho positions, based on the position of the nitrogen atom shown in formula (P-VIIIa), (P-VIIb), (L-P-VIIIa) and/or (L-P-VIIIb), where Ar⁴ is a mono- or polycyclic, aromatic or heteroaromatic ring system which has 5 to 60 aromatic ring atoms and may be substituted by one or more R radicals, where R may assume the definition given above, especially for formula (I), where the Ar⁴ radical may be substituted by one or more anionic coordination groups, preferably at least one group of formula (K-I) and/or (K-II).

It may additionally be the case that the sum total of the ring atoms of the Ar⁴ radical together with the ring atoms of the Ar⁵ or Ar⁸ group bonded to said radical of formulae (P-VIIIa), (P-VIIIb), (L-P-VIIIa) and/or (L-P-VIIIb) is at least 12. Preferably, the Ar⁴ radical together with the ring atoms of the Ar⁵ or Ar⁸ group bonded to said radical in formulae (P-VIIIa), (P-VIIIb), (L-P-VIIIa) and/or (L-P-VIIIb) does not form a fused ring system. In addition, preferred radicals are Ar⁴ groups having a low condensation level, and so preference is given to monocyclic, aromatic or heteroaromatic ring systems or to polycyclic, aromatic or heteroaromatic ring systems wherein the aromatic or heteroaromatic rings are bonded via groups which minimize or eliminate conjugation of the rings.

Ar⁴ can be bonded to at least one of the Ar⁵ and/or Ar⁸ radicals in formulae (P-VIIIa), (P-VIIIb), (L-P-VIIIa) and/or (L-P-VIIIb) either directly, i.e. via a single bond, or else via a linking group X. Preferably, an aromatic group in the Ar⁴ radical may be bonded directly to an aromatic group in the Ar⁵ and/or Ar⁸ radicals.

The structural unit of the formula (P-VIIIa) may thus preferably have the structure of the following formulae (P-VIIIa-1a), (P-VIIIa-1 b), (P-VIIIa-1c) and (P-VIIIa-1d):

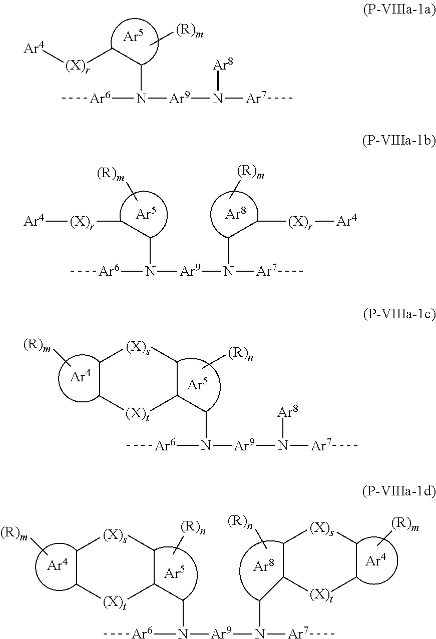

where Ar⁴, Ar⁵, Ar⁶, Ar⁷, Ar⁸, Ar⁹, X, m, n, r, s, t, R and the dotted lines may assume the definitions given above, especially for the formulae (P-I), (P-Ia), (P-Ib) and (P-VIIIa), where at least one of the Ar⁴, Ar⁵, Ar⁶, Ar⁷, Ar⁸, Ar⁹ and/or X groups may be substituted by at least one anionic coordination group, preferably at least one group of formula (K-I) and/or (K-III).

In addition, the structural unit of the formula (P-VIIIa) and/or (P-VIIIIIb) may thus have a structure of the following formulae (P-VIIIb-a), (P-VIIIb-b), (P-VIIIb-c) and/or (P-VIIb-d):

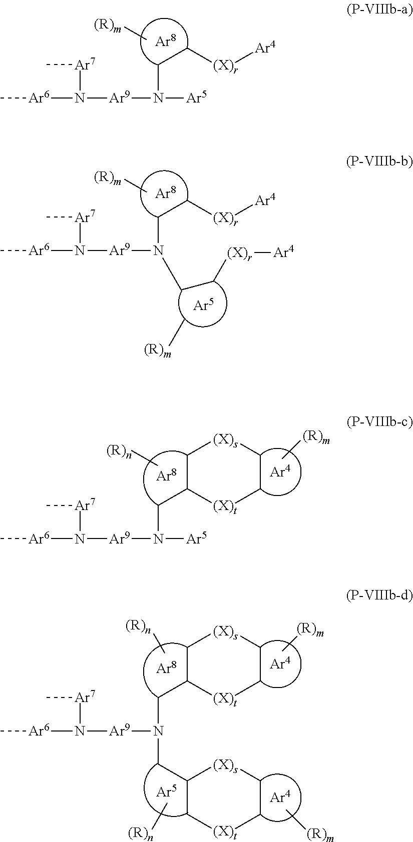

where Ar⁴, Ar⁵, Ar⁶, Ar⁷, Ar⁸, Ar⁹, X, m, n, s, t and R may assume the definitions given above, especially for the formulae (P-I), (P-Ia), (P-Ib), (P-VIIIa) and (P-VIIb), where at least one of the Ar⁴, Ar⁵, Ar⁶, Ar⁷, Ar⁸, Ar⁹ and/or X groups may be substituted by at least one anionic coordination group, preferably at least one group of formula (K-I) and/or (K-II).

In a preferred embodiment, the at least one structural unit of the formula (P-VIIIa) is selected from structural units of the following formulae (P-IX), (P-X), (P-XI), (P-XII), (P-XIII), (P-XIV), (P-XV) and (P-XVI):

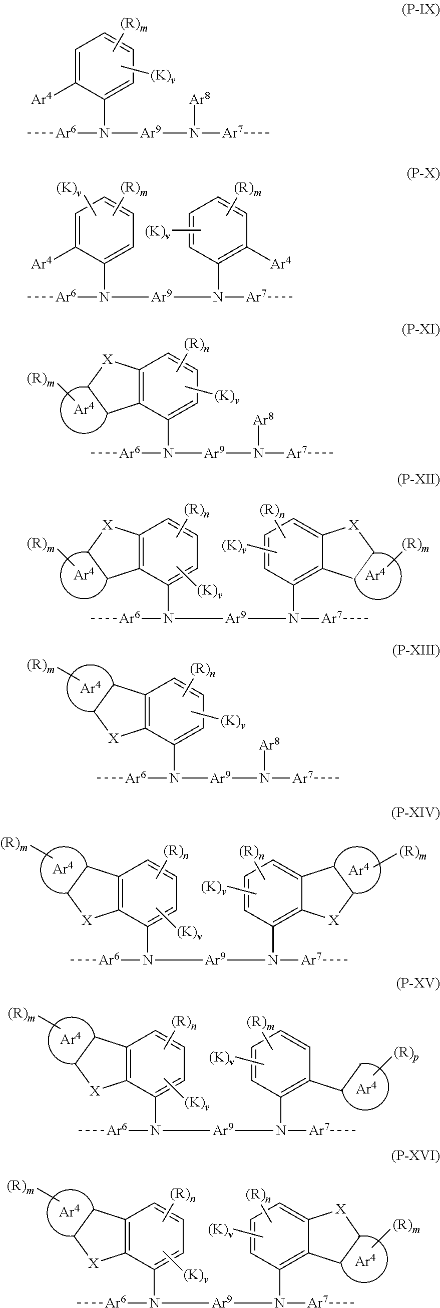

where Ar⁴, Ar⁵, Ar⁶, Ar⁷, Ar⁸, Ar⁹, X, v, m, n, p, R and the dotted lines may assume the definitions given above, especially for the formulae (P-I), (P-Ia), (P-Ib), (P-VIIIa), (L-P-VIIIa), (P-VIIIb) and (L-P-VIIIb).

In a particularly preferred embodiment, the structural units of the formulae (P-IX) and (P-X) are selected from the structural units of the following formulae (P-IXa) and (P-Xa):

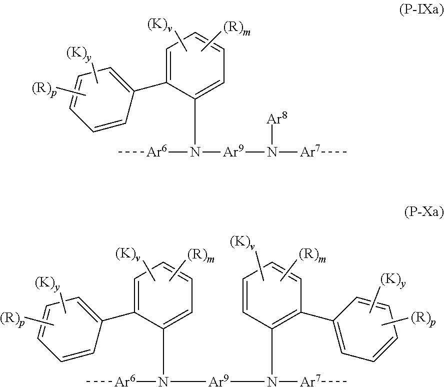

where Ar⁶, Ar⁷, Ar⁸, Ar⁹, R, m, p, v, y and the dotted lines may assume the definitions given above, especially for the formulae (P-I), (P-Ia), (P-Ib), (P-VIIIa), (L-P-VIIIa), (P-VIIIb) and (L-P-VIIIb).

In a further particularly preferred embodiment, the structural units of the formulae (P-XI) and (P-XII) are selected from the structural units of the following formulae (P-XIa) and (P-XIIa):

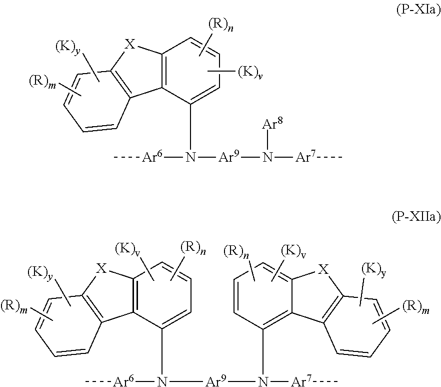

where Ar⁶, Ar⁷, Ar⁸, Ar⁹, R, m, n, v, y and X may assume the definitions given above, especially for the formulae (P-I), (P-Ia), (P-Ib), (P-VIIIa), (L-P-VIIIa), (P-VIIIb) and (L-P-VIIIb).

In another further particularly preferred embodiment, the structural units of the formulae (P-XIII) and (P-XIV) are selected from the structural units of the following formulae (P-XIIIa) and (P-XIVa):

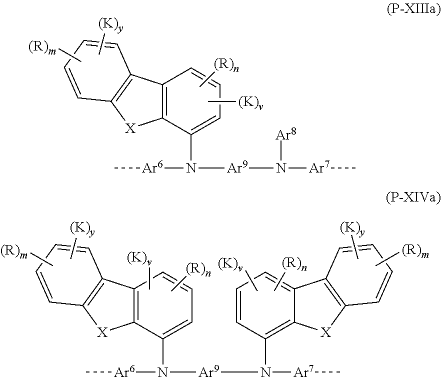

where Ar⁶, Ar⁷, Ar⁸, Ar⁹, R, m, n, v, y and X may assume the definitions given above, especially for the formulae (P-I), (P-Ia), (P-Ib), (P-VIIIa), (L-P-VIIIa), (P-VIIIb) and (L-P-VIIIb).

In a very particularly preferred embodiment, the structural units of the formulae (P-IXa) and (P-Xa) are selected from the structural units of the following formulae (P-IXb) and (P-Xb):

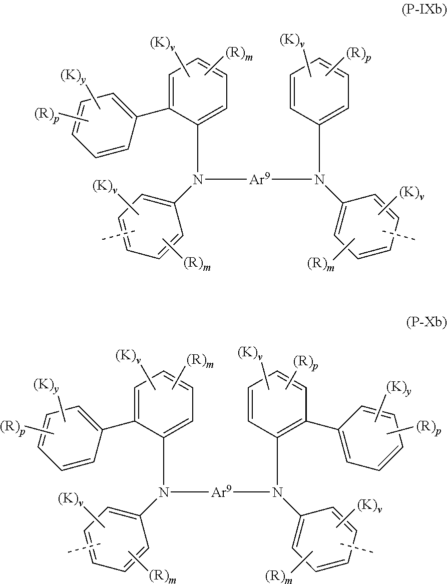

where Ar⁹, R, m p, v and y may assume the definitions given above, especially for the formulae (P-I), (P-Ia), (P-Ib), (P-VIIIa), (L-P-VIIIa), (P-VIIIb) and (L-P-VIIIb).

In a further very particularly preferred embodiment, the structural units of the formulae (P-XIa) and (P-XIIa) are selected from the structural units of the following formulae (P-XIb) and (P-XIIIb):

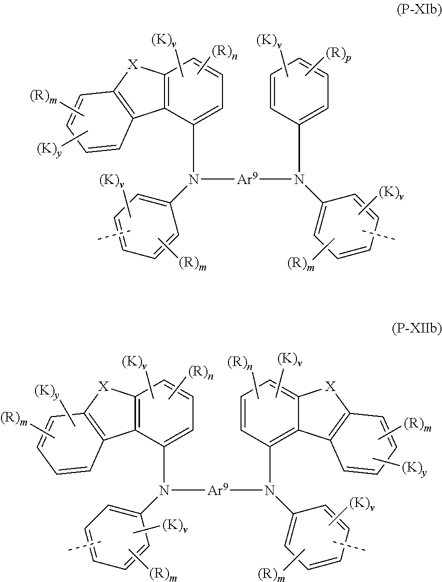

where Ar⁹, R, X, m, n, p, v and y may assume the definitions given above, especially for the formulae (P-I), (P-Ia), (P-Ib), (P-VIIIa), (L-P-VIIIa), (P-VIIIb) and (L-P-VIIIb).

In yet another further very particularly preferred embodiment, the structural units of the formulae (P-XIIIa) and (P-XIVa) are selected from the structural units of the following formulae (P-XIIb) and (P-XIVb):

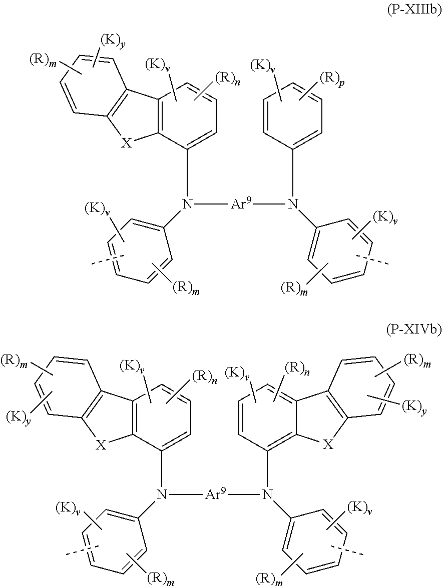

where R, X, m, n, p, v and y may assume the definitions given above, especially for the formulae (P-I), (P-Ia), (P-Ib), (P-VIIIa), (L-P-VIIIa), (P-VIIb) and (L-P-VIIIb).

In the formulae (P-IXa) to (P-XIVa) and (P-IXb) to (P-XIVb), the dotted lines represent the bonds to the adjacent structural units in the polymer. They may independently be arranged identically or differently in the ortho, meta or para position, preferably identically in the ortho, meta or para position, more preferably in the meta or para position and most preferably in the para position.

In addition, it may be the case that at least one of the structural units of the formulae (I), (Ia), (Ib), (II), (III), (IV), (V), (VI), (VII), (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI) and/or of a preferred configuration of the structural units has at least one crosslinkable Q group.

“Crosslinkable Q group” in the context of the present invention means a functional group capable of entering into a reaction and thus forming an insoluble compound. In this context, a crosslinkable Q group differs from an anionic coordination group present in the ligand usable in accordance with the invention. The reaction may be with a further identical Q group, a further different Q group or any other portion of the same or another polymer chain. The crosslinkable group is thus a reactive group. This affords, as a result of the reaction of the crosslinkable group, a correspondingly crosslinked compound. The chemical reaction can also be conducted in the layer, giving rise to an insoluble layer. The crosslinking can usually be promoted by means of heat or by means of UV radiation, microwave radiation, x-radiation or electron beams, optionally in the presence of an initiator. “Insoluble” in the context of the present invention preferably means that the polymer of the invention, after the crosslinking reaction, i.e. after the reaction of the crosslinkable groups, has a lower solubility at room temperature in an organic solvent by at least a factor of 3, preferably at least a factor of 10, than that of the corresponding non-crosslinked polymer of the invention in the same organic solvent.

At least one crosslinkable group in the present application means that a structural unit has one or more crosslinkable groups. Preferably, a structural unit has exactly one crosslinkable group.

If the structural unit of the formula (I) has a crosslinkable group, it may be bonded to Ar¹, Ar² or Ar³. Preferably, the crosslinkable group is bonded to the monovalently bonded mono- or polycyclic aromatic or heteroaromatic ring system Ar³.

If the structural unit of the formula (P-VIIIa) or (P-VIIIb) has a crosslinkable group, it may be bonded to Ar⁵, Ar⁶, Ar⁷, Ar⁸ or Ar⁹. Preferably, the crosslinkable group is bonded to one of the monovalently bonded mono- or polycyclic aromatic or heteroaromatic ring systems, i.e. to Ar⁵ or Ar⁸.

Preferred crosslinkable Q groups are detailed inter alia in document DE 10 2009 010 714.2, which is incorporated herein for the purposes of the disclosure.

Preferably, the use of specific crosslinkable Q groups can be reduced or preferably completely dispensed with, since, in a preferred embodiment, crosslinking of a layer obtainable from the metal complexes of the invention is effected via the metal complexes.

It may further be the case that at least some of the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) comprise, in the polymer, at least one anionic coordination group having at least one oxygen and/or nitrogen atom.

The proportion of structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) having at least one anionic coordination group may preferably be in the range from 0 to 50 mol %, preferably in the range from 1 to 40 mol %, especially preferably 3 to 30 mol % and more preferably 5 to 20 mol %, based on the total number of structural units in the polymer.

It may additionally be the case that at least some of the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) do not comprise, in the polymer, any anionic coordination group having at least one oxygen and/or nitrogen atom.

The proportion of structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) which do not comprise any anionic coordination group having at least one oxygen and/or nitrogen atom may preferably be in the range from 50 to 100 mol %, preferably in the range from 60 to 99 mol %, especially preferably 70 to 97 mol % and more preferably 80 to 95 mol %, based on the total number of structural units in the polymer.

In a first preferred embodiment, the polymer of the invention contains only structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI) and/or a preferred configuration of the structural units, meaning that the proportion thereof in the polymer is 100 mol %. More preferably, the polymer of the invention comprises only exactly one kind of structural units of the formulae (P-I), (P-Ia), (P-Ib), (P-II), (P-III), (P-IV), (P-V), (P-VI), (P-VII), (P-VIIIa), (P-VIIb), (P-IX), (P-X), (P-XI), (P-XII), (P-XIII), (P-XIV), (P-XV), (P-XVI) and/or a preferred configuration of the structural units. In this case, the polymer of the invention is a homopolymer.

In a second preferred embodiment, the proportion of structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI) and/or a preferred configuration of these structural units in the polymer is in the range from 50 to 95 mol %, more preferably in the range from 60 to 95 mol %, based on 100 mol % of all the copolymerizable monomers present as structural units in the polymer, i.e. the polymer of the invention has, as well as one or more structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI) and/or a preferred configuration of these structural units, also further structural units other than the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI) and/or a preferred configuration of these structural units.

In a third preferred embodiment, the proportion of structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) in the polymer is in the range from 5 to 50 mol %, more preferably in the range from 25 to 50 mol %, based on 100 mol % of all the copolymerizable monomers present as structural units in the polymer, i.e. the polymer of the invention has, as well as one or more structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI), also further structural units other than the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI).

These structural units that are different from the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) include those as disclosed and listed comprehensively in WO 02/077060 A1 and in WO 2005/014689 A2. These are considered to form part of the present invention by reference.

It may preferably be the case that the polymer, as well as structural units of the formulae (L-P-I), (L-P-Ia), (L-P-Ib), (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI), contains at least one further structural unit of the following formula (P-XVII) which is different from the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI):

-----Ar¹¹----- (P-XVII)

where Ar¹¹ is a mono- or polycyclic, aromatic or heteroaromatic ring system which may be substituted by one or more R and/or K radicals, where R may assume the definitions given above, especially for formula (I), and K represents an anionic coordination group, preferably a group of formula (K-I) and/or (K-II), and
the dotted lines represent bonds to adjacent structural units in the polymer.

In a preferred configuration, the polymer may comprise structural units of formula (P-XVII) unsubstituted by an anionic coordination group. It may preferably be the case that the proportion of structural units of the formula (P-XVII) which do not comprise any anionic coordination group having at least one oxygen and/or nitrogen atom is in the range from 50 to 100 mol %, preferably in the range from 60 to 99 mol %, especially preferably 70 to 97 mol % and more preferably 80 to 95 mol %, based on the total number of structural units in the polymer.

It may further be the case that the polymer, as well as structural units of the formulae (P-I), (P-Ia), (P-Ib), (L-P-I), (L-P-Ia), (L-P-Ib), (P-II), (P-III), (P-IV), (P-V), (P-VI), (P-VI), (P-VIIIa), (P-VIIIb), (L-P-VIIIa), (L-P-VIIb), (P-IX), (P-X), (P-XI), (P-XII), (P-XIII), (P-XIV), (P-XV) and/or (P-XVI), contains at least one further structural unit of the following formula (L-P-XVII) which is different from the structural units of the formulae (P-I), (P-Ia), (P-Ib), (L-P-I), (L-P-Ia), (L-P-Ib), (P-II), (P-III), (P-IV), (P-V), (P-VI), (P-VII), (P-VIIIa), (P-VIIIb), (L-P-VIIIa), (L-P-VIIIb), (P-IX), (P-X), (P-XI), (P-XII), (P-XIII), (P-XIV), (P-XV) and/or (P-XVI):

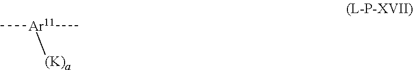

where Ar¹ is a mono- or polycyclic, aromatic or heteroaromatic ring system which may be substituted by one or more R radicals, where R may assume the definitions given above, especially for formula (I), and K represents an anionic coordination group, preferably a group of formula (K-I) and/or (K-II),
a=1, 2, 3, 4, 5, 6, 7 or 8, preferably 1, 2, 3 or 4, and
   the dotted lines represent bonds to adjacent structural units in the polymer.

Preferably, the proportion of structural units of the formula (P-XVII) in the polymer having at least one anionic coordination group is in the range from 0 to 50 mol %, preferably in the range from 1 to 40 mol %, especially preferably 3 to 30 mol % and more preferably 5 to 20 mol %, based on the total number of structural units in the polymer.

In one embodiment of the present invention, it may be the case that none of the structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) in a polymer comprises an anionic coordination group, and they instead comprise only structural units which can be represented, for example, by formula (P-XVII), especially (L-P-XVII).

It may further be the case that only structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) in a polymer comprise anionic coordination groups, and structural units in the polymer which can be represented, for example, by formula (P-XVII), do not comprise any anionic coordination groups.

It may further be the case that a copolymer comprises both structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) having anionic coordination groups and structural units having anionic coordination groups which do not correspond to the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) and can be represented, for example, by formula (P-XVII), especially (L-P-XVII).

It may further be the case that the proportion of structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI) and/or (P-XVII) having at least one anionic coordination group is in the range from 1 to 50 mol %, preferably in the range from 2 to 40 mol %, especially preferably 3 to 30 mol % and more preferably 5 to 20 mol %, based on the total number of structural units in the polymer.

Preferred mono- or polycyclic, aromatic or heteroaromatic Ar¹ and Ar² groups in formulae (I), (L-I); Ar³ in formulae (I), (P-I); Ar⁴ in formulae (Ia), (Ib), (II), (III), (IV), (V), (VI), (VII), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI); Ar⁵ and Ar⁸ in formulae (P-VIIIa) and/or (P-VIIIb), and the preferred embodiments thereof, are as follows:

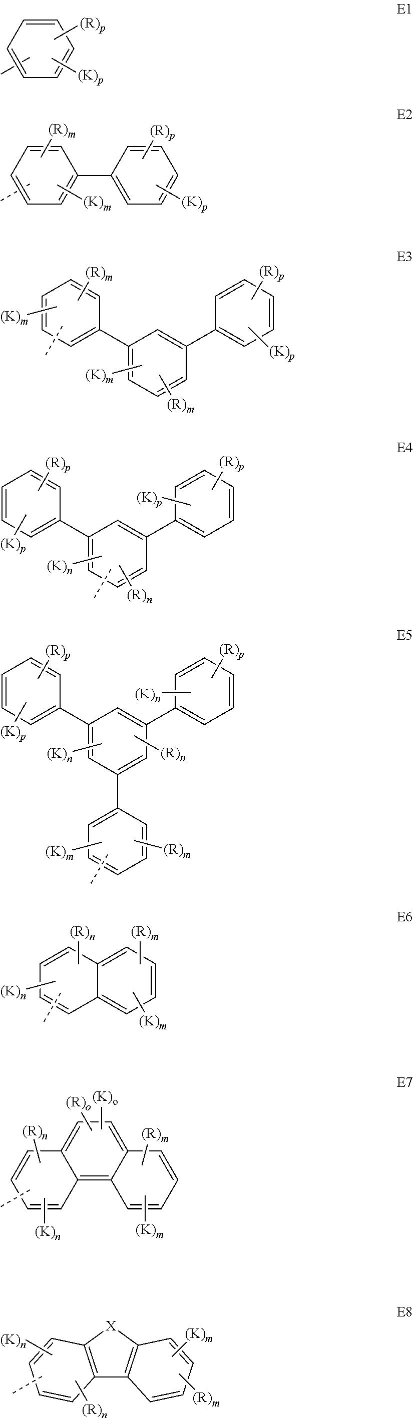

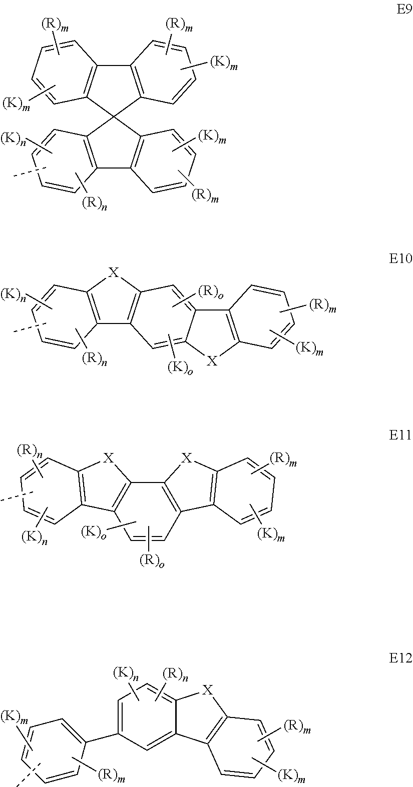

The R radicals in the formulae E1 to E12 may assume the same definition as the R radicals in the formula (I). K represents an anionic coordination group, preferably a group of formula (K-I) and/or (K-II). X may be a CR₂, NR, SiR₂, NR, CK₂, NK, SiK₂, CRK, SiRK, O, S, C═O or (P═O)R group, preferably CR₂, SiR₂, NR, CK₂, NK, SiK₂, CRK, SiRK, O or S, where K represents an anionic coordination group, preferably a group of formula (K-I) and/or (K-II), where R here too may assume the same definition as the R radicals in relation to the formula (I). The dotted line represents the bonding site to the adjacent group.

The Indices Used are Defined as Follows:
m=0, 1, 2, 3 or 4;
n=0, 1, 2 or 3;
o=0, 1 or 2; and
p=0, 1, 2, 3, 4 or 5.

Preferred mono- or polycyclic, aromatic or heteroaromatic Ar¹ and/or Ar² groups shown above, especially in formulae (P-I) and/or (L-P-I); Ar⁶, Ar⁷ and/or Ar⁹ groups shown above, especially in formulae (P-VIIIa), (P-VIIIb), (L-P-VIIIa) and/or (L-P-VIIIb); and/or Ar¹¹ groups shown above, especially in formulae (P-XVII) and/or (L-PXVII), are as follows:

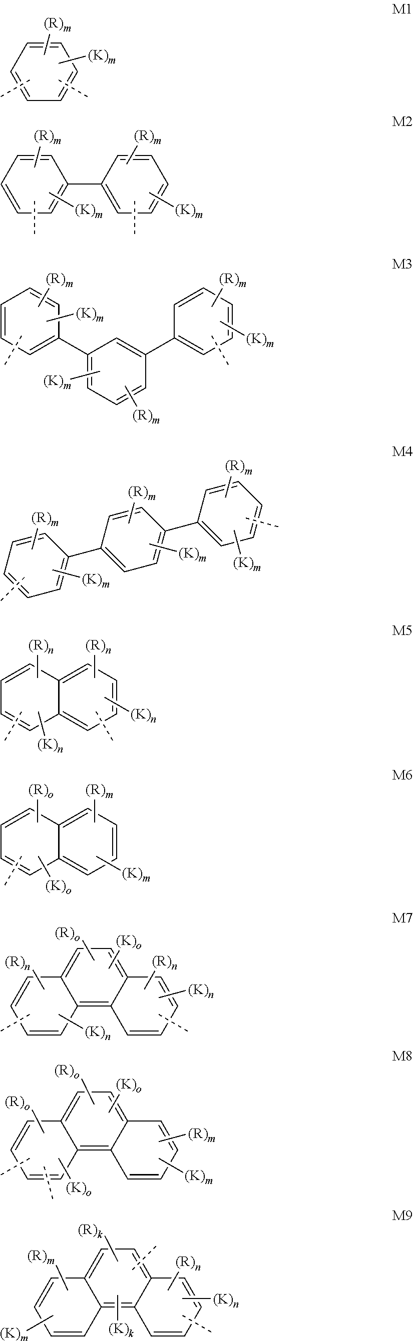

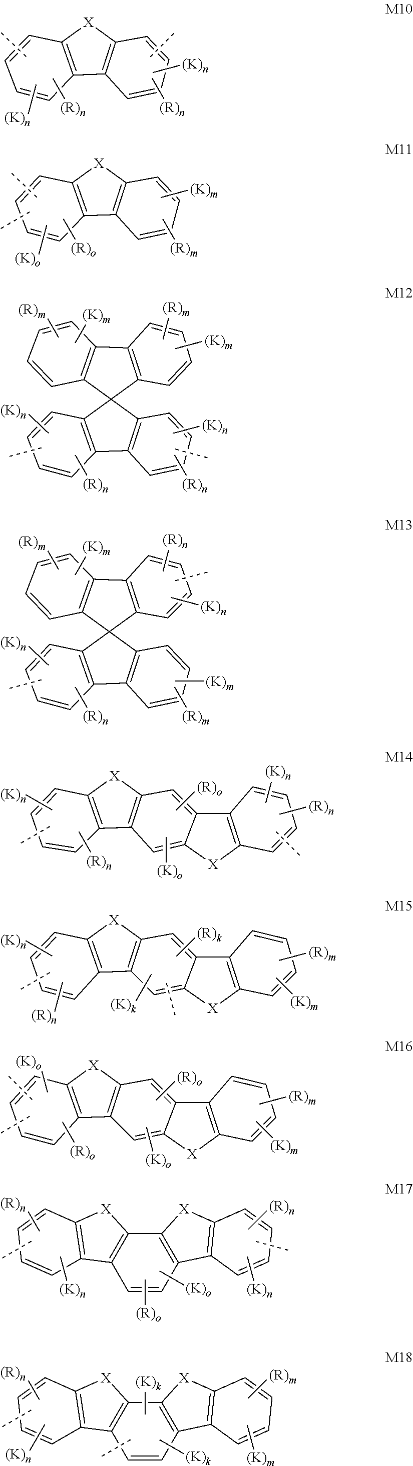

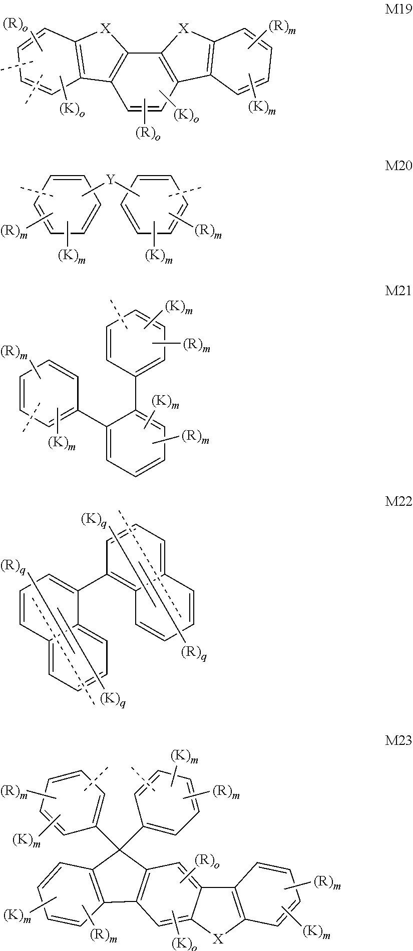

The R radicals in the formulae M1 to M23 may assume the same definition as the R radicals in the formula (I). K represents an anionic coordination group, preferably a group of formula (K-I) and/or (K-II). X may be a CR₂, NR, SiR₂, NR, CK₂, NK, SiK₂, CRK, SiRK, O, S, C═O or (P═O)R group, preferably CR₂, SiR₂, NR, CK₂, NK, SiK₂, CRK, SiRK, O or S, where K represents an anionic coordination group, preferably a group of formula (K-I) and/or (K-II), where R here too may assume the same definition as the R radicals in relation to the formula (I). The dotted line represents the bonding site to the adjacent group.

Y represents a CR₂, SiR₂, NR, CK₂, NK, SiK₂, CRK, SiRK, O or S group, a straight-chain or branched alkyl group having 1 to 20 carbon atoms or an alkenyl or alkynyl group having 2 to 20 carbon atoms, each of which may be substituted by one or more R¹ radicals, and where one or more nonadjacent CH₂ groups, CH groups or carbon atoms in the alkyl, alkenyl or alkynyl groups may be replaced by Si(R¹)₂, C═O, C═S, C═NR¹, P(═O)R¹, SO, SO₂, NR¹, O, S, CONR¹ or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals; where the R and R¹ radicals here too may be as defined for the R and R¹ radicals in formula (I), and K may be an anionic coordination group, preferably a group of formula (K-I) and/or (K-II).

The dotted line represents the bonding site to the adjacent group.

The indices used are defined as follows:
k=0 or 1;
m=0, 1, 2, 3 or 4;
n=0, 1, 2 or 3;
o=0, 1 or 2; and
q=0, 1, 2, 3, 4, 5 or 6.

Particularly preferred mono- or polycyclic, aromatic or heteroaromatic Ar¹ and Ar² groups in formulae (I), (L-I); Ar³ in formulae (I), (P-I); Ar⁴ in formulae (Ia), (Ib), (II), (III), (IV), (V), (VI), (VII), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV), (P-XVI); Ar⁵ and Ar⁸ in formulae (P-VIIIa) and/or (P-VIIIb), and the preferred embodiments thereof, are as follows:

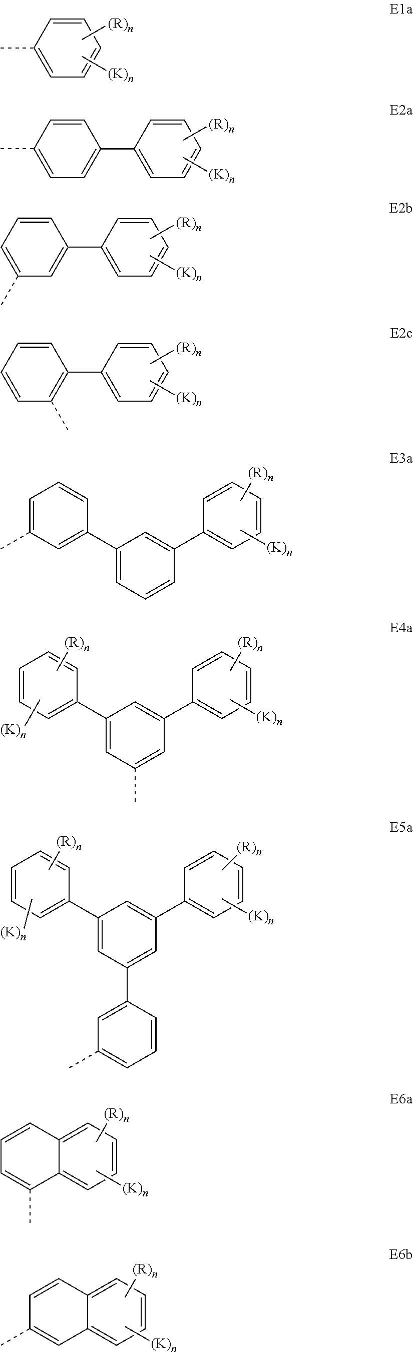

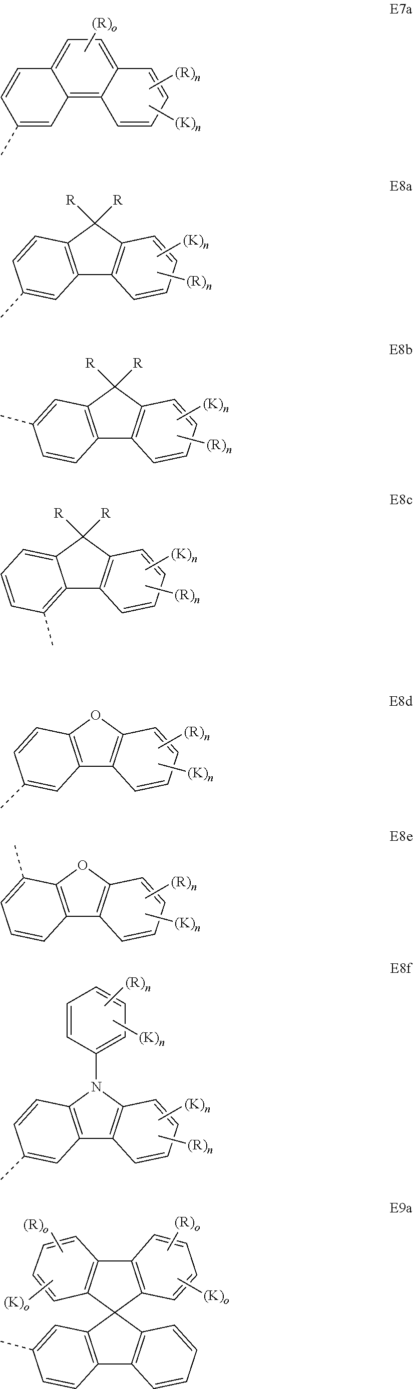

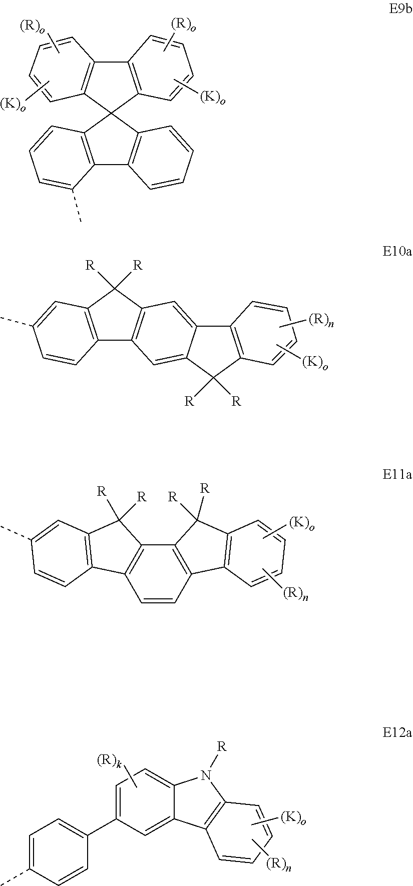

The R radicals in the formulae E1a to E12a may be as defined for the R radicals in formula (I). K represents an anionic coordination group, preferably a group of formula (K-I) and/or (K-III). X may be a CR₂, NR, SiR₂, NR, CK₂, NK, SiK₂, CRK, SiRK, O, S, C═O or (P═O)R group, preferably CR₂, SiR₂, NR, CK₂, NK, SiK₂, CRK, SiRK, O or S, where K represents an anionic coordination group, preferably a group of formula (K-I) and/or (K-II), where R here too may assume the same definition as the R radicals in relation to the formula (I). The dotted line represents the bonding site to the adjacent group.

The indices used are defined as follows:
o=0 or 1; and
n=0, 1, 2 or 3.

The R radicals in the formulae E1a to E12a may be the same or different at each instance and are preferably H or a straight-chain or branched alkyl group having 1 to 12 carbon atoms, preferably 1 to 10 carbon atoms. More preferably, the R radicals in the formulae E1a to E12a are methyl, n-butyl, sec-butyl, tert-butyl, n-hexyl and n-octyl.

Particularly preferred mono- or polycyclic, aromatic or heteroaromatic Ar¹ and/or Ar² groups shown above, especially in formulae (P-I) and/or (L-P-I); Ar⁶, Ar⁷ and/or Ar⁹ groups shown above, especially in formulae (P-VIIIa), (P-VIIIb), (L-P-VIIIa) and/or (L-P-VIIIb); and/or Ar¹¹ groups shown above, especially in formulae (P-XVII) and/or (L-PXVII), are as follows:

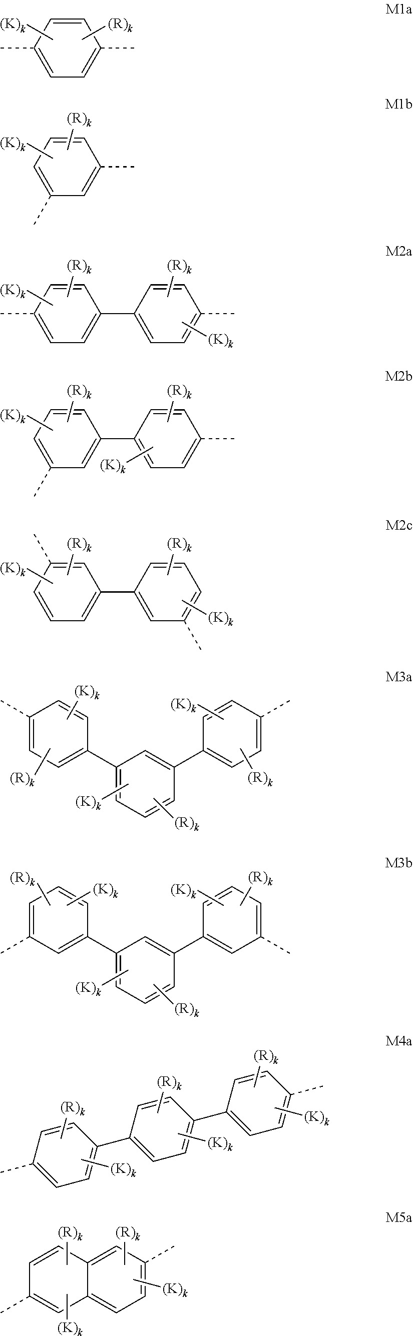

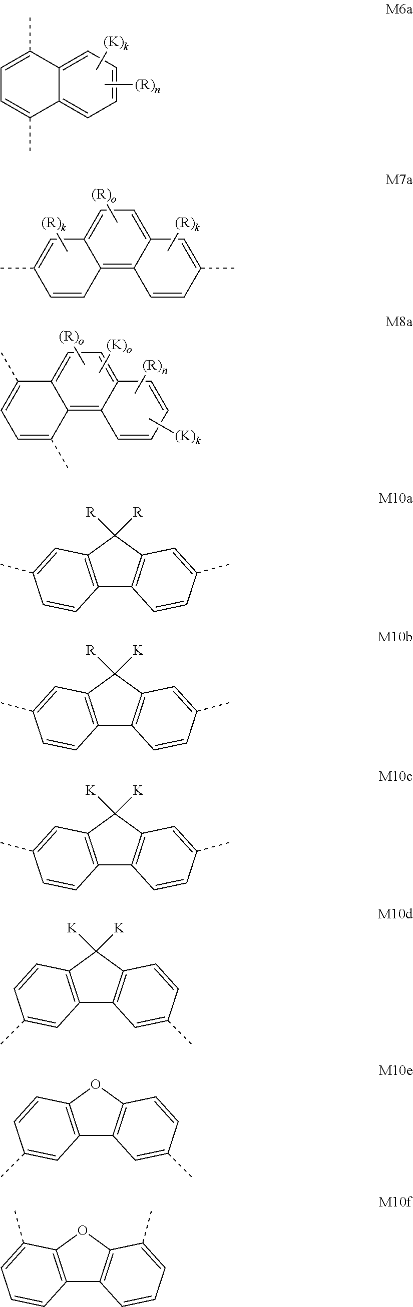

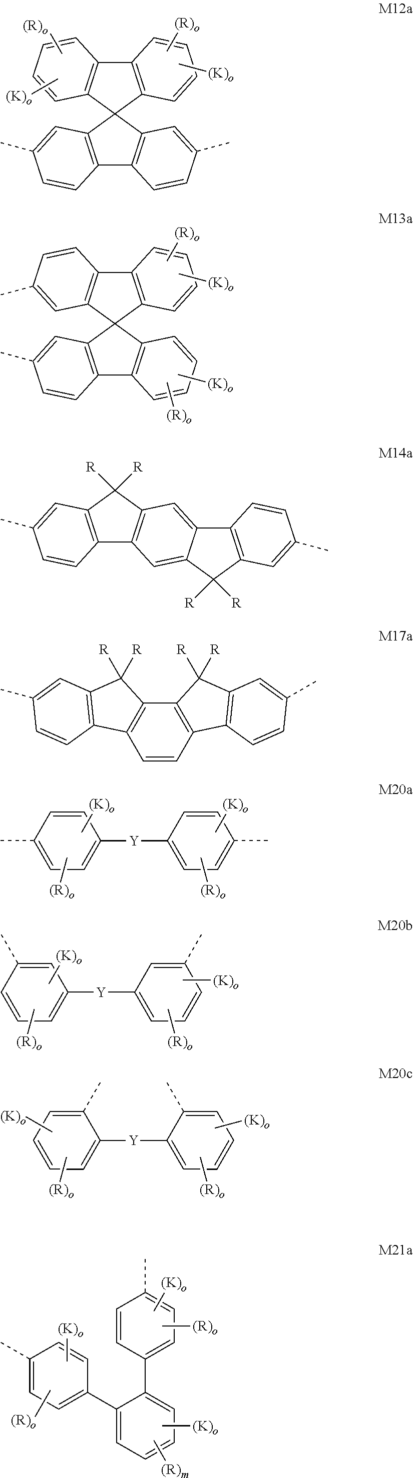

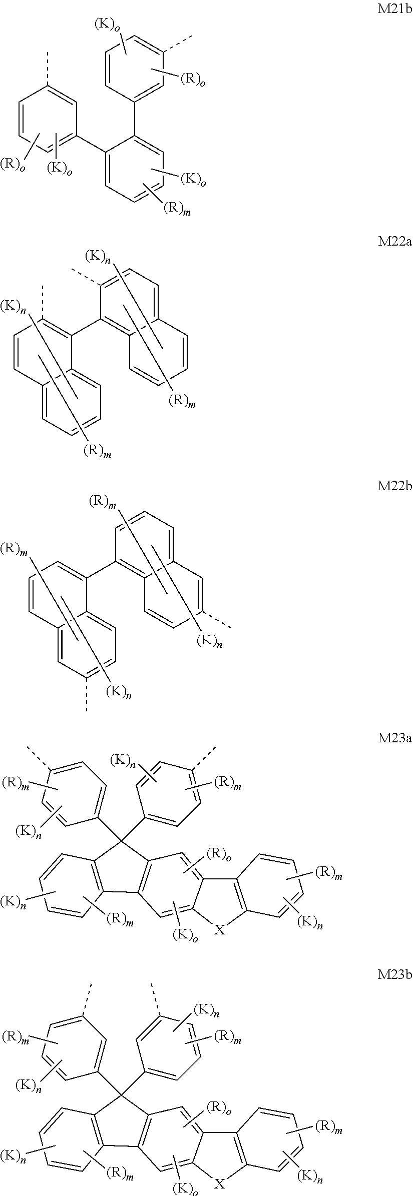

The R radicals in the formulae M1a to M23b may be as defined for the R radicals in formula (I). K represents an anionic coordination group, preferably a group of formula (K-I) and/or (K-II). X may be a CR₂, NR, SiR₂, NR, CK₂, NK, SiK₂, CRK, SiRK, O, S, C═O or P═O group, preferably CR₂, SiR₂, NR, CK₂, NK, SiK₂, CRK, SiRK, O or S, where K represents an anionic coordination group, preferably a group of formula (K-I) and/or (K-III), where R here too may assume the same definition as the R radicals in relation to the formula (I).

Y represents a CR₂, SiR₂, NR, CK₂, NK, SiK₂, CRK, SiRK, O or S group, a straight-chain or branched alkyl group having 1 to 20 carbon atoms or an alkenyl or alkynyl group having 2 to 20 carbon atoms, each of which may be substituted by one or more R¹ radicals, and where one or more nonadjacent CH₂ groups, CH groups or carbon atoms in the alkyl, alkenyl or alkynyl groups may be replaced by Si(R¹)₂, C═O, C═S, C═NR¹, P(═O)R¹, SO, SO₂, NR¹, O, S, CONR¹ or an aromatic or heteroaromatic ring system which has 5 to 60 aromatic ring atoms and may be substituted in each case by one or more R¹ radicals, or an aryloxy or heteroaryloxy group which has 5 to 60 aromatic ring atoms and may be substituted by one or more R¹ radicals, or an aralkyl or heteroaralkyl group which has 5 to 60 aromatic ring atoms and may be substituted by one or more R¹ radicals, or a diarylamino group, diheteroarylamino group or arylheteroarylamino group which has 10 to 40 aromatic ring atoms and may be substituted by one or more R¹ radicals; where the R and R¹ radicals here too may be as defined for the R and R¹ radicals in formula (I), and K may be an anionic coordination group, preferably a group of formula (K-I) and/or (K-II).

The dotted line represents the bonding site to the adjacent group.

The indices used are defined as follows:
k=0 or 1;
o=0, 1 or 2;
n=0, 1, 2 or 3; and
m=0, 1, 2, 3 or 4.

A selection of preferred structural elements of the formula (I) and/or structural units of the formula (P-I) is listed in Table 1 below.

TABLE 1

| Formula (I) | Ar¹ | Ar² | Ar³ |
|---|---|---|---|
| I1 | M1 | M1 | E1 |
| I2 | M2 | M2 | E1 |
| I3 | M10 | M10 | E1 |
| I4 | M12 | M12 | E1 |
| I5 | M14 | M14 | E1 |
| I6 | M19 | M19 | E1 |
| I7 | M1 | M1 | E2 |
| I8 | M1 | M2 | E2 |
| I9 | M7 | M7 | E2 |
| I10 | M12 | M12 | E2 |
| I11 | M13 | M13 | E2 |
| I12 | M1 | M1 | E3 |
| I13 | M13 | M13 | E3 |
| I14 | M1 | M1 | E4 |
| I15 | M2 | M2 | E4 |
| I16 | M14 | M14 | E4 |
| I17 | M3 | M3 | E5 |
| I18 | M12 | M12 | E5 |
| I19 | M6 | M6 | E6 |
| I20 | M10 | M10 | E6 |
| I21 | M16 | M16 | E6 |
| I22 | M2 | M2 | E7 |
| I23 | M15 | M15 | E7 |
| I24 | M1 | M1 | E8 |
| I25 | M2 | M2 | E8 |
| I26 | M4 | M4 | E8 |
| I27 | M5 | M5 | E8 |
| I28 | M10 | M10 | E8 |
| I29 | M12 | M12 | E8 |
| I30 | M14 | M14 | E8 |
| I31 | M1 | M1 | E9 |
| I32 | M8 | M8 | E9 |
| I33 | M13 | M13 | E9 |
| I34 | M10 | M10 | E10 |
| I35 | M9 | M9 | E11 |
| I36 | M17 | M17 | E11 |
| I37 | M7 | M7 | E12 |
| I38 | M18 | M18 | E12 |
| I39 | M23 | M23 | E1 |
| I40 | M1 | M21 | E2 |
| I41 | M20 | M20 | E8 |
| I42 | M22 | M22 | E9 |

Particularly preferred structural elements of the formula (I) and/or structural units of the formula (P-I) are structural units in which Ar³ is selected from the groups of the formulae E1a to E12a and Ar¹ and Ar² are selected from the groups of the formulae M1a to M17a, it being particularly preferable when Ar¹ and Ar² are the same.

A selection of particularly preferred structural elements of the formula (I) and/or structural units of the formula (P-I) is listed in Table 2 below.

TABLE 2

| Formula (I) | Ar¹ | Ar² | Ar³ |
|---|---|---|---|
| I1a | M1a | M1a | E1a |
| I2a | M2a | M2a | E1a |
| I2b | M2c | M2c | E1a |
| I3a | M10a | M10a | E1a |
| I4a | M12a | M12a | E1a |
| I5a | M14a | M14a | E1a |
| I7a | M1b | M1b | E2a |
| I7b | M1a | M1a | E2c |
| I8a | M1a | M2c | E2c |
| I9a | M7a | M7a | E2b |
| I10a | M12a | M12a | E2a |
| I11a | M13a | M13a | E2a |
| I12a | M1b | M1b | E3a |
| I13a | M13a | M13a | E3a |
| I14a | M1a | M1a | E4a |
| I15a | M2a | M2a | E4a |
| I15b | M2b | M2b | E4a |
| I16a | M14a | M14a | E4a |
| I17a | M3a | M3a | E5a |
| I18a | M12a | M12a | E5a |
| I19a | M6a | M6a | E6a |
| I20a | M10b | M10b | E6b |
| I22a | M2a | M2a | E7a |
| I24a | M1a | M1a | E8a |
| I24b | M1b | M1b | E8b |
| I24c | M1a | M1a | E8e |
| I24d | M1b | M1b | E8f |
| I25a | M2c | M2c | E8a |
| I25b | M2b | M2b | E8b |
| I25c | M2c | M2c | E8f |
| I26a | M4a | M4a | E8c |
| I27a | M5a | M5a | E8d |
| I28a | M10a | M10a | E8c |
| I29a | M12a | M12a | E8b |
| I30a | M14a | M14a | E8e |
| I31a | M1a | M1a | E9b |
| I32a | M8a | M8a | E9a |
| I33a | M13a | M13a | E9a |
| I34a | M10c | M10c | E10a |
| I36a | M17a | M17a | E11a |
| I37a | M7a | M7a | E12a |
| I39a | M23a | M23a | E1a |
| I39b | M23b | M23b | E1a |
| I40a | M1a | M21a | E2c |
| I40b | M1b | M21a | E2a |
| I41a | M20a | M20a | E8b |
| I41b | M20b | M20b | E8c |

Particularly preferred structural units of the formula (P-VIIIa) are structural units in which Ar⁵ and Ar⁸ are the same or different and are each independently selected from the groups of the formulae E1 to E12 and Ar⁵, Ar⁷ and Ar⁹ are the same or different and are each independently selected from the groups of the formulae M1 to M19, it being particularly preferable when Ar⁵ and Ar⁸, and Ar⁶ and Ar⁷, are the same.

Particularly preferred structural units of the formula (P-VIIIb) are structural units in which Ar⁵ and Ar⁸ are the same or different and are each independently selected from the groups of the formulae E1 to E12 and Ar⁵, Ar⁷ and Ar⁹ are the same or different and are each independently selected from the groups of the formulae M1 to M19, it being particularly preferable when Ar⁵ and Ar⁸, and Ar⁶ and Ar¹, are the same.

A selection of preferred structural units of the formulae (P-VIIIa) and (P-VIIIb) is listed in Table 3 below.

TABLE 3

Formula (P-VIIIa)

| | | | | |
|---|---|---|---|---|
| Ar⁵ | Ar⁶ | Ar⁷ | Ar⁸ | Ar⁹ |

Formula (P-VIIIb)

| | Ar⁵ | Ar⁶ | Ar⁷ | Ar⁸ | Ar⁹ |
|---|---|---|---|---|---|
| P-VIII1 | E1 | M1 | M1 | E1 | M1 |
| P-VIII2 | E1 | M1 | M1 | E1 | M2 |
| P-VIII3 | E1 | M1 | M1 | E1 | M10 |
| P-VIII4 | E1 | M1 | M1 | E1 | M13 |
| P-VIII5 | E1 | M1 | M1 | E1 | M14 |
| P-VIII6 | E1 | M14 | M14 | E1 | M12 |
| P-VIII7 | E2 | M1 | M1 | E2 | M2 |
| P-VIII8 | E2 | M2 | M2 | E2 | M12 |
| P-VIII9 | E3 | M7 | M7 | E3 | M1 |
| P-VIII10 | E3 | M10 | M10 | E3 | M16 |
| P-VIII11 | E4 | M1 | M1 | E4 | M7 |
| P-VIII12 | E4 | M1 | M1 | E4 | M12 |
| P-VIII13 | E4 | M2 | M2 | E4 | M14 |
| P-VIII14 | E4 | M10 | M10 | E4 | M13 |
| P-VIII15 | E4 | M1 | M1 | E8 | M7 |
| P-VIII16 | E5 | M2 | M13 | E5 | M13 |
| P-VIII17 | E6 | M3 | M3 | E6 | M6 |
| P-VIII18 | E6 | M17 | M17 | E6 | M10 |
| P-VIII19 | E7 | M5 | M5 | E7 | M4 |
| P-VIII20 | E8 | M1 | M1 | E8 | M1 |
| P-VIII21 | E8 | M1 | M1 | E8 | M2 |
| P-VIII22 | E8 | M1 | M1 | E8 | M12 |
| P-VIII23 | E8 | M2 | M2 | E8 | M10 |
| P-VIII24 | E8 | M6 | M6 | E8 | M8 |
| P-VIII25 | E8 | M10 | M10 | E8 | M7 |
| P-VIII26 | E8 | M13 | M13 | E8 | M2 |
| P-VIII27 | E8 | M14 | M14 | E8 | M12 |
| P-VIII28 | E9 | M1 | M1 | E9 | M2 |
| P-VIII29 | E9 | M9 | M9 | E9 | M11 |
| P-VIII30 | E9 | M19 | M19 | E9 | M18 |
| P-VIII31 | E10 | M1 | M1 | E10 | M4 |
| P-VIII32 | E11 | M2 | M2 | E11 | M10 |
| P-VIII33 | E11 | M13 | M13 | E11 | M15 |
| P-VIII34 | E12 | M7 | M7 | E12 | M14 |
| VIII35 | E2 | M1 | M1 | E2 | M14 |
| VIII36 | E2 | M1 | M1 | E2 | M12 |
| VIII37 | E8 | M1 | M1 | E8 | M20 |
| VIII38 | E9 | M1 | M1 | E9 | M23 |

Particularly preferred structural units of the formula (P-VIIIa) are structural units in which Ar⁵ and Ar⁸ are the same or different and are each independently selected from the groups of the formulae E1a to E12a and Ar⁵, Ar⁷ and Ar⁹ are the same or different and are each independently selected from the groups of the formulae M1a to M17a, it being particularly preferable when Ar⁵ and Ar⁸, and Ar⁶ and Ar⁷, are the same.

Particularly preferred structural units of the formula (P-VIIIb) are structural units in which Ar⁵ and Ar⁸ are the same or different and are each independently selected from the groups of the formulae E1a to E12a and Ar⁵, Ar⁷ and Ar⁹ are the same or different and are each independently selected from the groups of the formulae M1a to M17a, it being particularly preferable when Ar⁵ and Ar⁸, and Ar⁶ and Ar⁷, are the same.

A selection of particularly preferred structural units of the formula (P-VIIIa) or (P-VIIb) is listed in Table 4 below.

TABLE 4

Formula (P-VIIIa)

| | | | | |
|---|---|---|---|---|
| Ar⁵ | Ar⁶ | Ar⁷ | Ar⁸ | Ar⁹ |

Formula (P-VIIIb)

| | Ar⁵ | Ar⁶ | Ar⁷ | Ar⁸ | Ar⁹ |
|---|---|---|---|---|---|
| P-VIII1a | E1a | M1a | M1a | E1a | M1a |
| P-VIII1b | E1a | M1b | M1b | E1a | M1b |
| P-VIII2a | E1a | M1a | M1a | E1a | M2a |
| P-VIII3a | E1a | M1a | M1a | E1a | M10a |
| P-VIII4a | E1a | M1a | M1a | E1a | M13a |
| P-VIII4b | E1a | M1b | M1b | E1a | M13a |
| P-VIII5a | E1a | M1a | M1a | E1a | M14a |
| P-VIII6a | E1a | M14a | M14a | E1a | M12a |
| P-VIII7a | E2a | M1a | M1a | E2a | M2a |
| P-VIII7b | E2c | M1a | M1a | E2c | M2a |
| P-VIII8a | E2b | M2b | M2b | E2b | M12a |
| P-VIII9a | E3a | M7a | M7a | E3a | M1b |
| P-VIII11a | E4a | M1b | M1b | E4a | M7a |
| P-VIII12a | E4a | M1b | M1b | E4a | M12a |
| P-VIII13a | E4a | M2b | M2b | E4a | M14a |
| P-VIII14a | E4a | M10a | M10a | E4a | M13a |
| P-VIII15a | E4a | M1b | M1b | E8a | M7a |
| P-VIII16a | E5a | M2c | M13a | E5a | M13a |
| P-VIII17a | E6a | M3a | M3a | E6a | M6a |
| P-VIII18a | E6b | M17a | M17a | E6b | M10b |
| P-VIII19a | E7a | M5a | M5a | E7a | M4a |
| P-VIII20a | E8f | M1a | M1a | E8f | M1a |
| P-VIII21a | E8b | M1a | M1a | E8b | M2a |
| P-VIII21b | E8e | M1a | M1a | E8e | M2a |
| P-VIII22a | E8b | M1b | M1b | E8b | M12a |
| P-VIII23a | E8d | M2b | M2b | E8d | M10c |
| P-VIII24a | E8f | M6a | M6a | E8f | M8a |
| P-VIII25a | E8a | M10a | M10a | E8a | M7a |
| P-VIII26a | E8c | M13a | M13a | E8c | M2c |
| P-VIII27a | E8b | M14a | M14a | E8b | M12a |
| P-VIII28a | E9a | M1a | M1a | E9a | M2a |
| P-VIII28b | E9b | M1a | M1a | E9b | M2a |
| P-VIII31a | E10a | M1b | M1b | E10a | M4a |
| P-VIII32a | E11a | M2c | M2c | E11a | M10c |
| P-VIII34a | E12a | M7a | M7a | E12a | M14a |
| P-VIII35a | E2a | M1a | M1a | E2a | M14a |
| P-VIII35b | E2c | M1a | M1a | E2c | M14a |
| P-VIII36a | E2c | M1a | M1a | E2c | M12a |
| P-VIII37a | E8b | M1a | M1a | E8b | M20a |
| P-VIII37b | E8e | M1a | M1a | E8e | M20b |
| P-VIII38a | E9a | M1b | M1b | E9a | M23a |
| P-VIII38b | E9b | M1b | M1b | E9b | M23b |

The proportion of structural units of the formulae (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) in the polymer is preferably in the range from 1 to 100 mol %, preferably in the range from 25 to 100 mol %, more preferably in the range from 50 to 95 mol %, based on 100 mol % of all copolymerized monomers present as structural units in the polymer.

Preferred structural units of the following formula (P-XVII) are structural units in which Ar¹¹ is selected from the groups of the formulae M1 to M23, as listed in Table 5 below.

TABLE 5

| Formula (P-XVII) | Ar¹¹ |
|---|---|
| P-XVII1 | M1 |
| P-XVII2 | M2 |
| P-XVII3 | M3 |
| P-XVII4 | M4 |
| P-XVII5 | M5 |
| P-XVII6 | M6 |
| P-XVII7 | M7 |
| P-XVII8 | M8 |
| P-XVII9 | M9 |
| P-XVII10 | M10 |
| P-XVII11 | M11 |
| P-XVII12 | M12 |
| P-XVII13 | M13 |
| P-XVII14 | M14 |
| P-XVII15 | M15 |
| P-XVII16 | M16 |
| P-XVII17 | M17 |
| P-XVII18 | M18 |
| P-XVII19 | M19 |
| P-XVII20 | M20 |
| P-XVII21 | M21 |
| P-XVII22 | M22 |
| P-XVII23 | M23 |

Particularly preferred structural units of the formula (P-XVII) are structural units in which Ar¹¹ is selected from the groups of the formulae M1a to M23a, as listed in Table 6 below.

TABLE 6

| Formula (P-XVII) | Ar¹¹ |
|---|---|
| P-XVII1a | M1a |
| P-XVII1b | M1b |
| P-XVII2a | M2a |
| P-XVII2b | M2b |
| P-XVII2c | M2c |
| P-XVII3a | M3a |
| P-XVII4a | M4a |
| P-XVII5a | M5a |
| P-XVII6a | M6a |
| P-XVII7a | M7a |
| P-XVII8a | M8a |
| P-XVII10a | M10a |
| P-XVII10b | M10b |
| P-XVII10c | M10c |
| P-XVII12a | M12a |
| P-XVII13a | M13a |
| P-XVII14a | M14a |
| P-XVII17a | M17a |
| P-XVII20a | M20a |
| P-XVII20b | M20b |
| P-XVII20c | M20c |
| P-XVII21a | M21a |
| P-XVII21b | M21b |
| P-XVII22a | M22a |
| P-XVII22b | M22b |
| P-XVII23a | M23a |
| P-XVII23b | M23b |

The further structural units may come, for example, from the following classes:
Group 1: units which influence the hole injection and/or hole transport properties of the polymers;
Group 2: units which influence the electron injection and/or electron transport properties of the polymers;
Group 3: units having combinations of individual units of group 1 and group 2;
Group 4: units which alter the emission characteristics in such a way that electrophosphorescence rather than electrofluorescence is obtainable;
Group 5: units which improve the transition from the singlet to the triplet state;
Group 6: units which affect the emission colour of the resulting polymers;
Group 7: units which are typically used as polymer backbone;
Group 8: units which affect the film morphology and/or the rheological properties of the resulting polymers.

Preferred polymers of the invention are those in which at least one structural unit has charge transport properties, i.e. those which contain the units from groups 1 and/or 2.

Structural units from group 1 having hole injection and/or hole transport properties are, for example, triarylamine, benzidine, tetraaryl-para-phenylenediamine, triarylphosphine, phenothiazine, phenoxazine, dihydrophenazine, thianthrene, dibenzo-para-dioxin, phenoxathiine, carbazole, azulene, thiophene, pyrrole and furan derivatives and further O-, S- or N-containing heterocycles.

Preferred structural units from group 1 are the structural units of the following formulae (1a) to (1q):

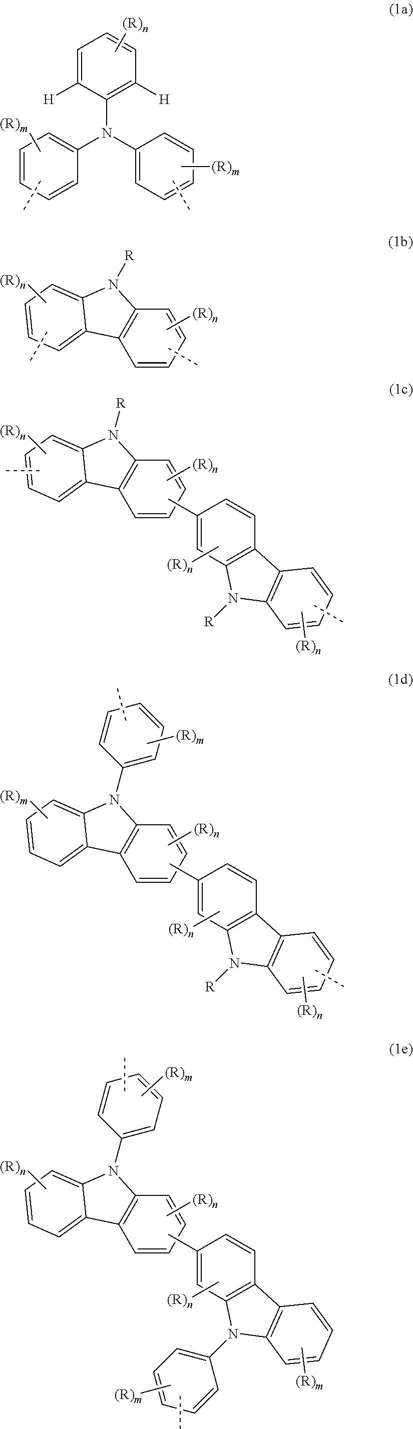

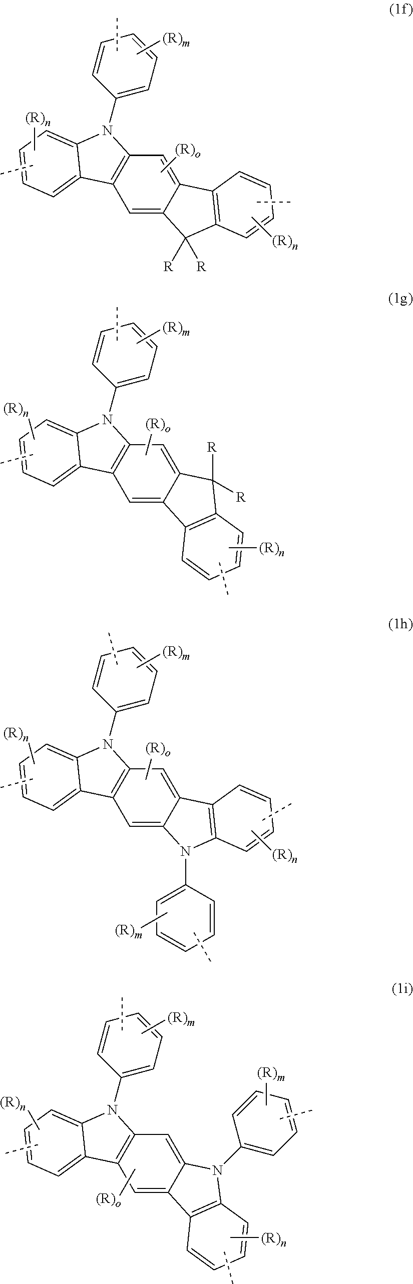

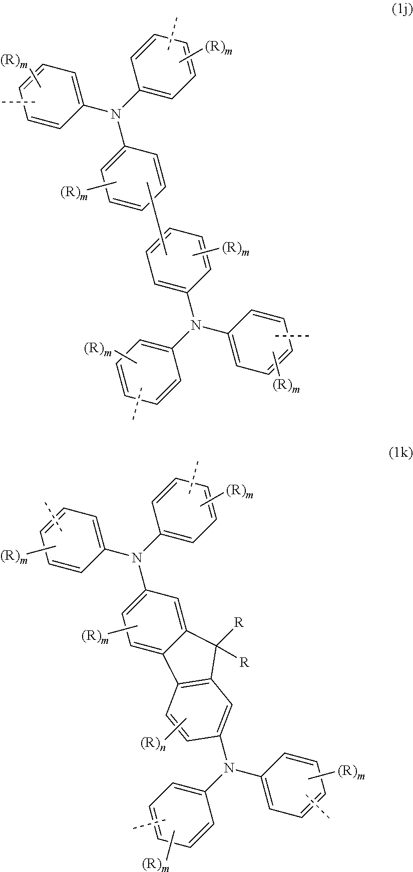

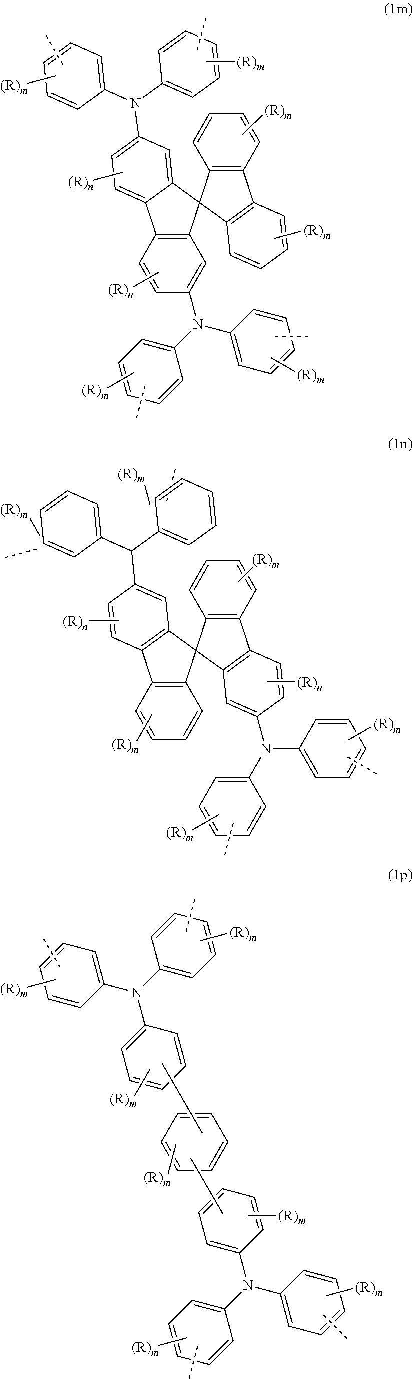

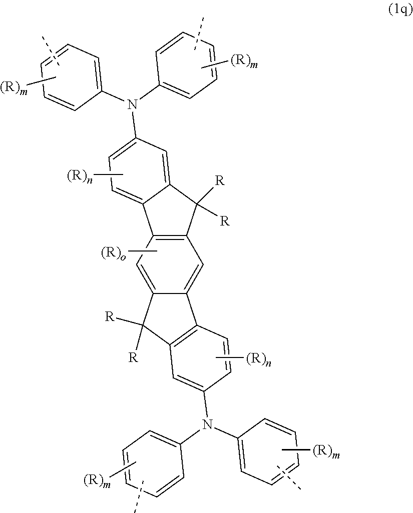

where R, m, n and o may each be as defined above.

In the formulae (1a) to (1q), the dotted lines represent possible bonds to the adjacent structural units in the polymer. If two dotted lines are present in the formulae, the structural unit has one or two, preferably two, bond(s) to adjacent structural units. If three dotted lines are present in the formulae, the structural unit has one, two or three, preferably two, bond(s) to adjacent structural units. If four dotted lines are present in the formulae, the structural unit has one, two, three or four, preferably two, bond(s) to adjacent structural units. They may independently be arranged, identically or differently, in the ortho, meta or para position.

Structural units from group 2 having electron injection and/or electron transport properties are, for example, pyridine, pyrimidine, pyridazine, pyrazine, oxadiazole, quinoline, quinoxaline, anthracene, benzanthracene, pyrene, perylene, benzimidazole, triazine, ketone, phosphine oxide and phenazine derivatives, but also triarylboranes and further O-, S- or N-containing heterocycles.

It may be preferable when the polymers of the invention contain units from group 3 in which structures which increase hole mobility and which increase electron mobility (i.e. units from group 1 and 2) are bonded directly to one another, or structures which increase both hole mobility and electron mobility are present. Some of these units may serve as emitters and shift the emission colour into the green, yellow or red. The use thereof is thus suitable, for example, for the creation of other emission colours from originally blue-emitting polymers.

Structural units of group 4 are those which can emit light with high efficiency from the triplet state even at room temperature, i.e. exhibit electrophosphorescence rather than electrofluorescence, which frequently brings about an increase in energy efficiency. Suitable for this purpose, first of all, are compounds containing heavy atoms having an atomic number of more than 36. Preferred compounds are those which contain d or f transition metals, which fulfil the abovementioned condition. Particular preference is given here to corresponding structural units containing elements of groups 8 to 10 (Ru, Os, Rh, Ir, Pd, Pt). Useful structural units here for the polymers usable in accordance with the invention include, for example, various complexes as described, for example, in WO 02/068435 A1, WO 02/081488 A1, EP 1239526 A2 and WO 2004/026886 A2. Corresponding monomers are described in WO 02/068435 A1 and in WO 2005/042548 A1.

Structural units of group 5 are those which improve the transition from the singlet to the triplet state and which, used in association with the structural elements of group 4, improve the phosphorescence properties of these structural elements. Useful units for this purpose are especially carbazole and bridged carbazole dimer units, as described, for example, in WO 2004/070772 A2 and WO 2004/113468 A1. Additionally useful for this purpose are ketones, phosphine oxides, sulphoxides, sulphones, silane derivatives and similar compounds, as described, for example, in WO 2005/040302 A1.

Structural units of group 6 are, as well as those mentioned above, those which include at least one further aromatic structure or another conjugated structure which are not among the abovementioned groups, i.e. which have only little effect on the charge carrier mobilities, which are not organometallic complexes or which have no effect on the singlet-triplet transition. Structural elements of this kind can affect the emission colour of the resulting polymers. According to the unit, they can therefore also be used as emitters. Preference is given to aromatic structures having 6 to 40 carbon atoms or else tolane, stilbene or bisstyrylarylene derivatives which may each be substituted by one or more R radicals. Particular preference is given to the incorporation of 1,4- or 9,10-anthrylene, 1,6-, 2,7- or 4,9-pyrenylene, 3,9- or 3,10-perylenylene, 4,4′-tolanylene, 4,4′-stilbenylene, benzothiadiazole and corresponding oxygen derivatives, quinoxaline, phenothiazine, phenoxazine, dihydrophenazine, bis(thiophenyl)arylene, oligo(thiophenylene), phenazine, rubrene, pentacene or perylene derivatives which are preferably substituted, or preferably conjugated push-pull systems (systems substituted by donor and acceptor substituents) or systems such as squarines or quinacridones which are preferably substituted.

Structural units of group 7 are units including aromatic structures having 6 to 40 carbon atoms, which are typically used as the polymer backbone. These are, for example, 4,5-dihydropyrene derivatives, 4,5,9,10-tetrahydropyrene derivatives, fluorene derivatives, 9,9′-spirobifluorene derivatives, phenanthrene derivatives, 9,10-dihydrophenanthrene derivatives, 5,7-dihydrodibenzooxepine derivatives and cis- and trans-indenofluorene derivatives, but also 1,2-, 1,3- or 1,4-phenylene, 1,2-, 1,3- or 1,4-naphthylene, 2,2′-, 3,3′- or 4,4′-biphenylylene, 2,2″-, 3,3″- or 4,4″-terphenylylene, 2,2′-, 3,3′- or 4,4′-bi-1,1′-naphthylylene or 2,2′″-, 3,3′″- or 4,4′″-quarterphenylylene derivatives.

Preferred structural units from group 7 are the structural units of the following formulae (7a) to (70):

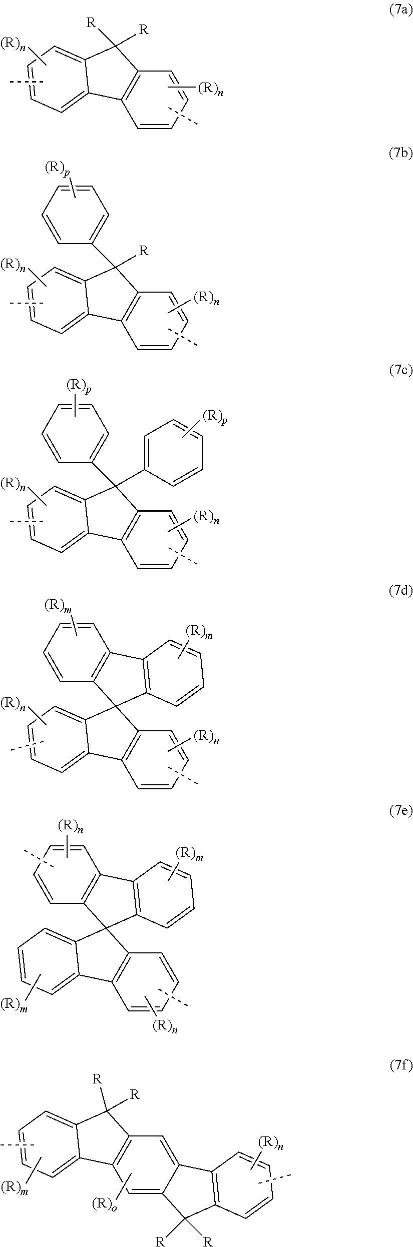

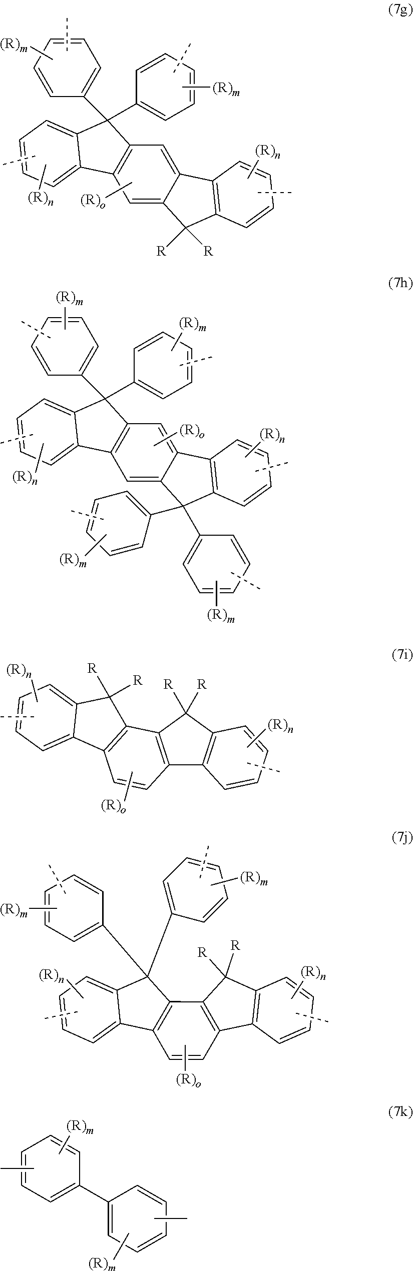

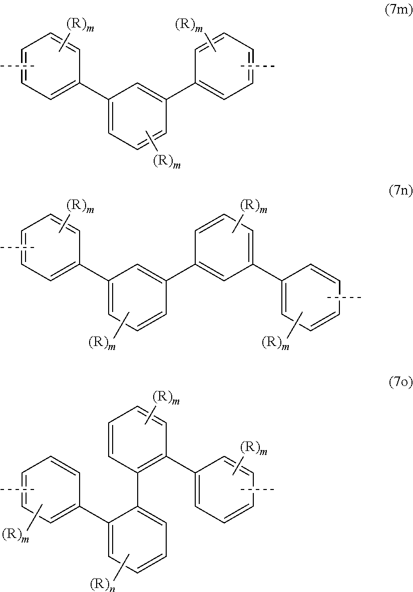

where R, m, n, o and p may each be as defined above.

In the formulae (7a) to (7o), the dotted lines represent possible bonds to the adjacent structural units in the polymer. If two dotted lines are present in the formulae, the structural unit has one or two, preferably two, bond(s) to adjacent structural units. If four or more dotted lines are present in the formulae (Formulae (7g), (7h) and (7j)), the structural units have one, two, three or four, preferably two, bond(s) to adjacent structural units. They may independently be arranged, identically or differently, in the ortho, meta or para position.

Structural units of group 8 are those which affect the film morphology and/or the rheological properties of the polymers, for example siloxanes, alkyl chains or fluorinated groups, but also particularly stiff or flexible units, liquid crystal-forming units or crosslinkable groups.

Preference is given to polymers of the invention which simultaneously, as well as structural units of the formula (I), (Ia), (Ib), (II), (III), (IV), (V), (VI), (VII), (VIIIa), (VIIIb), (IX), (X), (XI), (XII), (XIII), (XIV), (XV) and/or (XVI), additionally contain one or more units selected from groups 1 to 8. It may likewise be preferable when more than one further structural unit from one group is simultaneously present.

Preference is given here to polymers of the invention which, as well as at least one structural unit of the formula (I), (Ia), (Ib), (II), (III), (IV), (V), (VI), (VII), (VIIIa), (VIIIb), (IX), (X), (XI), (XII), (XIII), (XIV), (XV) and/or (XVI), also contain units from group 7.

It is likewise preferable when the polymers usable in accordance with the invention contain units which improve charge transport or charge injection, i.e. units from group 1 and/or 2.

It is additionally particularly preferable when the polymers usable in accordance with the invention contain structural units from group 7 and units from group 1 and/or 2.

The polymers usable in accordance with the invention are either homopolymers of structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) or copolymers. The polymers usable in accordance with the invention may be linear or branched, preferably linear. Copolymers of the invention may, as well as one or more structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI) potentially contain one or more further structures from the above-detailed groups 1 to 8.

The copolymers of the invention may have random, alternating or block structures, or else have two or more of these structures in alternation. More preferably, the copolymers of the invention have random or alternating structures. More preferably, the copolymers are random or alternating copolymers. The way in which copolymers having block structures are obtainable and which further structural elements are particularly preferred for the purpose is described in detail, for example, in WO 2005/014688 A2.

This is incorporated into the present application by reference. It should likewise be emphasized once again at this point that the polymer may also have dendritic structures.

The polymers usable in accordance with the invention, containing structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI), are generally prepared by polymerization of one or more monomer types, of which at least one monomer leads, in the polymer, to structural units of the formula (P-I), (P-Ia), (P-Ib), (P-II), (P-III), (P-IV), (P-V), (P-VI), (P-VII), (P-VIIIa), (P-VIIIb), (P-IX), (P-X), (P-XI), (P-XII), (P-XIII), (P-XIV), (P-XV) and/or (P-XVI). Suitable polymerization reactions are known to those skilled in the art and are described in the literature.

Particularly suitable and preferred polymerization reactions which lead to C—C and C—N bonds are as follows:
(A) SUZUKI polymerization;
(B) YAMAMOTO polymerization;
(C) STILLE polymerization;
(D) HECK polymerization;
(E) NEGISHI polymerization;
(F) SONOGASHIRA polymerization;
(G) HIYAMA polymerization; and
(H) HARTWIG-BUCHWALD polymerization.

How the polymerization can be conducted by these methods and how the polymers can then be separated from the reaction medium and purified is known to those skilled in the art and is described in detail in the literature, for example in WO 03/048225 A2, WO 2004/037887 A2 and WO 2004/037887 A2.

The C—C couplings are preferably selected from the groups of SUZUKI coupling, YAMAMOTO coupling and STILLE coupling; the C—N coupling is preferably a coupling according to HARTWIG-BUCHWALD.

For synthesis of the polymers usable in accordance with the invention, it is possible to use the corresponding monomers of the formula (MI)

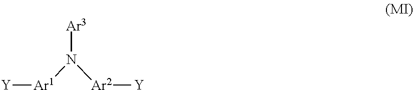

where Ar¹, Ar² and Ar³ may be as defined in relation to the structural unit of the formula (I).

The monomers of the formula (MI) which lead to structural units of the formula (P-I) in the inventive polymers are compounds which have corresponding substitution and have suitable functionalities at two positions that allow incorporation of this monomer unit into the polymer. These monomers of the formula (MI) thus likewise form part of the subject-matter of the present invention. The Y group is the same or different and is a leaving group suitable for a polymerization reaction, such that the incorporation of the monomer units into polymeric compounds is enabled. Preferably, Y is a chemical functionality which is the same or different and is selected from the class of the halogens, O-tosylates, O-triflates, O-sulphonates, boric esters, partly fluorinated silyl groups, diazonium groups and organotin compounds.

Corresponding monomers for preparation of structural units of the formulae (P-VIIIa) and/or (P-VIIIb) correspondingly arise through replacement of the dotted lines by leaving groups Y as defined for formula (MI).

The polymers for use as ligands in accordance with the invention may be formed here from monomers which comprise the above-detailed anionic coordination groups. In addition, the end groups of the polymers may have anionic coordination groups.

The basic structure of the monomer compounds can be functionalized by standard methods, for example by Friedel-Crafts alkylation or acylation. In addition, the basic structure can be halogenated by standard organic chemistry methods. The halogenated compounds can optionally be converted further in additional functionalization steps. For example, the halogenated compounds can be used either directly or after conversion to a boronic acid derivative or an organotin derivative as starting materials for the conversion to polymers, oligomers or dendrimers.

Said methods are merely a selection from the reactions known to those skilled in the art, who are able to use these, without exercising inventive skill, to synthesize the inventive compounds.

The polymers usable in accordance with the invention can be used as a pure substance, or else as a mixture together with any further polymeric, oligomeric, dendritic or low molecular weight substances. A low molecular weight substance is understood in the present invention to mean compounds having a molecular weight in the range from 100 to 3000 g/mol, preferably 200 to 2000 g/mol. These further substances can, for example, improve the electronic properties or emit themselves. A mixture refers above and below to a mixture comprising at least one polymeric component. In this way, it is possible to produce one or more polymer layers consisting of a mixture (blend) of one or more polymers of the invention having a structural unit of the formula (P-I), (P-Ia), (P-Ib), (P-III), (P-III), (P-IV), (P-V), (P-VI), (P-VII), (P-VIIa), (P-VIIIb), (P-IX), (P-X), (P-XI), (P-XII), (P-XIII), (P-XIV), (P-XV) and/or (P-XVI) and optionally one or more further polymers with one or more low molecular weight substances.

The term “main group metal complex of groups 13 to 15” is understood to mean the metals of groups 13 to 15 according to IUPAC, i.e. aluminium, gallium, indium, silicon, germanium, tin, lead, thallium, arsenic, antimony, bismuth or mixtures thereof. Preference is given to metals of groups 14 and 15, i.e. silicon, germanium, tin, lead, arsenic, antimony, bismuth, more preferably tin and/or bismuth, especially preferably bismuth.

In a further-preferred embodiment of the present invention, the metal atom in the metal complex for use in accordance with the invention may be selected from the group comprising bismuth, tin and mixtures thereof, particular preference being given to bismuth.

In a preferred embodiment, the metal complex is a mono- or di- or polynuclear metal complex. More particularly, the metal complex in the solid state may take the form of a polynuclear metal complex.

In a preferred embodiment, at least one of the ligands L is arranged in a bridging position between two metals.

In a preferred embodiment, the metal complex may have the empirical formula M₂L₄ (with M=metal and L=ligand) where both the metals and the individual ligands may be selected independently as per the above definition.

It may further be the case that the metal complex has the structure MLₘ where M=metal atom, L=ligand and m=1 to 10 and, if m>1, all L are independent of one another. These metal complexes are preferred especially in the case of tin and bismuth; in this case, preferably, m=2 for tin or 2, 4, and 3 or 5 for bismuth, according to the oxidation state.

In an alternative embodiment of the invention, the metal complex has the structure ML₂L′ₙ with M=metal, L=ligand, as defined above, and L′=a ligand nonidentical to L selected from the group of aryl, heteroaryl, haloaryl and haloheteroaryl, where n may be from 0 to 3 and, if n>1, each L′ is selected independently of the others. These metal complexes are preferred especially in the case of tin and bismuth; in this case, n=2 for tin or 1 or 3 for bismuth, according to the oxidation state, and n=0 is preferred.

More preferably, the main group metal complex contains bismuth. Particular preference is given here to bismuth main group metal complexes:

of the oxidation state II which, without being bound by the theory, as a function of the ligands chosen, may have a paddlewheel structure.
of the oxidation state III (MLₙ=3) which, without being bound by the theory, do not have a paddlewheel structure. These compounds in the solid state are generally in mono- to polynuclear form.
of the oxidation state V in which, in a particular embodiment, the main group metal complex of bismuth in the oxidation state V may have the structure described in detail in WO 2013/182389 A2.

Some of the above-detailed structures and formulae of the metal complex relate to an uncrosslinked complex, i.e. a complex in which the ligand is bonded only to a metal atom. Preferably, the metal complex may be in crosslinked form. In these embodiments, the structures shown above for an uncrosslinked complex may be regarded as a partial structure.

The proportion of metal in an inventive complex of the present invention may be within a wide range. Advantageously, the weight ratio of ligand to metal may be in the range from 10 000:1 to 10:1, preferably 4000:1 to 20:1, more preferably in the range from 2000:1 to 30:1, especially preferably in the range from 1500:1 to 50:1. Use of a greater or lesser proportion of metal is possible, but the efficiency of the composition, of the functional layers obtainable therefrom or of the optoelectronic components comprising these layers decreases unexpectedly in this case.

The present invention further provides a process for preparing a metal complex, which is characterized in that a ligand having a triarylamine group is contacted with a metal compound comprising a metal atom of groups 13 to 15.

The way in which the metal compound is contacted with the ligand is uncritical in this context. For example, a solution of a ligand may be mixed with a solution of a metal compound. In addition, a solid ligand can be contacted with a solution of a metal compound. It is also possible to introduce a solid metal compound into a solution comprising at least one ligand. It is also possible to contact a gaseous metal compound with a gaseous ligand. Preference is given to producing a solution of a ligand and a metal compound. With regard to the metal compound, there are no restrictions in principle, it being possible with preference to use aryl-metal compounds, for example of the formula M(Ar)₃, where Ar is an aromatic radical, preferably benzene or toluene. The reaction can preferably be effected at temperatures above 60° C., preferably above 80° C., in which case the residue released from the metal compound, for example of the formula Ar, can be separated from the reaction mixture.

In very schematic form, an illustrative reaction can be represented by the following reaction equation:

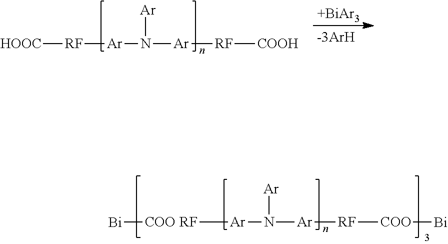

n=1, 2, 3, 4, . . . .

The scheme shown above is relatively rough, since the three ligands of a bismuth atom generally do not interact simultaneously with an identical second bismuth atom. Instead, crosslinking occurs. The triaryl ligand may have more than two coordination groups, such that the level of crosslinking can be adjusted correspondingly.

The conversion can be controlled via the temperature, and so it is possible to store solutions which may be relatively viscous. A reaction which leads to crosslinking and hence to a significant reduction in solubility can be conducted at elevated temperature.

It can be seen from the reaction scheme detailed above that the free ligand can be used in acidic form, for example as carboxylic acid, which is converted to the anionic form by the reaction.

The use of a metal atom of groups 13 to 15 preferably achieves p-doping.

The invention further provides solutions and formulations comprising at least one metal complex of the invention. The way in which such solutions can be prepared is detailed above and below.

These solutions can be used in order to produce thin polymer layers, for example by surface coating methods (e.g. spin-coating) or by printing methods (e.g. inkjet printing).

Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents. Preferred solvents are especially ethers and/or esters.

The present invention also encompasses what are called hybrid devices in which one or more layers which are processed from solution and layers which are produced by vapour deposition of low molecular weight substances may occur.

The metal complexes of the invention can be used in electronic or optoelectronic devices or for production thereof.

The present invention thus further provides for the use of the metal complex of the invention in electronic or optoelectronic devices, preferably in organic electroluminescent devices (OLEDs), organic field-effect transistors (OFETs), organic integrated circuits (O-ICs), organic thin-film transistors (TFTs), organic solar cells (O-SCs), organic laser diodes (O-laser), organic photovoltaic (OPV) elements or devices or organic photoreceptors (OPCs), more preferably in organic electroluminescent devices (OLEDs).

In the case of the aforementioned hybrid device, in conjunction with organic electroluminescent devices, reference is made to combined PLED/SMOLED (polymeric light-emitting diode/small molecule organic light-emitting diode) systems.

The way in which OLEDs can be produced is known to those skilled in the art and is described in detail, for example, as a general process in WO 2004/070772 A2, which has to be adapted appropriately to the individual case.

As described above, the inventive compositions are very particularly suitable as electroluminescent materials in OLEDs or displays produced in this way.

Electroluminescent materials in the context of the present invention are considered to mean materials which can find use as the active layer. “Active layer” means that the layer is capable of emitting light on application of an electrical field (light-emitting layer) and/or that it improves the injection and/or transport of the positive and/or negative charges (charge injection or charge transport layer).

The present invention therefore preferably also provides for the use of the metal complexes of the invention in OLEDs, especially as electroluminescent material.

The present invention further provides electronic or optoelectronic components, preferably organic electroluminescent devices (OLEDs), organic field-effect transistors (OFETs), organic integrated circuits (O-ICs), organic thin-film transistors (TFTs), organic solar cells (O-SCs), organic laser diodes (O-laser), organic photovoltaic (OPV) elements or devices and organic photoreceptors (OPCs), more preferably organic electroluminescent devices, having one or more active layers, wherein at least one of these active layers comprises one or more metal complexes of the invention. The active layer may, for example, be a light-emitting layer, a charge transport layer and/or a charge injection layer.

More preferably, the active layer may comprise a composition of the present invention comprising a crosslinked metal complex.

The crosslinking may be detected especially via a reduced solubility. For this purpose, it is possible to apply a solvent, preferably toluene, to a layer, for example by spin-coating. After removal of the solvent, the layer thicknesses before and after the treatment can be compared. In the case of a reduction of more than 5% of the layer thickness, the layer is soluble. The detection is preferably conducted at 30° C., allowing solvent contact preferably for 2 hours.

In the present application text and also in the examples that follow hereinafter, the main aim is the use of the inventive compositions in relation to OLEDs and corresponding displays. In spite of this restriction of the description, it is possible for the person skilled in the art, without exercising further inventive skill, to utilize the inventive compositions as semiconductors for the further above-described uses in other electronic devices as well.

The examples which follow are intended to illustrate the invention without restricting it. More particularly, the features, properties and advantages that are described therein for the defined compounds that form the basis of the example in question are also applicable to other compounds that are not referred to in detail but are covered by the scope of protection of the claims, unless the opposite is stated elsewhere.

### EXAMPLES

All syntheses are conducted in an argon atmosphere and in dry solvents, unless stated otherwise.

### Part A: Preparation of the Monomers

### A.1 Preparation of Am1

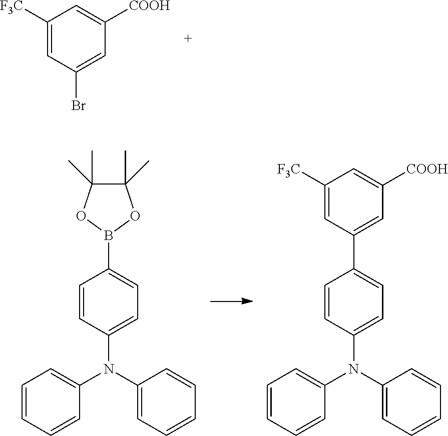 [SMILES: O=C(O)c1cc(Br)cc(C(F)(F)F)c1 ; CC1(C)OB(c2ccc(N(c3ccccc3)c3ccccc3)cc2)OC1(C)C ; O=C(O)c1cc(-c2ccc(N(c3ccccc3)c3ccccc3)cc2)cc(C(F)(F)F)c1]

3-Bromo-5-(trifluoromethyl)benzoic acid [328-67-6] (8.79 g, 40 mmol), pinacol 4-(diphenylamino)phenylboronate [267221-88-5] (17.85 g, 48 mmol), caesium carbonate (32.64 g, 100 mmol) and [1,1′-bis(diphenylphosphino)ferrocene]palladium dichloride [72287-26-4] (234 mg, 3.2 mmol) are heated to reflux in a mixture of 120 ml of dioxane and 30 ml of ethanol for 8 h. After cooling, the mixture is filtered through Celite, and the solvents are removed on a rotary evaporator. The residue is taken up with a mixture of ethyl acetate and 1 N aqueous hydrochloric acid (1:1 v/v). The phases are separated; the organic phase is washed three times with saturated sodium chloride solution, dried over magnesium sulphate and freed of the solvent on a rotary evaporator. The residue is purified by column chromatography (reversed phase, eluent mixture: dichloromethane/methanol/acetic acid (90:8:2 v/v)). Drying under reduced pressure leaves 14.0 g (81% of theory) of the product as a colourless powder having a purity of about 99.5% by ¹H NMR.

In analogous manner, it is possible to prepare the following compounds:

| Example | Bromide | Product | Yield |
|---|---|---|---|
| Am2 | 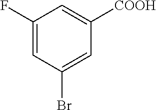 [SMILES: O=C(O)c1cc(F)cc(Br)c1] [176548-70-2] | 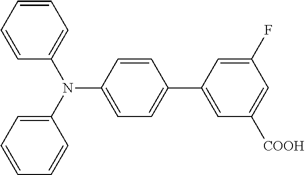 [SMILES: O=C(O)c1cc(F)cc(-c2ccc(N(c3ccccc3)c3ccccc3)cc2)c1] | 87% |
| Am3 | 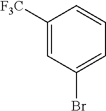 [SMILES: FC(F)(F)c1cccc(Br)c1] [401-78-5] | 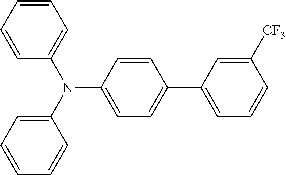 [SMILES: FC(F)(F)c1cccc(-c2ccc(N(c3ccccc3)c3ccccc3)cc2)c1] | 72% |
| Am4 | 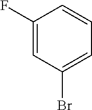 [1073-06-9] | 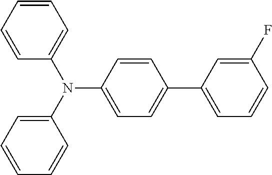 [SMILES: Fc1cccc(-c2ccc(N(c3ccccc3)c3ccccc3)cc2)c1] | 77% |

### A.2 Preparation of Br1

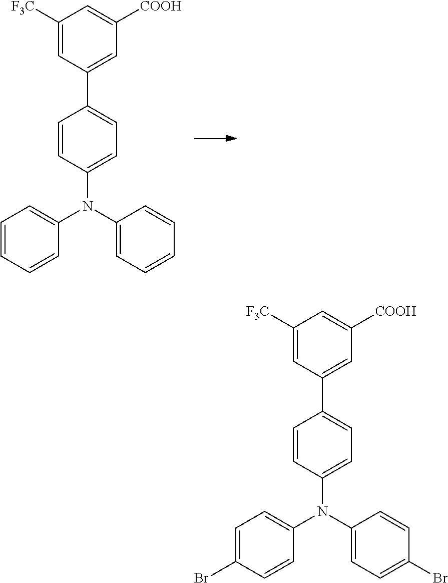 [SMILES: O=C(O)c1cc(-c2ccc(N(c3ccccc3)c3ccccc3)cc2)cc(C(F)(F)F)c1 ; O=C(O)c1cc(-c2ccc(N(c3ccc(Br)cc3)c3ccc(Br)cc3)cc2)cc(C(F)(F)F)c1]

To an initial charge of 4′-(diphenylamino)-5-(trifluoromethyl)biphenyl-3-carboxylic acid (12.7 g, 29 mmol) in 150 ml of tetrahydrofuran is added in portions, while cooling with ice, N-bromosuccinimide (10.5 g, 59 mmol). The cooling is removed and the mixture is stirred for 18 h. The solvent is removed on a rotary evaporator. The residue is purified by column chromatography (reversed phase, eluent: dichloromethane/methanol/acetic acid (90:8:2 v/v)). Drying under reduced pressure leaves 15.3 g (26 mmol, 89% of theory) of the product as a colourless powder having a purity of 99.8% by HPLC.

In an analogous manner, it is possible to prepare the following compounds:

| Example | Amine | Product | Yield |
|---|---|---|---|
| Br2 | 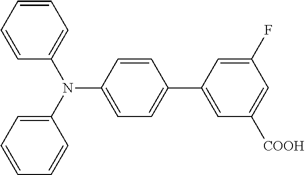 [SMILES: O=C(O)c1cc(F)cc(-c2ccc(N(c3ccccc3)c3ccccc3)cc2)c1] Am2 | 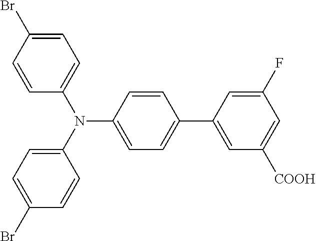 [SMILES: O=C(O)c1cc(F)cc(-c2ccc(N(c3ccc(Br)cc3)c3ccc(Br)cc3)cc2)c1] | 86% |
| Br3 | 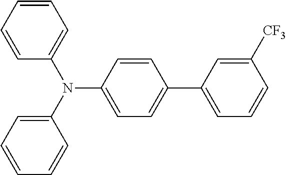 [SMILES: FC(F)(F)c1cccc(-c2ccc(N(c3ccccc3)c3ccccc3)cc2)c1] Am3 | 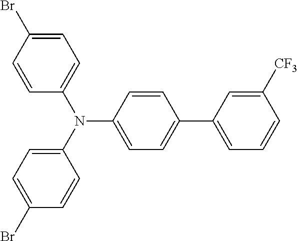 [SMILES: FC(F)(F)c1cccc(-c2ccc(N(c3ccc(Br)cc3)c3ccc(Br)cc3)cc2)c1] | 82% |
| Br4 | 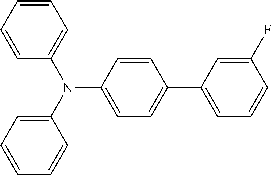 [SMILES: Fc1cccc(-c2ccc(N(c3ccccc3)c3ccccc3)cc2)c1] Am4 | 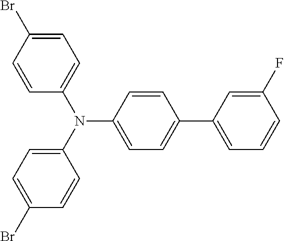 [SMILES: Fc1cccc(-c2ccc(N(c3ccc(Br)cc3)c3ccc(Br)cc3)cc2)c1] | 82% |

### Part B: Preparation of the Polymers

### Preparation of the Polymer P1 of the Invention Using the Monomers Prepared in Part A

The polymer P1 of the invention is prepared by SUZUKI coupling by the method described in WO 2003/048225 from the structural units shown below. After the polymerization, the pH of the reaction solution is adjusted to pH 2-3, before the purification methods described in WO 03/048225 are conducted. The polymer P1 prepared in this way contains the structural units, after elimination of the leaving groups, in the percentages reported (percentages=mol %).
P1 (Mₙ=58 000).

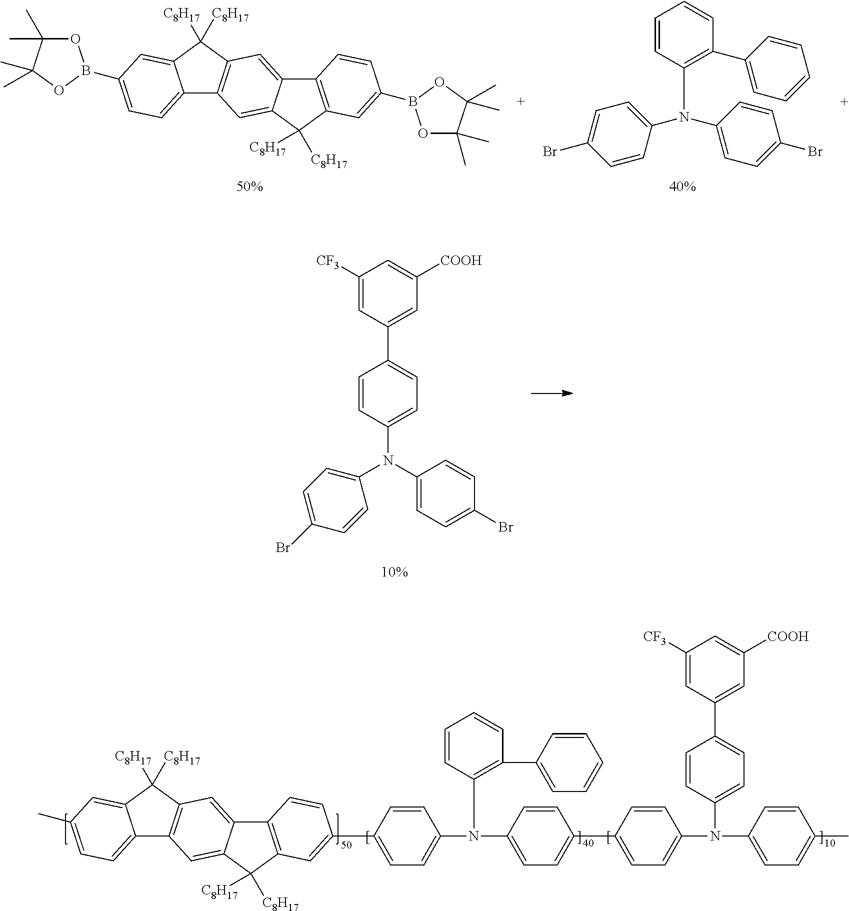

Further examples are prepared analogously to P1:

| Polymer | Structure | Synthesis according to |
|---|---|---|
| P2 | 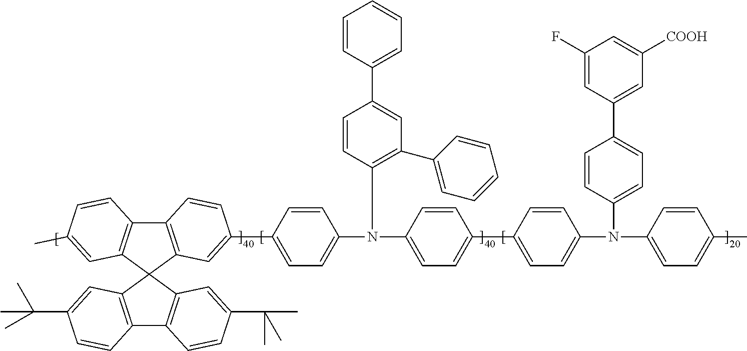 [SMILES: Cc1ccc(N(c2ccc(-c3ccc(N(c4ccc(-c5ccc6c(c5)C5(c7cc(C)ccc7-6)c6cc(C(C)(C)C)ccc6-c6ccc(C(C)(C)C)cc65)cc4)c4ccc(-c5ccccc5)cc4-c4ccccc4)cc3)cc2)c2ccc(-c3cc(F)cc(C(=O)O)c3)cc2)cc1] | WO2003/048225 |
| P3 | 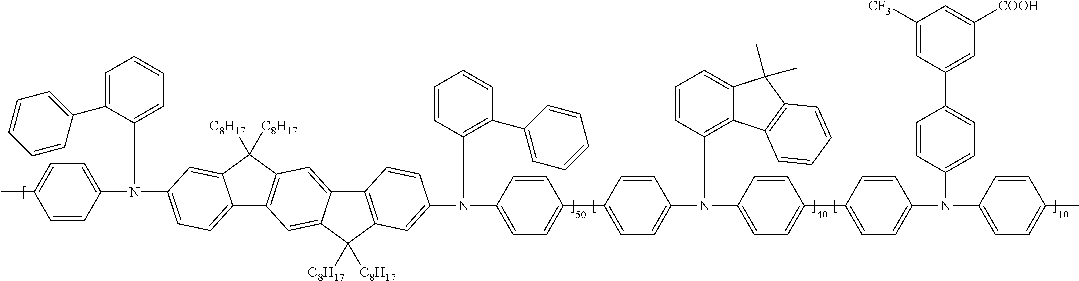 | WO2003/048225 |
| P4 | 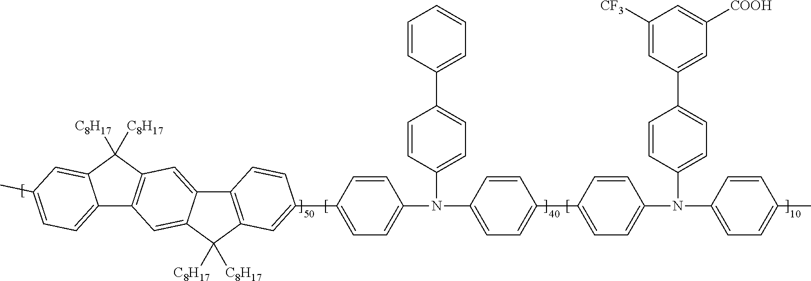 | WO2003/048225 |
| P5 | 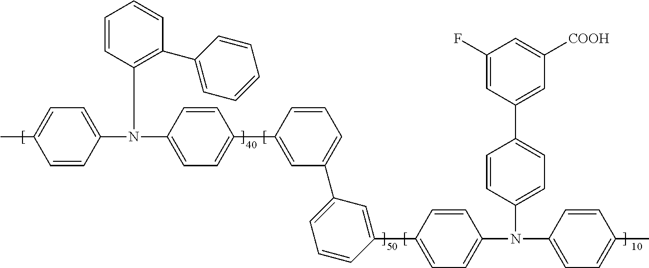 | WO2003/048225 |

Comparative polymers V1-5 are prepared analogously to WO 2003/048225.

| Polymer | Structure | Synthesis according to |
|---|---|---|
| V1 | 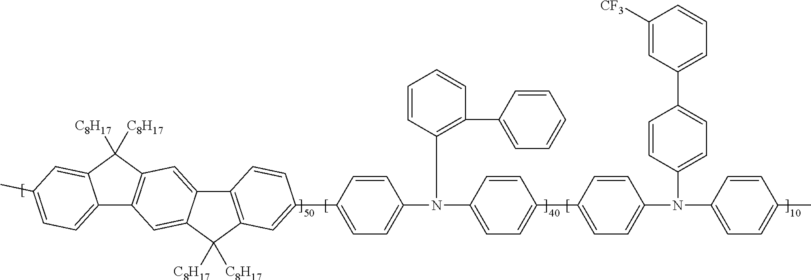 | WO2003/048225 |
| V2 | 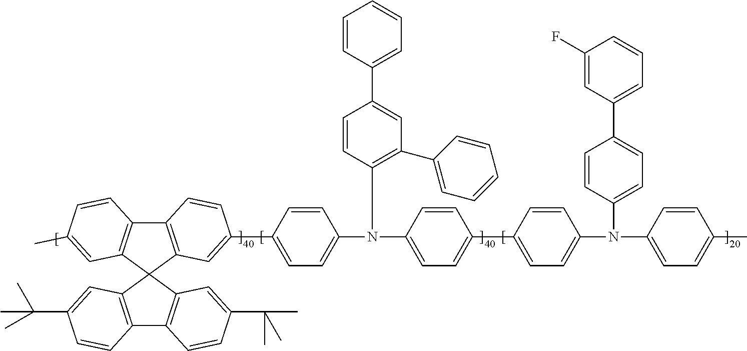 [SMILES: Cc1ccc(N(c2ccc(-c3ccc(N(c4ccc(-c5ccc6c(c5)C5(c7cc(C)ccc7-6)c6cc(C(C)(C)C)ccc6-c6ccc(C(C)(C)C)cc65)cc4)c4ccc(-c5ccccc5)cc4-c4ccccc4)cc3)cc2)c2ccc(-c3cccc(F)c3)cc2)cc1] | WO2003/048225 |
| V3 | 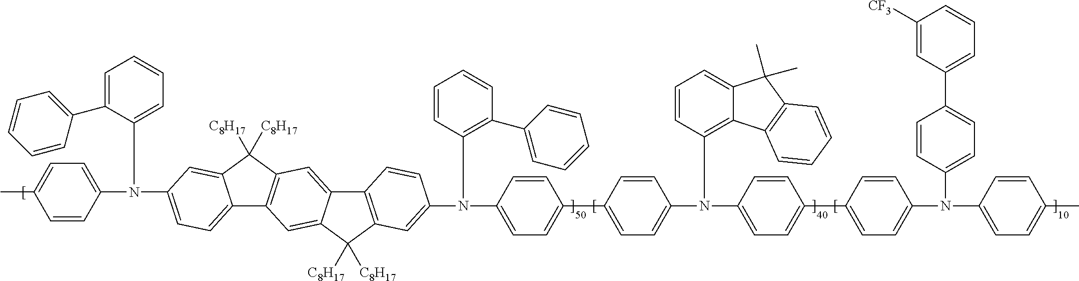 | WO2003/048225 |
| V4 | 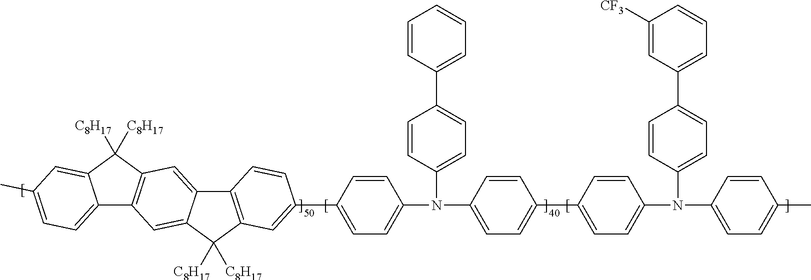 | WO2003/048225 |
| V5 | 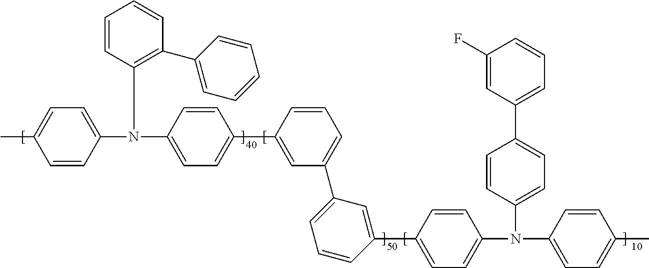 | WO2003/048225 |

### Part C: Device Examples

The inventive mixtures of polymer and bismuth compound can be processed from solution and lead, after baking, to insoluble layers having excellent hole injection and hole transport properties. They are therefore outstandingly suitable as hole injection layers in OLEDs.

Table C1 shows the bismuth compound used, which was purchased from Betapharma (Shanghai) Co., Ltd.

TABLE C1
Bismuth compound used

Bi1

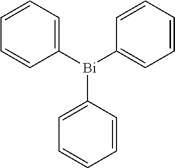

The mass ratio between polymer and bismuth compound is chosen such that there are about 1.1 bismuth atoms for every three COOH groups of the polymer. The mass ratio between the comparative polymers V1 to V5, for reasons of good comparability, are the same as the ratios of the corresponding inventive mixtures.

Whether the inventive mixtures after crosslinking give rise to a completely insoluble layer is tested analogously to WO 2010/097155.

Table D1 lists the remaining layer thickness of the original 20 nm after the washing operation described in WO 2010/097155. If there is no decrease in the layer thickness, the mixture of polymer and bismuth compound is insoluble and hence the crosslinking is sufficient.

TABLE C2
Check of the residual layer thickness of the original 20 nm after the wash
test

| | | | | Residual layer |
|---|---|---|---|---|
| | | | | thickness |
| | | | | after wash |
| | | | | test [nm] |
| | Bismuth | Mass ratio of | | Crosslinking at |
| Polymer | compound | polymer:Bi1 | Baking: 60 min @ | 220° C. |
| P1 | Bi1 | 97:3 | 180° C. | 20 |
| V1 | Bi1 | 97:3 | 180° C. | 3.5 |
| P2 | Bi1 | 92:8 | 180° C. | 20 |
| V2 | Bi1 | 92:8 | 180° C. | 8 |
| P3 | Bi1 | 98:2 | 180° C. | 20 |
| V3 | Bi1 | 98:2 | 180° C. | 6.5 |
| P4 | Bi1 | 97:3 | 180° C. | 20 |
| V4 | Bi1 | 97:3 | 180° C. | 4 |
| P5 | Bi1 | 93:7 | 180° C. | 20 |
| V5 | Bi1 | 93:7 | 180° C. | 7.5 |

As can be inferred from Table C2, the inventive mixtures comprising the inventive polymers P1, P2, P3, P4 and P5 crosslink completely at 180° C., whereas a majority of the layer was washed away from the layers composed of mixtures with comparative polymers (Vi to V5).

There are already many descriptions of the production of solution-based OLEDs in the literature, for example in WO 2004/037887 and WO 2010/097155. The process is matched to the circumstances described hereinafter (variation in layer thickness, materials).

The inventive mixtures of the inventive polymers and bismuth compound are used in two different layer sequences:

Structure A is as follows:
substrate,
ITO (50 nm),
hole injection layer (HIL) (100 nm),
cathode.

Structure B is as follows:
substrate,
ITO (50 nm),
HIL (20 nm),
hole transport layer (HTL) (40 nm),
emission layer (EML) (30 nm),
electron transport layer (ETL) (20 nm),
cathode.

Substrates used are glass plates coated with structured ITO (indium tin oxide) of thickness 50 nm. The different layers are applied to these coated glass plates analogously to Structure A or B.

The hole injection layers used are the inventive mixtures, composed of polymer and bismuth compound, and comparative mixtures, each dissolved in toluene. The typical solids content of such solutions is about 5-20 g/I when layer thicknesses between 20 nm and 100 nm are to be achieved by means of spin-coating. The layers are spun on in an inert gas atmosphere, argon in the present case, and baked at 180° C. for 60 minutes.

In structure B, the hole transport layer is formed by thermal evaporation in a vacuum chamber.

The materials used in the present case are shown in Table C3.

TABLE C3
Structural formulae of the hole-transporting materials processed from
vacuum

HT1

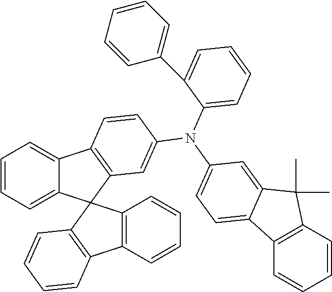 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

The emission layer is always composed of at least one matrix material (host material) and an emitting dopant (emitter). In structure B, the emission layer is formed by thermal evaporation in a vacuum chamber. This layer may consist of more than one material, the materials being added to one another by co-evaporation in a particular proportion by volume. Details given in such a form as M1:dopant (95:5) mean here that the M1 and dopant materials are present in the layer in a proportion by volume of 95%:5%.

The materials used in the present case are shown in Table C4.

TABLE C4
Structural formulae of the materials used in the emission layer

M1

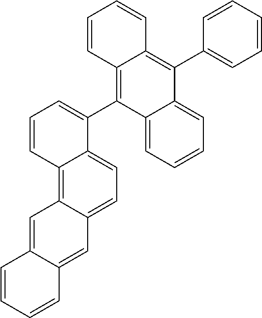 [SMILES: c1ccc(-c2c3ccccc3c(-c3cccc4c3ccc3cc5ccccc5cc34)c3ccccc23)cc1]

SEB

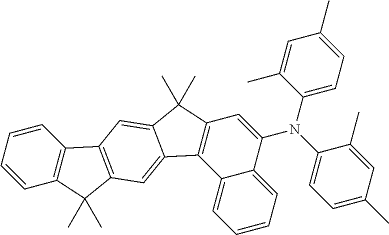 [SMILES: Cc1ccc(N(c2ccc(C)cc2C)c2cc3c(c4ccccc24)-c2cc4c(cc2C3(C)C)-c2ccccc2C4(C)C)c(C)c1]

The materials for the hole blocker layer and electron transport layer are likewise applied by thermal vapour deposition in a vacuum chamber and are shown in Table C5. The hole blocker layer consists of ETM1. The electron transport layer consists of the two materials ETM1 and ETM2, which are added to one another by co-evaporation in a proportion by volume of 50% each.

TABLE C5
HBL and ETL materials used

ETM1

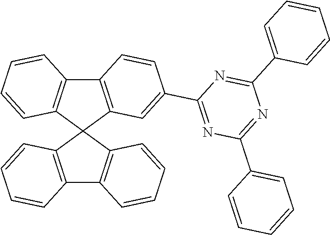 [SMILES: c1ccc(-c2nc(-c3ccccc3)nc(-c3ccc4c(c3)C3(c5ccccc5-c5ccccc53)c3ccccc3-4)n2)cc1]

ETM2

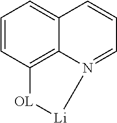

The cathode is formed by the thermal evaporation of a 100 nm-thick aluminium layer.

The exact structure of the OLEDs can be found in Table C6. The HIL column lists the polymer used, and the temperature at which the layer is baked and optionally crosslinked.

TABLE C6
Structure of the OLEDs

| | | HIL | | | | EML |
|---|---|---|---|---|---|---|
| Exam- | Struc- | Poly- | Bismuth | Mass ratio of | | Compo- |
| ple | ture | mer | compound | polymer:Bi1 | T [° C.] | sition |
| C01 | A | P1 | Bi1 | 97:3 | 180° C. | — |
| C02 | A | V1 | Bi1 | 97:3 | 180° C. | — |
| C03 | A | P2 | Bi1 | 92:8 | 180° C. | — |
| C04 | A | V2 | Bi1 | 92:8 | 180° C. | — |
| C05 | A | P3 | Bi1 | 98:2 | 180° C. | — |
| C06 | A | V3 | Bi1 | 98:2 | 180° C. | — |
| C07 | A | P4 | Bi1 | 97:3 | 180° C. | — |
| C08 | A | V4 | Bi1 | 97:3 | 180° C. | — |
| C09 | A | P5 | Bi1 | 93:7 | 180° C. | — |
| C10 | A | V5 | Bi1 | 93:7 | 180° C. | — |
| C11 | B | P1 | Bi1 | 97:3 | 180° C. | M1:SEB |
| | | | | | | (95:5) |
| C12 | B | V1 | Bi1 | 97:3 | 180° C. | M1:SEB |
| | | | | | | (95:5) |

The OLEDs are characterized in a standard manner. For this purpose, the electroluminescence spectra, current-voltage-luminance characteristics (IUL characteristics) assuming Lambertian radiation characteristics and, in the case of structure B, the (operating) lifetime are determined. The IUL characteristics are used to determine parameters such as the operating voltage (in V) and the external quantum efficiency (in %) at a particular brightness. LD80 @ 1000 cd/m² is the lifetime until the OLED, given a starting brightness of 1000 cd/m², has dropped to 80% of the starting intensity, i.e. to 800 cd/m².

The properties of the different OLEDs are summarized in Tables C7 a and b.

### Tables C7 a-b:

### Properties of the OLEDs

TABLE C7 a

| | Voltage |
|---|---|
| | at 1 mA/cm² |
| Example | [V] |
| C01 | 0.4 |
| C02 | 6 |
| C03 | 0.5 |
| C04 | 4 |
| C05 | 0.2 |
| C06 | 3.5 |
| C07 | 0.3 |
| C08 | 4.5 |
| C09 | 0.4 |
| C10 | 5.5 |

TABLE C7 b

| | | | LD80 |
|---|---|---|---|
| | Efficiency | Voltage | at |
| | at 1000 cd/m² | at 1000 cd/m² | 1000 cd/m² |
| Example | % EQE | [V] | [h] |
| C11 | 7.8 | 4.6 | 257 |
| C12 | 4 | 6.2 | 35 |

Table C7 a shows that the voltages of components made from inventive mixtures (polymers P1 to P5) are significantly lower than their uncrosslinkable and undopable equivalents (polymers V1 to V5). The inventive mixtures are thus suitable as hole injection materials which lower the operating voltage of the OLED.

Table C7 b shows that the use of the inventive mixtures leads to an improvement in component performance.

1-20. (canceled)

21. A metal complex having a metal atom of groups 13 to 15 and at least one ligand, where the ligand comprises at least one anionic coordination group having at least one oxygen and/or nitrogen atom through which the metal atom is coordinated, and the ligand comprises at least one triarylamine group.

22. The metal complex of claim 21, wherein at least one triarylamine group comprises a structural element of formula (I): 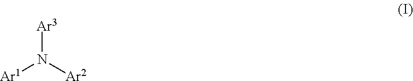
wherein
Ar¹, Ar², and Ar³
are the same or different in each instance and are a mono- or polycyclic, aromatic or heteroaromatic ring system which is optionally substituted by one or more R radicals;
R is the same or different in each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 40 carbon atoms or an alkenyl or alkynyl group having 2 to 40 carbon atoms or a branched or cyclic alkyl, alkoxy, or thioalkoxy group having 3 to 40 carbon atoms, each of which is optionally substituted by one or more R¹ radicals, wherein one or more nonadjacent CH₂ groups are optionally replaced by R¹C═CR¹, C≡C, Si(R¹)₂, C═O, C═S, C═NR¹, P(═O)R¹, SO, SO₂, NR¹, O, S, or CONR¹, and wherein one or more hydrogen atoms are optionally replaced by D, F, Cl, Br, I, or CN, an aromatic or heteroaromatic ring system which has 5 to 60 aromatic ring atoms and is optionally substituted in each case by one or more R¹ radicals, an aryloxy or heteroaryloxy group which has 5 to 60 aromatic ring atoms and is optionally substituted by one or more R¹ radicals, an aralkyl or heteroaralkyl group which has 5 to 60 aromatic ring atoms and is optionally substituted by one or more R¹ radicals, or a diarylamino group, diheteroarylamino group, or arylheteroarylamino group which has 10 to 40 aromatic ring atoms and is optionally substituted by one or more R¹ radicals; and wherein two or more R radicals together optionally define a mono- or polycyclic, aliphatic, aromatic, and/or benzofused ring system; and
R¹ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R¹ substituents together optionally define a mono- or polycyclic, aliphatic, or aromatic ring system; and
wherein at least one of the Ar¹, Ar², and Ar³ radicals is bonded covalently to at least one anionic coordination group.

23. The metal complex of claim 21, wherein
at least one anionic coordination group in the ligand comprises a structure of formula (K-I): 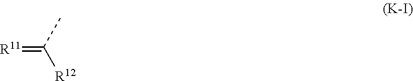
wherein
R¹¹ and R¹² are each, independently, oxygen, sulphur, selenium, NH, or NR¹³, wherein R¹³ is selected from the group consisting of alkyl and aryl and is optionally bonded to other groups in the ligand; and
the dotted line represents the bond of the anionic coordination group to the ligand.

24. The metal complex of claim 21, wherein the ligand comprises at least two spatially far-removed anionic coordination groups via which two metal atoms can be complexed.

25. The metal complex of claim 21, wherein
at least one anionic coordination group in the ligand comprises a structure of formula (K-II): 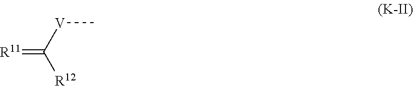
wherein
R¹¹ and R¹²
are, independently, oxygen, sulphur, selenium, NH, or NR¹³, wherein R¹³ is selected from the group consisting of alkyl and aryl and is optionally bonded to other groups in the ligand;
V is a bond or a bonding group selected from the group consisting of an aromatic or heteroaromatic ring system which has 5 to 40 aromatic ring atoms and is optionally substituted in each case by one or more R radicals, an alkylene group which has 1 to 40 carbon atoms and is optionally substituted in each case by one or more R radicals, wherein one or more nonadjacent CH₂ groups is optionally replaced by RC═CR, C≡C, Si(R)₂, C═O, C═S, C═NR, P(═O)R, SO, SO₂, NR, O, S, or CONR and wherein one or more hydrogen atoms is optionally replaced by D, F, Cl, Br, I, or CN;
R is the same or different in each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 40 carbon atoms or an alkenyl or alkynyl group having 2 to 40 carbon atoms or a branched or cyclic alkyl, alkoxy, or thioalkoxy group having 3 to 40 carbon atoms, each of which is optionally substituted by one or more R¹ radicals, wherein one or more nonadjacent CH₂ groups are optionally replaced by R¹C═CR¹, C≡C, Si(R¹)₂, C═O, C═S, C═NR¹, P(═O)R¹, SO, SO₂, NR¹, O, S, or CONR¹, and wherein one or more hydrogen atoms are optionally replaced by D, F, Cl, Br, I, or CN, an aromatic or heteroaromatic ring system which has 5 to 60 aromatic ring atoms and is optionally substituted in each case by one or more R¹ radicals, an aryloxy or heteroaryloxy group which has 5 to 60 aromatic ring atoms and is optionally substituted by one or more R¹ radicals, an aralkyl or heteroaralkyl group which has 5 to 60 aromatic ring atoms and is optionally substituted by one or more R¹ radicals, or a diarylamino group, diheteroarylamino group, or arylheteroarylamino group which has 10 to 40 aromatic ring atoms and is optionally substituted by one or more R¹ radicals; and wherein two or more R radicals together optionally define a mono- or polycyclic, aliphatic, aromatic, and/or benzofused ring system;
R¹ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R¹ substituents together optionally define a mono- or polycyclic, aliphatic, or aromatic ring system;
and
the dotted line represents the bond of the anionic coordination group to the triarylamine group.

26. The metal complex of claim 25, wherein
the V radical is a bond or a bonding group selected from the group consisting of arylene groups having 6 to 24 carbon atoms and heteroarylene groups having 3 to 24 carbon atoms, each of which is optionally substituted by one or more R¹ radicals, alkylene groups which have 1, 2, 3, 4, 5, 6, 7, 8, 9, 10, 11, or 12 carbon atoms and is optionally substituted by one or more R¹ radicals, wherein
R¹ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R¹ substituents together optionally define a mono- or polycyclic, aliphatic, or aromatic ring system.

27. The metal complex of claim 21, wherein the ligand is a compound comprising a structure of formula (L-I): 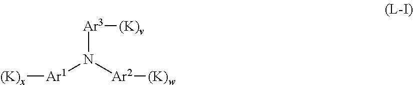
wherein
Ar¹, Ar², and Ar³
are the same or different in each instance and are a mono- or polycyclic, aromatic or heteroaromatic ring system which is optionally substituted by one or more R radicals;
R is the same or different in each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 40 carbon atoms or an alkenyl or alkynyl group having 2 to 40 carbon atoms or a branched or cyclic alkyl, alkoxy, or thioalkoxy group having 3 to 40 carbon atoms, each of which is optionally substituted by one or more R¹ radicals, wherein one or more nonadjacent CH₂ groups are optionally replaced by R¹C═CR¹, C≡C, Si(R¹)₂, C═O, C═S, C═NR¹, P(═O)R¹, SO, SO₂, NR¹, O, S, or CONR¹, and wherein one or more hydrogen atoms are optionally replaced by D, F, Cl, Br, I, or CN, an aromatic or heteroaromatic ring system which has 5 to 60 aromatic ring atoms and is optionally substituted in each case by one or more R¹ radicals, an aryloxy or heteroaryloxy group which has 5 to 60 aromatic ring atoms and is optionally substituted by one or more R¹ radicals, an aralkyl or heteroaralkyl group which has 5 to 60 aromatic ring atoms and is optionally substituted by one or more R¹ radicals, or a diarylamino group, diheteroarylamino group, or arylheteroarylamino group which has 10 to 40 aromatic ring atoms and is optionally substituted by one or more R¹ radicals; and wherein two or more R radicals together optionally define a mono- or polycyclic, aliphatic, aromatic, and/or benzofused ring system; and
R¹ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R¹ substituents together optionally define a mono- or polycyclic, aliphatic, or aromatic ring system;
K is an anionic coordination group;
v is 0, 1, 2, 3, 4, 5, 6, or 7;
w is 0, 1, 2, 3, 4, 5, 6, or 7; and
x is 0, 1, 2, 3, 4, 5, 6, or 7;
wherein the sum of v, w, and x is not less than 1.

28. The metal complex of claim 21, wherein the ligand has a molecular weight of not more than 10,000 g/mol.

29. The metal complex of claim 21, wherein the ligand is a polymer comprising at least one structural unit of formula (P-I): 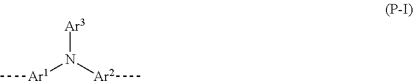
wherein
Ar¹, Ar², and Ar³
are the same or different in each instance and are a mono- or polycyclic, aromatic or heteroaromatic ring system which is optionally substituted by one or more R radicals;
R is the same or different in each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 40 carbon atoms or an alkenyl or alkynyl group having 2 to 40 carbon atoms or a branched or cyclic alkyl, alkoxy, or thioalkoxy group having 3 to 40 carbon atoms, each of which is optionally substituted by one or more R¹ radicals, wherein one or more nonadjacent CH₂ groups are optionally replaced by R¹C═CR¹, C≡C, Si(R¹)₂, C═O, C═S, C═NR¹, P(═O)R¹, SO, SO₂, NR¹, O, S, or CONR¹, and wherein one or more hydrogen atoms are optionally replaced by D, F, Cl, Br, I, or CN, an aromatic or heteroaromatic ring system which has 5 to 60 aromatic ring atoms and is optionally substituted in each case by one or more R¹ radicals, an aryloxy or heteroaryloxy group which has 5 to 60 aromatic ring atoms and is optionally substituted by one or more R¹ radicals, an aralkyl or heteroaralkyl group which has 5 to 60 aromatic ring atoms and is optionally substituted by one or more R¹ radicals, or a diarylamino group, diheteroarylamino group, or arylheteroarylamino group which has 10 to 40 aromatic ring atoms and is optionally substituted by one or more R¹ radicals; and wherein two or more R radicals together optionally define a mono- or polycyclic, aliphatic, aromatic, and/or benzofused ring system; and
R¹ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R¹ substituents together optionally define a mono- or polycyclic, aliphatic, or aromatic ring system;
and
the dotted lines represent bonds to adjacent structural units in the polymer, and wherein the Ar¹, Ar², and Ar³ groups in the structural unit (P-I) are optionally substituted by at least one anionic coordination group.

30. The metal complex of claim 21, wherein the ligand is a polymer comprising at least one structural unit of formula (L-P-I): 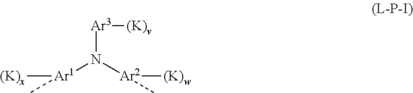
wherein
Ar¹, Ar², and Ar³
are the same or different in each instance and are a mono- or polycyclic, aromatic or heteroaromatic ring system which is optionally substituted by one or more R radicals;
R is the same or different in each instance and is H, D, F, Cl, Br, I, N(R¹)₂, CN, NO₂, Si(R¹)₃, B(OR¹)₂, C(═O)R¹, P(═O)(R¹)₂, S(═O)R¹, S(═O)₂R¹, OSO₂R¹, a straight-chain alkyl, alkoxy, or thioalkoxy group having 1 to 40 carbon atoms or an alkenyl or alkynyl group having 2 to 40 carbon atoms or a branched or cyclic alkyl, alkoxy, or thioalkoxy group having 3 to 40 carbon atoms, each of which is optionally substituted by one or more R¹ radicals, wherein one or more nonadjacent CH₂ groups are optionally replaced by R¹C═CR¹, C≡C, Si(R¹)₂, C═O, C═S, C═NR¹, P(═O)R¹, SO, SO₂, NR¹, O, S, or CONR¹, and wherein one or more hydrogen atoms are optionally replaced by D, F, Cl, Br, I, or CN, an aromatic or heteroaromatic ring system which has 5 to 60 aromatic ring atoms and is optionally substituted in each case by one or more R¹ radicals, an aryloxy or heteroaryloxy group which has 5 to 60 aromatic ring atoms and is optionally substituted by one or more R¹ radicals, an aralkyl or heteroaralkyl group which has 5 to 60 aromatic ring atoms and is optionally substituted by one or more R¹ radicals, or a diarylamino group, diheteroarylamino group, or arylheteroarylamino group which has 10 to 40 aromatic ring atoms and is optionally substituted by one or more R¹ radicals; and wherein two or more R radicals together optionally define a mono- or polycyclic, aliphatic, aromatic, and/or benzofused ring system; and
R¹ is the same or different in each instance and is H, D, F, or an aliphatic, aromatic, and/or heteroaromatic hydrocarbyl radical having 1 to 20 carbon atoms, wherein one or more hydrogen atoms are optionally replaced by F; and wherein two or more R¹ substituents together optionally define a mono- or polycyclic, aliphatic, or aromatic ring system;
K is an anionic coordination group;
v is 0, 1, 2, 3, 4, 5, 6, or 7,
w is 0, 1, 2, 3, 4, 5, 6, or 7, and
x is 0, 1, 2, 3, 4, 5, 6, or 7,
wherein the sum of v, w, and x is not less than 1, and
the dotted lines represent bonds to adjacent structural units in the polymer.

31. The metal complex of claim 22, wherein the Ar³ radical in formula (I) is substituted by Ar⁴ in at least one ortho position, based on the position of the nitrogen atom shown in formula (I), wherein Ar⁴ is a mono- or polycyclic, aromatic or heteroaromatic ring system which has 5 to 60 aromatic ring atoms and is optionally substituted by one or more R radicals, and wherein the Ar⁴ radical is optionally substituted by one or more anionic coordination groups.

32. The metal complex of claim 29, wherein the Ar³ radical in formula (P-I) is substituted by Ar⁴ in at least one ortho position, based on the position of the nitrogen atom shown in formula (PI), wherein Ar⁴ is a mono- or polycyclic, aromatic or heteroaromatic ring system which has 5 to 60 aromatic ring atoms and is optionally substituted by one or more R radicals, and wherein the Ar⁴ radical is optionally substituted by one or more anionic coordination groups.

33. The metal complex of claim 31, wherein the triarylamine group comprises at least one structural element of formula (I) selected from the group consisting of structural elements of formula (Ia): 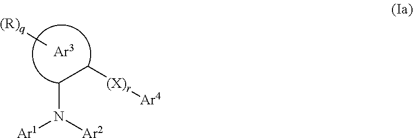
wherein
q is 0, 1, 2, 3, 4, 5, or 6,
X is CR₂, NR, SiR₂, NR, CK₂, NK, SiK₂, CRK, SiRK, O, S, C═O, or (P═O)R; and
r is 0 or 1.

34. The metal complex of claim 32, wherein the polymer comprises at least one structural unit of formula (P-I) selected from the group consisting of structural units of formulae (P-Ia): 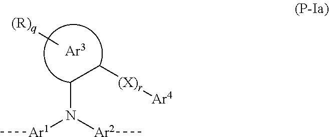
wherein
the dotted lines represent bonds to adjacent structural units in the polymer;
q is 0, 1, 2, 3, 4, 5, or 6,
X is CR₂, NR, SiR₂, NR, CK₂, NK, SiK₂, CRK, SiRK, O, S, C═O, or (P═O)R; and
r is 0 or 1.

35. The metal complex of claim 31, wherein the triarylamine group comprises at least one structural element of formula (I) selected from the group consisting of structural units of formula (Ib): 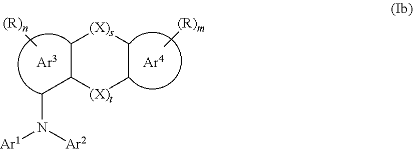
wherein
X is CR₂, NR, SiR₂, NR, CK₂, NK, SiK₂, CRK, SiRK, O, S, C═O, or (P═O)R;
m is 0, 1, 2, 3, or 4,
n is 0, 1, 2, or 3; and
s and t are each 0 or 1, wherein the sum of (s+t)=1 or 2.

36. The metal complex of claim 32, wherein the polymer comprises at least one structural unit of formula (P-I) selected from the group consisting of structural units formulae (P-Ib): 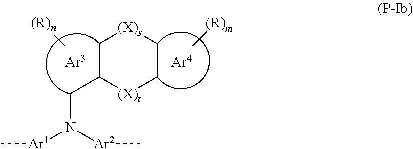
wherein
the dotted lines represent bonds to adjacent structural units in the polymer,
X is CR₂, NR, SiR₂, NR, CK₂, NK, SiK₂, CRK, SiRK, O, S, C═O, or (P═O)R;
m is 0, 1, 2, 3, or 4,
n is 0, 1, 2, or 3; and
s and t are each 0 or 1, wherein the sum of (s+t)=1 or 2.

37. The metal complex of claim 29, wherein the polymer comprises at least one structural unit of formula (P-I) selected from the group consisting of structural units of formula (P-VIIIa): 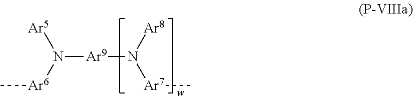
and structural units of formula (P-VIIIb): 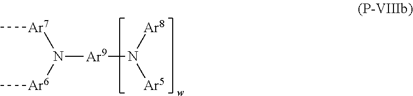
wherein
z is 1, 2, or 3;
Ar⁵ to Ar⁹
are each the same or different in each instance and are a mono- or polycyclic, aromatic or heteroaromatic ring system which is optionally substituted by one or more R radicals;
the dotted lines represent bonds to adjacent structural units in the polymer; and
wherein the Ar⁵, Ar⁶, Ar⁷, Ar⁸, and Ar⁹ groups are optionally substituted by one or more anionic coordination groups.

38. The metal complex of claim 29, wherein the polymer, as well as structural units of the formulae (P-I), contain at least one further structural unit of formula (P-XVII) which is different from the structural units of formulae (P-I):
-----Ar¹¹----- (P-XVII)
wherein
Ar¹¹ is a mono- or polycyclic, aromatic or heteroaromatic ring system which is optionally substituted by one or more R and/or K radicals;
K is an anionic coordination group; and
the dotted lines represent bonds to adjacent structural units in the polymer.

39. The metal complex of claim 21, wherein the metal atom in the metal complex is selected from the group consisting of bismuth, tin, and mixtures thereof.

40. A process for preparing a metal complex according to claim 21, comprising contacting a ligand having a triarylamine group with a metal compound comprising a metal atom of groups 13 to 15.

41. A solution or formulation comprising at least one metal complex of claim 22 in one or more solvents.

42. An electronic or optoelectronic component having one or more active layers, wherein at least one of these active layers comprises one or more metal complexes of claim 21.

43. The electronic or optoelectronic component of claim 42, wherein the electronic or optoelectronic component is selected from the group consisting of organic electroluminescent devices, organic light-emitting electrochemical cells, organic field-effect transistors, organic integrated circuits, organic thin-film transistors, organic solar cells, organic laser diodes, organic photovoltaic elements and devices. and organic photoreceptors.
